(19) United States
(12) Patent Application Publication
(10) Pub. No.: US 2012/0241898 A1
(43) Pub. Date: Sep. 27, 2012

(54) SEMICONDUCTOR DEVICE AND METHOD FOR MANUFACTURING THE SAME

(75) Inventors: Tsuyoshi Ohta, Kanagawa-ken (JP); Masatoshi Arai, Tokyo (JP); Miwako Suzuki, Kanagawa-ken (JP); Tadashi Matsuda, Kanagawa-ken (JP)

(73) Assignee: Kabushiki Kaisha Toshiba, Tokyo (JP)

(21) Appl. No.: 13/419,395

(22) Filed: Mar. 13, 2012

(30) Foreign Application Priority Data
Mar. 24, 2011 (JP) 2011-066018

(51) Int. Cl. H01L 29/47

(52) U.S. Cl. 257/475; 257/E29.148

(57) ABSTRACT

According to one embodiment, a semiconductor device includes a first semiconductor region of a first conductivity type, a first electrode, a second semiconductor region of the first conductivity type and a second electrode. The first semiconductor region includes a first portion including a first major surface and a second portion extending in a first direction perpendicular to the first major surface on the first major surface. The first electrode includes a third portion provided to face the second portion and is provided to be separated from the first semiconductor region. The second semiconductor region is provided between the second and third portions, includes a first concentration region having a lower impurity concentration than the first semiconductor region and forms a Schottky junction with the third portion. The second electrode is provided on an opposite side of the first major surface and in conduction with the first portion.

### CROSS-REFERENCE TO RELATED APPLICATIONS

This application is based upon and claims the benefit of priority from the prior Japanese Patent Application No. 2011-066018, filed on Mar. 24, 2011; the entire contents of which are incorporated herein by reference.

### FIELD

Embodiments described herein relate generally to a semiconductor device and a method for manufacturing the same.

### BACKGROUND

As a semiconductor device for a better trade-off between forward voltage and leakage current characteristics, there is a structure in which a Schottky barrier joint and a p-n junction are merged (for example, MPS (Merged PIN Schottky Rectifier)). The MPS includes a plurality of p-type semiconductor regions formed within an n-type semiconductor region and a Schottky barrier metal in contact with an n-type semiconductor region and a p-type semiconductor region. When a reverse voltage is applied to the MPS, respective empty layers that extend from the p-type semiconductor regions are pinched off one another at a low voltage. Thereby, an increase in an electric field in a Schottky barrier junction is suppressed, which in turn suppresses the leakage current. For such semiconductor device, a further reduction in forward voltage is desired to be lowered without increasing the element area.

### BRIEF DESCRIPTION OF THE DRAWINGS

FIG. 1 is a schematic perspective view illustrating the configuration of a semiconductor device;

FIG. 2 is a schematic perspective view illustrating the configuration of a part of the semiconductor device;

FIG. 3 is a schematic perspective view illustrating the configuration of a semiconductor device;

FIG. 4A to FIG. 6B are schematic views illustrating the configuration of semiconductor devices;

FIGS. 7A and 7B are schematic views illustrating the configuration of semiconductor devices;

FIG. 8 is a schematic view illustrating the configuration of a semiconductor device;

FIG. 9A to FIG. 16C are schematic perspective views describing methods for manufacturing the semiconductor devices;

FIG. 17 to FIG. 23 are schematic perspective views illustrating the configuration of semiconductor devices;

FIG. 24 is a schematic perspective view illustrating the configuration of a semiconductor device;

FIG. 25A to FIG. 26B are schematic perspective views describing a method for manufacturing the semiconductor device;

FIG. 27 is a schematic perspective view describing a method for manufacturing the semiconductor device;

FIGS. 28A to 28B are schematic perspective view describing another example of the embodiment;

FIG. 29A to FIG. 31B are schematic perspective views describing a method for manufacturing the semiconductor device;

FIG. 32 is a schematic perspective view describing a method for manufacturing the semiconductor device;

FIG. 33A to FIG. 37B are schematic perspective views describing another example of the method for manufacturing the semiconductor device;

FIG. 38 is a schematic perspective view describing another example of the method for manufacturing the semiconductor device;

FIG. 39 is a schematic plan view illustrating the configuration of a semiconductor device;

FIG. 40A to FIG. 48B are schematic views illustrating the configuration of the semiconductor device;

FIG. 49 is a schematic plan view illustrating a semiconductor device;

FIG. 50A to FIG. 51B are schematic views describing a method for manufacturing the semiconductor device;

FIG. 52A to FIG. 53C are schematic views describing the ion implantation by rotations;

FIG. 54 is a schematic perspective view illustrating the configuration of the semiconductor device;

FIGS. 55A to 55C are schematic views of the semiconductor device;

FIG. 56A to FIG. 57D are schematic perspective views illustrating a method for manufacturing the semiconductor device;

FIGS. 58A to 58C are schematic views illustrating various aspect of the semiconductor device;

FIG. 59 is a view illustrating the characteristics of a leak current;

FIG. 60 is a schematic view showing an example of another semiconductor device;

FIG. 61A to FIG. 63 are schematic plan views showing variations; and

FIG. 64 is a schematic view illustrating the terminal structure of the third part.

### DETAILED DESCRIPTION

According to one embodiment, a semiconductor device includes a first semiconductor region, a first electrode, a second semiconductor region and a second electrode. The first semiconductor region is a semiconductor region of a first conductivity type, including a first portion including a first major surface and a second portion extending in a first direction perpendicular to the first major surface on the first major surface. The first electrode includes a third portion that is a metal region provided so as to face the second portion. The first electrode is provided so as to be separated from the first semiconductor region. The second semiconductor region is provided between the second portion and the third portion. The second semiconductor region includes a first concentration region having an impurity concentration lower than an impurity concentration in the first semiconductor region. The second semiconductor region forms a Schottky junction with the third portion. The second semiconductor region is a semiconductor region of the first conductivity type. The second electrode is provided on an opposite side of the first major surface of the first portion. The second electrode is in conduction with the first portion.

Various embodiments will be described hereinafter with reference to the accompanying drawings.

The drawings are schematic or conceptual; and the relationships between the thicknesses and widths of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

In the following explanations, a specific example in which a first conductivity type is an n-type, and a second conductivity type is a p-type is shown as one example.

The expression of the conductivity marked with “+” indicates that an impurity concentration is relatively higher than an impurity concentration indicated by the expression of the conductivity type without being marked with “+”.

The expression of the conductivity marked with “−” indicates that an impurity concentration is relatively lower than an impurity concentration indicated by the expression of the conductivity type without being marked with “−”.

### First Embodiment

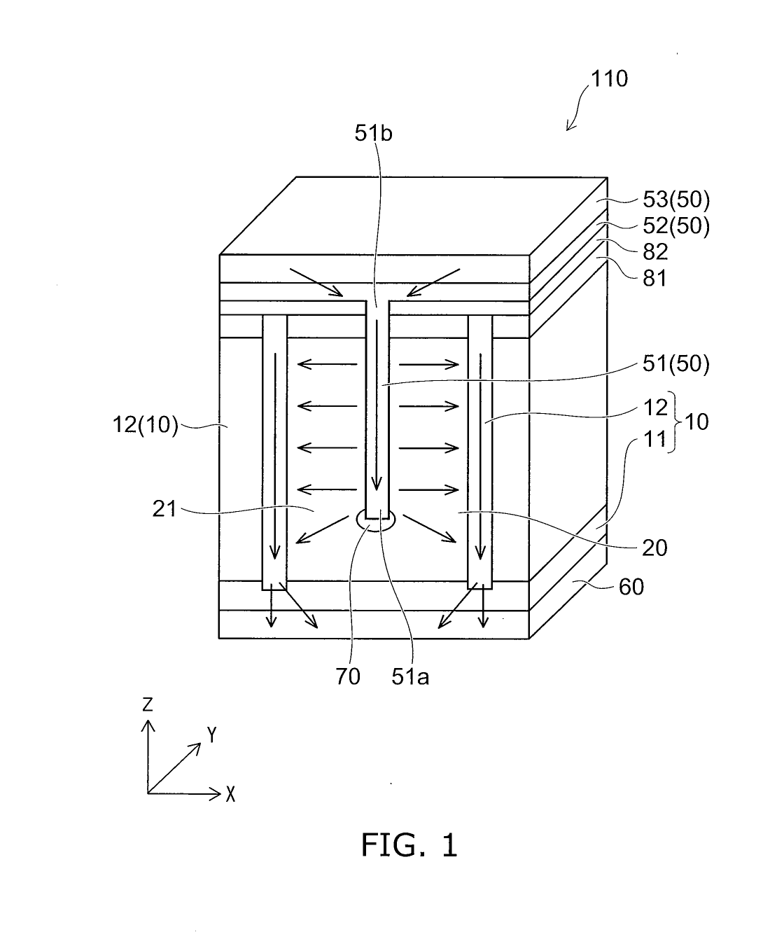

FIG. 1 is a schematic perspective view illustrating the configuration of a semiconductor device according to a first embodiment.

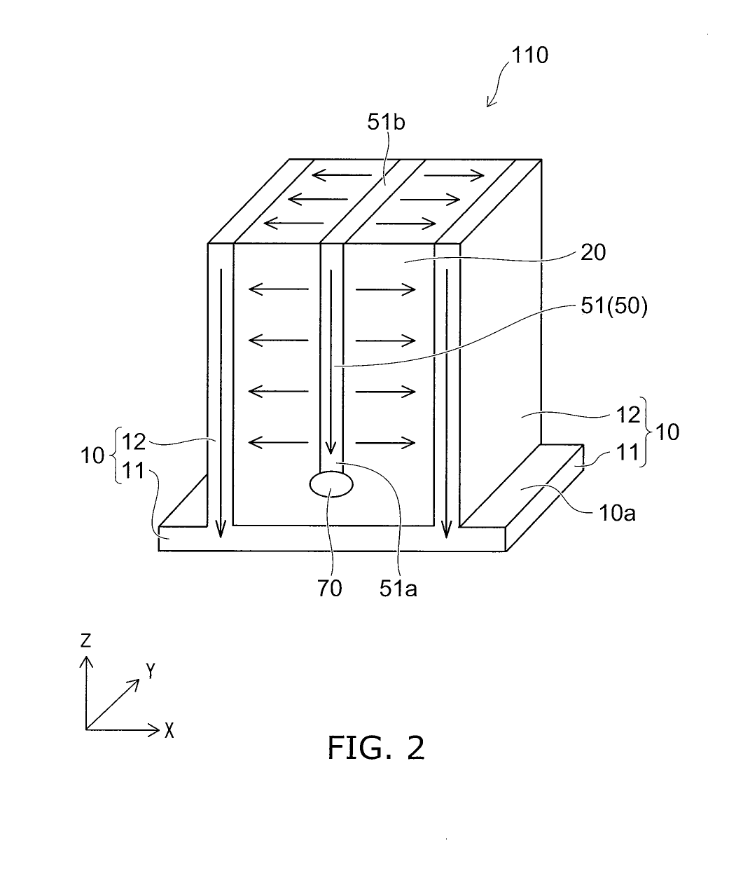

FIG. 2 is a schematic perspective view illustrating the configuration of a part of the semiconductor device illustrated in FIG. 1.

A semiconductor device 110 according to the embodiment is a Schottky barrier diode.

As shown in FIGS. 1 and 2, the semiconductor device 110 according to the first embodiment includes a first semiconductor region 10 of a first conductivity type, a second semiconductor region 20 of the first conductivity type, a first electrode 50 and a second electrode 60.

The first semiconductor region 10 has a first portion 11 including a first major surface 10a, and a second portion 12 that extends in a first direction perpendicular to the first major surface 10a on the first major surface 10a.

Here, the first direction perpendicular to the first major surface 10a is defined to be a Z-axis direction. A direction perpendicular to the Z-axis direction is defined to be an X-axis direction (a second direction); and a direction perpendicular to the Z-axis direction and the X-axis direction is defined to be a Y-axis direction (a third direction). Additionally, a side of the first major surface 10a of the first portion 11 may be referred to as upper (upper side), and the opposite side of the first portion 11 may be referred to as lower (lower side).

The second portion 12 is provided in a pillar-shape on the first major surface 10a of the first portion 11. On the first major surface 10a, a plurality of the second portions 12 may be provided as necessary. FIGS. 1 and 2 illustrate two of the second portions 12 on the first major surface 10a.

The first portion 11 is, for example, a semiconductor substrate of an n⁺-type. The second portion 12 is, for example, a semiconductor pillar of the n⁺-type.

The second portion 12 extends in the Z-axis direction and also extends in the Y-axis direction. The two second portions 12 illustrated in FIGS. 1 and 2 are disposed in the X-axis direction at a predetermined interval.

The first electrode 50 has a third portion 51. The third portion 51 is a metallic region provided so as to face the second portions 12. That is, the third portion 51 extends in the Z-axis direction, and also extends in the Y-axis direction. Because of this, the third portion 51 is disposed so as to face the second portions 12 at a predetermined interval. The first electrode 50 having the third portion 51 is provided separated from the first semiconductor region 10.

In the semiconductor device 110 illustrated in FIGS. 1 and 2, a third portion 51 is disposed between the two second portions 12 (at the center, for example). Thereby, the third portion 51 is provided so as to face both one of the two second portions 12 and the other of the two second portions 12.

An end portion 51a at the lower side of the third portion 51 is separated from the first major surface 10a of the first portion 11. As shown in FIG. 1, in the semiconductor device 110 of the embodiment, an intermediate electrode 52 is connected to an end portion 51b at an upper side of the third portion 51. The intermediate electrode 52 is in conduction with the third portion 51, and is provided along an X-Y plane. A second insulating film 82 is provided between the intermediate electrode 52 and the second portion 12. A first insulating film 81 is provided as necessary between the second semiconductor region 20 and the second insulating film 82. An upper electrode 53 is provided to a predetermined thickness along the X-Y plane on this intermediate electrode 52.

For example, the intermediate electrode 52 is made up of the same material as the third portion 51 and is integrally provided therewith. For example, a stacked film of W (tungsten)—Al (aluminum), a stacked film of W—Ni (nickel)—Au, or stacked films using Mo (molybdenum), Pt (platinum), TiW (titanium, tungsten alloy), V (vanadium), Ti (titanium), or the like in place of W in the above stacked films may be used for the intermediate electrode 52 and the third portion 51. A material which eases a connection with an external wiring (including a wiring pattern) is used for the upper electrode 53. For example, Al is used for the upper electrode 53.

The first electrode 50, which has the third portion 51, the intermediate electrode 52 and the upper electrode 53, functions as an anode electrode of the Schottky barrier diode.

A second semiconductor region 20 is provided between the second portion 12 and the third portion 51. The second semiconductor region 20 has a first concentration region 21 whose impurity concentration is lower than a concentration in the first semiconductor region 10. In the semiconductor device 110 illustrated in FIGS. 1 and 2, the entire second semiconductor region 20 is the first concentration region 21. For example, the second semiconductor region 20 is an n-type epitaxial layer of Si (silicon).

The second semiconductor region 20 forms a Schottky junction with the third portion 51.

The second electrode 60 is provided in the first portion 11 on the opposite side of the first major surface 10a. For example, the second electrode 60 is provided on an entire surface on the lower side of the first portion 11. A stacked film of, for example, Ti—Ni—Au is used for the second electrode 60. The foregoing second electrode 60 functions as a cathode electrode of the Schottky barrier diode.

An arrow shown in FIG. 1 indicates the direction of current schematically. In the semiconductor device 110, when a voltage (positive potential) higher than the voltage applied to the second electrode 60 is applied to the first electrode 50, a current flows from the upper electrode 53 through the intermediate electrode 52 into the third portion 51 that extends in the Z-axis direction. The current flowing into the third portion 51 flows into the second semiconductor region 20 that forms a Schottky junction with the third portion 51. In the semiconductor device 110 shown in FIG. 1, the current flows into the second portion 12 on both sides in the X-axis direction having the third portion 51 at the center. Then, the current flowing into the second portion 12 flows from the first portion 11 into the second electrode 60.

According to the foregoing semiconductor device 110, the longer (deeper) the length (depth) in the Z-axis direction of the third portion 51 becomes, the larger an area of the Schottky barrier face between the third portion 51 and the second semiconductor region 20 becomes. Furthermore, a contact area between the second semiconductor region 20 and the second part 12 in which the current flows also becomes larger. Therefore, it is possible to realize a reduction in forward voltage drop in the Schottky barrier diode (hereinafter referred to as “VF”).

Here, in the case where Ti, V or the like having a small work function φB is used as a material for the third portion 51 out of W, Mo, Pt, TiW, V, Ti, or the like, a reverse power loss (off loss) caused by a leak current (hereinafter referred to as “IR”) is easy to increase. In the case of using the foregoing material, the application in which a reduction in VF is more emphasized than an increase in IR (for example, for preventing reverse junction) is preferable.

In contrast, in the case of using Mo, W or the like having a large work function φB, the application in which IR can be suppressed even at high temperatures, for example, application for a switch power is preferable.

Moreover, in the application for a high breakdown voltage, since the specific resistance in the second semiconductor region 20 becomes relatively larger, the depletion layer is easy to extend into the second semiconductor region 20, which in turn makes it possible to suppress an electric field on the Schottky barrier side so as to be small. Thereby, the increase in IR can be suppressed.

Furthermore, the electric field is easy to be concentrated in a vicinity of the lower end portion 51a of the third portion 51. Therefore, IR is easy to be larger in a vicinity of the end portion 51a and the breakdown voltage is also decreased. For this reason, the electric field relaxation region 70 (first electric field relaxation region) may be provided between the end portion 51a of the third portion 51 and the first portion 11.

In the example shown in FIGS. 1 and 2, the electric field relaxation region 70 is provided in the vicinity of the end portion 51a.

As the electric field relaxation region 70, for example, the semiconductor region of the second conductivity type is used. By using the semiconductor region of the second conductivity type as the electric field relaxation region 70, it is possible to relax the concentration of the electric field at the end portion 51a and improve the breakdown voltage. Moreover, the Schottky barrier face can be eliminated from the portion where the electric field relaxation region 70 is provided, which in turn makes it possible to suppress IR.

Moreover, in the case of using the semiconductor region of the second conductivity type as the electric field relaxation region 70, the portion where a breakdown occurs when applying the reverse voltage can be made in the electric field relaxation region 70. In this case, it is possible to cause the generated electrons to flow into the first portion 11 directly below the electric field relaxation region 70 and the second portions 12 on both side, and to cause the holes to flow into the third portion directly above the electric field relaxation region 70. Thereby, the discharge resistance in the electrons and the holes can be reduced, and a reverse-serge tolerated dose can be improved.

A semiconductor region of the first conductivity type having a specific resistance higher than a specific resistance in the second semiconductor region 20 may be used as the electric field relaxation region 70. By using the semiconductor region of the first conductivity type as the electric field relaxation region 70, a resistance higher than a resistance in other Schottky barrier face can be obtained, which in turn makes it possible to relax the concentration of the electric field. Thereby, IR at the end portion 51a can be suppressed.

In the case of using the semiconductor region of the first conductivity type as the electric field relaxation region 70, the portion where a breakdown occurs when applying the reverse voltage can be made in the electric field relaxation region 70. In this case, the reverse-serge tolerated dose can be improved as in the case of the above example.

Here, in the semiconductor device 110 according to the embodiment, since the breakdown voltage can be improved, the portion where a breakdown occurs when applying the reverse voltage may be provided outside the electric field relaxation region 70.

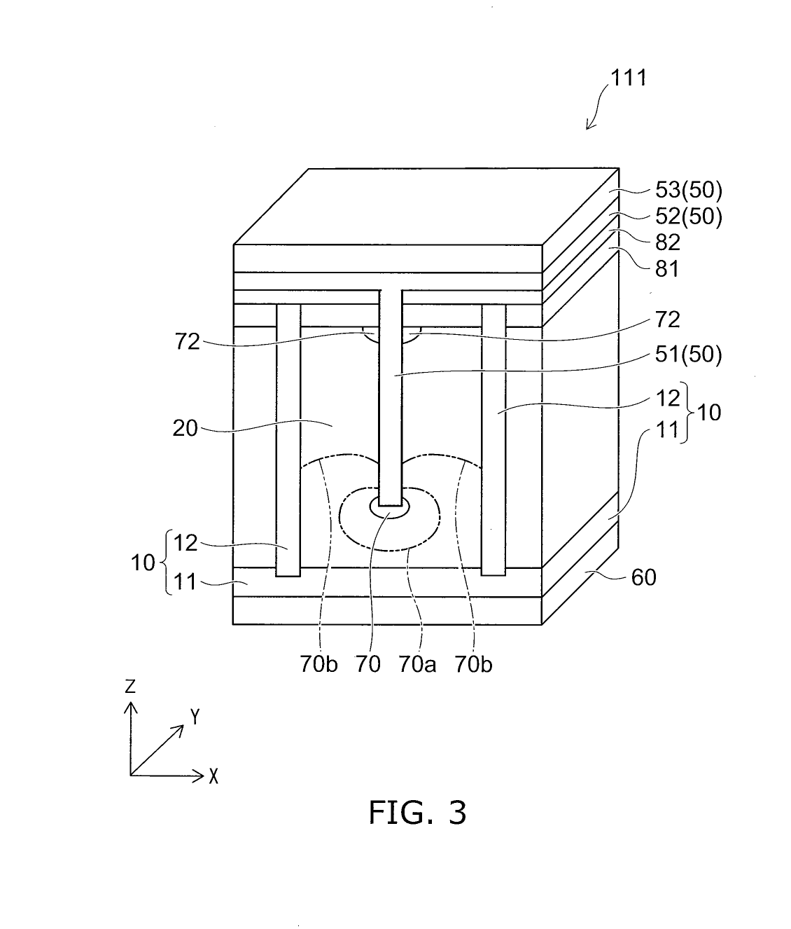

FIG. 3 is a schematic perspective view illustrating another example of the semiconductor device according to the first embodiment.

In a semiconductor device 111 shown in FIG. 3, a semiconductor region 72 of the second conductivity type (a second electric field relaxation region) is provided in an upper part of an interface between the third portion 51 and the second semiconductor region 20. Providing the foregoing semiconductor region 72 makes it possible to function as the electric field relaxation region, and when applying a reverse voltage, IR in a vicinity of the semiconductor region 72 can be suppressed. Moreover, it may be arranged such that a breakdown occurs when applying the reverse voltage in the electric field relaxation region 72. Thereby, the reverse-serge tolerated dose can be improved as in the case of the above. Incidentally, the semiconductor region 72 may be provided in a portion other than the upper portion of the interface between the third portion 51 and the second semiconductor region 20.

The semiconductor device 111 may be provided with the electric field relaxation region 70a. The electric field relaxation region 70a is larger in size than the electric field relaxation region 70. The electric field relaxation region 70a is provided so as to surround the lower side and the side surface of the end portion 51a of the third portion 51 within the first concentration region 21. For example, the electric field relaxation region 70a extends along the X-axis from the end portion 51a to a vicinity of the second portion 12. Furthermore, the electric field relaxation region 70a extends along the Z-axis from the end portion 51a to a vicinity of the first portion 11.

In the semiconductor device 111, since the electric field relaxation region 70a is provided, the electric field at the end portion 51a of the third portion 51 is relaxed, and the breakdown voltage can be made higher.

Moreover, the semiconductor device 111 may be provided with the electric field relaxation region 70b. The electric field relaxation region 70b is larger in size than the electric field relaxation region 70a. The electric field relaxation region 70b extends from the end portion 51a to the second portion 12 along the X-axis within the first concentration region 21. Furthermore, the electric field relaxation region 70a extends from the end portion 51a to the first portion 11 along the Z-axis.

When the electric field relaxation region 70b is the first conductivity type, the impurity concentration profile between the end portion 51a and the second portion 12 and the impurity concentration profile between the end portion 51a and the first portion 11 in the electric field relaxation region 70b change continuously from the end portion 51a to the first portion 11 and the second portion 12, respectively.

In the semiconductor device 111, since the electric field relaxation region 70b is provided, the electric field at the end portion 51a of the third portion 51 is further relaxed as compared with the case where the electric field relaxation region 70a is provided, and the semiconductor device 111 having a high breakdown voltage can be provided.

Here, the semiconductor device 111 may be provided with at least one of the electric field relaxation regions 70, 70a and 70b. That is, the semiconductor device 111 may be provided with any one of the electric field relaxation regions 70, 70a and 70b, or two or more in combination.

In the case where the second portion 12 is the n⁺-type, and the second semiconductor region 20 is the n-type, the impurity concentrations of the electric field relaxation regions 70, 70a and 70b are as follows:

The electric field relaxation region 70 can be any one of the p-type, p⁻-type and the n⁻-type.

The electric field relaxation region 70a can be any one of the p-type, p⁻-type and the n⁻-type.

The electric field relaxation region 70b can be any one of the p⁻-type and the n⁻-type.

To improve the breakdown voltage, preferable examples of the combinations of the impurity concentrations of the electric field relaxation regions 70, 70a and 70b are as follows:

(1) The electric field relaxation region 70a is the p-type, and the electric field relaxation region 70b is the n⁻-type.

(2) The electric field relaxation region 70 is the p-type, the electric field relaxation region 70a is the p⁻-type, and the electric field relaxation region 70b is the n⁻-type.

Additionally, in the case where the second portion 12 is the n⁺-type, and the second semiconductor region 20 is the n-type, any one of the p-type, p⁻-type and the n⁻-type can be adopted for the impurity concentration in the semiconductor region 72. Any one of these impurity concentrations makes it possible to relax the electric field in a vicinity of an interface between the third portion 51 and the first insulating film 81 by providing the semiconductor region 72.

### Second Embodiment

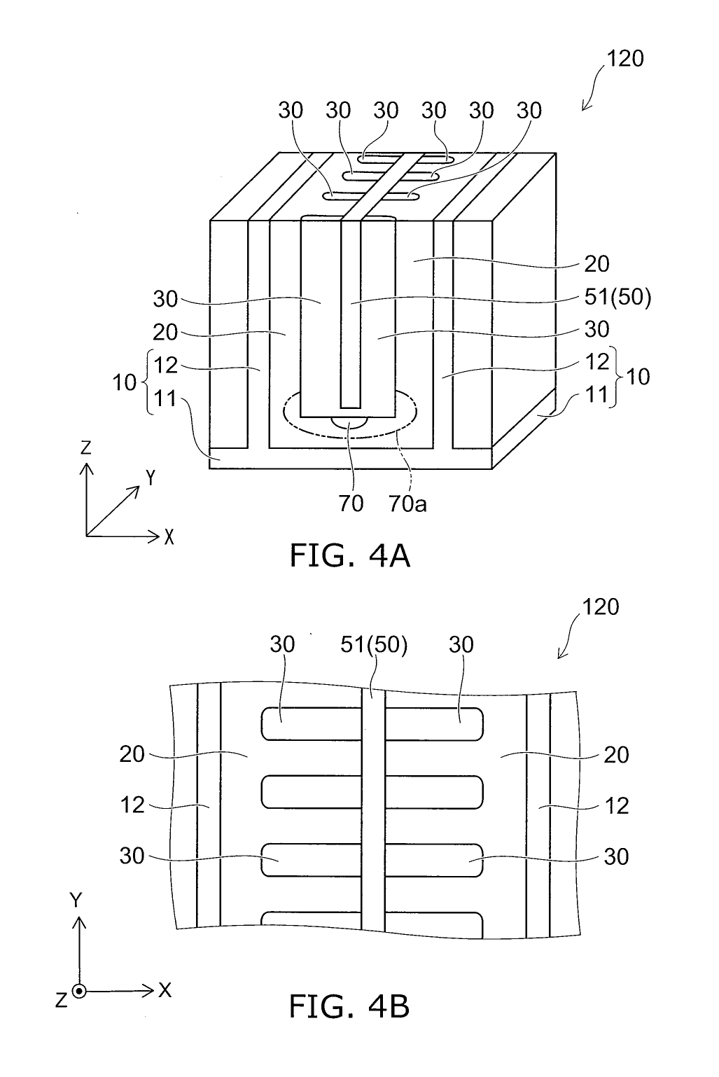

FIGS. 4A and 4B are schematic views illustrating the configuration of a semiconductor device according to a second embodiment.

The FIG. 4A is a schematic perspective view showing a part of the semiconductor device. FIG. 4B is a plan view of a part of the semiconductor device. As shown in FIG. 4A, the first insulating film 81, the second insulating film 82, the intermediate electrode 52 and the upper electrode 53 are omitted.

As shown in FIGS. 4A and 4B, a semiconductor device 120 according to the second embodiment further includes a third semiconductor region 30 of the second conductivity type that extends in the X-axis direction from the third portion 51 in addition to the configuration of the semiconductor device 110 according to the first embodiment.

The third semiconductor region 30 extends in the X-axis direction and extends also in the Z-axis direction. The third semiconductor region 30 is in conduction with the first electrode 50. In the semiconductor device 120 shown in FIGS. 4A and 4B, a plurality of third semiconductor regions 30 are provided at a predetermined interval in the Y-axis direction. In the semiconductor device 120, for example, the third semiconductor region 30 is a semiconductor pillar of the p-type. That is, the semiconductor device 120 is a MPS in which a plurality of p-type semiconductor pillars are provided along the Schottky barrier face. The third semiconductor region 30 may be polysilicon (polycrystalline silicon) of the p-type.

The semiconductor device 120 may be provided with the electric field relaxation regions 70 and 70a as in the semiconductor device 111. The electric field relaxation region is provided in an interface portion with the third semiconductor region 30 within the second semiconductor region 20.

The electric field relaxation region 70a is provided so as to surround the lower side and the side surface of the third semiconductor region 30 within the second semiconductor region 20.

Since the electric field relaxation regions 70 and 70a are provided, the electric field at the lower portion of the third semiconductor region 30 is relaxed, and the breakdown voltage can be made higher.

As shown in FIG. 4B, when the semiconductor device 120 is seen in the Z-axis direction, the third semiconductor region 30 extends from the interface (Schottky barrier face) between the third portion 51 and the second semiconductor region 20 in the X-axis direction. When the reverse voltage is applied to the semiconductor device 120, respective depletion layers that extend in the interface between the semiconductor region 30 and the second semiconductor region 20 are pinched off one another at a low voltage. Thereby, an increase in electric field in the Schottky barrier face can be suppressed and IR can be suppressed, while improving the breakdown voltage.

Furthermore, to an extend that the breakdown voltage can be improved, it is possible to reduce the specific resistance in the second semiconductor region 20 and reduce the VF. Furthermore, since the IR can be suppressed, a material with a small φB can be used. By adopting such material, it is possible to realize a further reduction in VF.

Generally, in the planar type MPS, a current flows into the n-type layer sandwiched between a plurality of p-type layers formed on the Schottky barrier face. Therefore, if the n-type layer becomes narrower thereby of miniaturization, an increase in VF is liable to occur. Furthermore, when the p-type layer is made narrower for the miniaturization, it is necessary to set the specific resistance in the n-type layer high in order to suppress a reduction in breakdown voltage. Thereby, an increase in VF is caused.

In contrast, according to the embodiment, since an area of the Schottky barrier face increases as compared with the planar MPS, it is possible to reduce VF even when the p-type layer (third semiconductor region 30) has the same width.

In the semiconductor device 120, charge balance between the second semiconductor region 20 and the third semiconductor region 30 may be unbalanced. For example, an impurity concentration in the third semiconductor region is set higher than (for example, 2 to 5 times) an impurity concentration in the second semiconductor region 20. Thereby, when the reverse voltage is applied, the second semiconductor region 20 is easier to be depleted than the third semiconductor region 30. Therefore, the electric field between the third portion 51 and the second semiconductor region 20 can be suppressed to be low and a high voltage leak current can be reduced.

### Third Embodiment

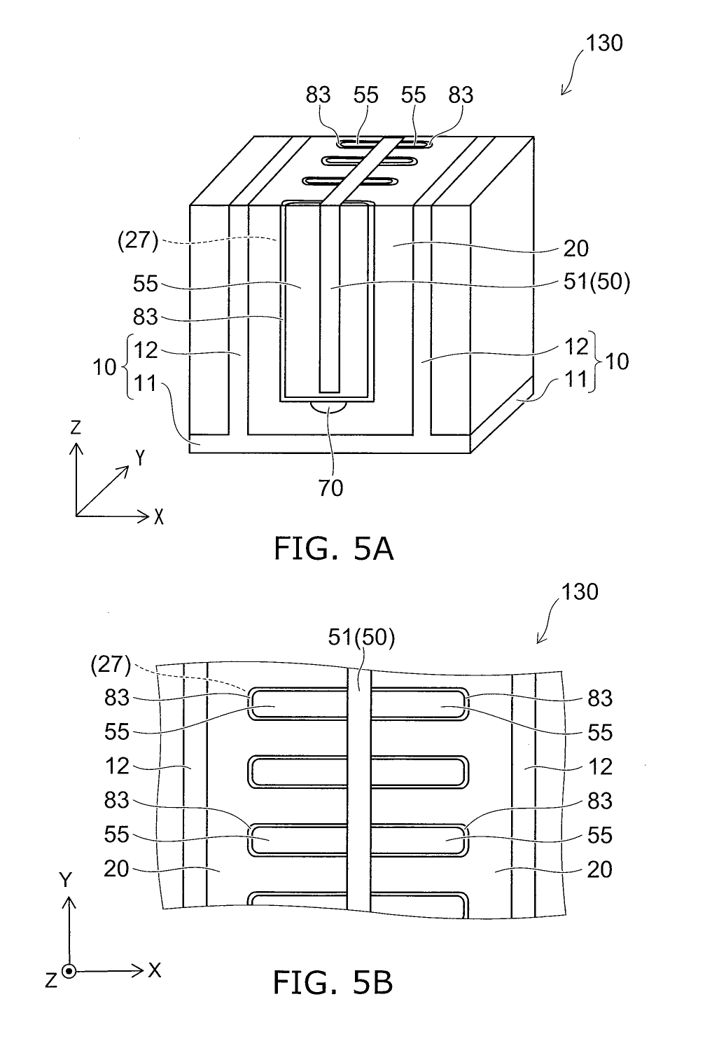

FIGS. 5A and 5B are schematic views illustrating the configuration of a semiconductor device according to a third embodiment.

FIG. 5A is a schematic perspective view of a part of the semiconductor device. FIG. 5B is a plan view of a part of the semiconductor device.

As shown in FIGS. 5A and 5B, a semiconductor device 130 according to a fifth embodiment further includes a fourth portion 55 and a third insulating film 83 in addition to the configuration of the semiconductor device 110 according to the first embodiment. The fourth portion 55 is a portion provided as the first electrode 50, and extends from the third portion 51 in the X-axis direction. The fourth portion 55 extends in the X-axis direction and also extends in the Z-axis direction. The fourth portion 55 is formed of an electrically conductive material. The fourth portion 55 is a part of the first electrode 50. Therefore, the fourth portion 55 is in the same potential as other parts of the first electrode 50 (for example, the third portion 51). In the semiconductor device 130 shown in FIGS. 5A and 5B, a plurality of fourth portions 55 are provided at a predetermined interval in the Y-axis direction. The third insulating film 83 is provided between the fourth portion 55 and the second semiconductor region 20. In the semiconductor device 130, a so-called MOS (Metal Oxide Semiconductor) structure is formed from the fourth portion 55, the third insulating film 83, and the second semiconductor region 20. That is, the semiconductor device 130 is a TMBS (Trench MOS Barrier Schottky) in which the plurality of MOS structures are provided along the Schottky barrier face. In the semiconductor device 130, a fourth semiconductor region 27 of the second conductivity type may be provided on a side of the third insulating film 83 of the second semiconductor region 20.

As shown in FIG. 5B, when the semiconductor device 130 is seen in the Z-axis direction, the fourth portion 55 and the third insulating film 83 extend in the X-axis direction from the interface (Schottky barrier face) between the third portion 51 and the second semiconductor region 20. When the reverse voltage is applied to the semiconductor device 130, respective depletion layers that extend in the interface between the third insulating film 83 and the second semiconductor region 20 are pinched off one another at a low voltage. Thereby, it is possible to suppress an increase in electric field in the Schottky barrier face and to suppress the IR, while improving the breakdown voltage.

In the semiconductor device 130, the specific resistance in the second semiconductor region 20 can be reduced to be lower than the specific resistance in the semiconductor device 120. Thereby, the specific resistance in the second semiconductor region 20 in the semiconductor device 130 can be reduced to be lower than the specific resistance in the semiconductor device 120, and a further reduction in VF can be achieved. Because of a reduction in the specific resistance in the second semiconductor region 20, φB decreases by the Schottky lowering effect on the Schottky barrier face. Therefore, it is preferable that a material with a relatively large φB (for example, Mo with φB=0.67 volt (V)) is used for the third portion 51.

### Fourth Embodiment

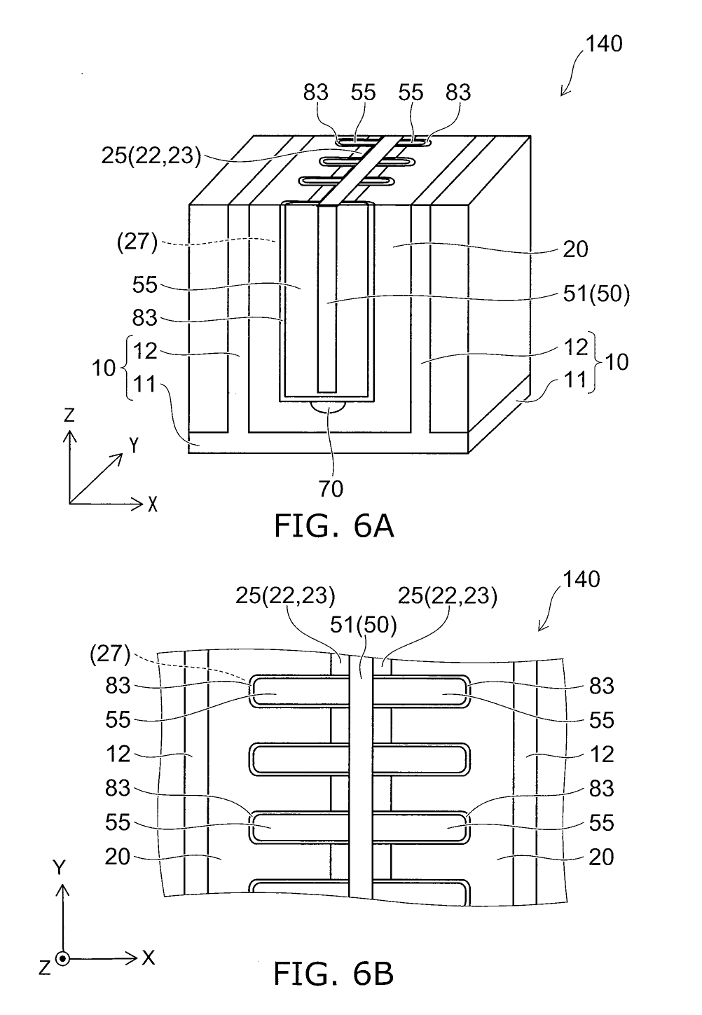

FIGS. 6A and 6B are schematic views illustrating the configuration of a semiconductor device according to a fourth embodiment.

FIG. 6A is a schematic perspective view showing a part of the semiconductor device. FIG. 6B is a plan view of a part of the semiconductor device.

As shown in FIGS. 6A and 6B, a semiconductor device 140 according to the fourth embodiment includes a concentration adjustment region 25 between the first concentration region 21 and the third portion 51 in the second semiconductor region 20 in addition to the configuration of the semiconductor device 130 according to the third embodiment.

There are the cases where the concentration adjustment region 25 is a second concentration region 22 with an impurity concentration lower than an impurity concentration in the first concentration region 21 and the case where the concentration adjustment region 25 is a third concentration region 23 with an impurity concentration higher than the impurity concentration in the first concentration region 21.

In the case where the second concentration region 22 is provided as the concentration adjustment region 25, it is possible to reduce the Schottky lowering effect by increasing the resistance in a vicinity of the Schottky barrier face. Thereby, as compared with the case where the second concentration region 22 is not provided, respective depletion layers are pinched off one another at a lower voltage, and it is possible to relax the electric field at the Schottky barrier face. Therefore, a reduction in IR can be achieved even when a material with a relatively low φB such as V or the like is used as a material of the third portion 51.

Moreover, in the case where the third concentration region 23 is provided as the concentration adjustment region 25, it is possible to reduce VF by reducing the resistance in a vicinity of the Schottky barrier face. Here, in the case of using the third concentration region 23, it is possible to reduce φB by the Schottky lowering effect as compared with the case of using the second concentration region 22. However, by using a material with a relatively large φB (for example, Mo with φB=0.67 volt (V)) for the third portion 51, it is possible to suppress IR.

### Fifth Embodiment

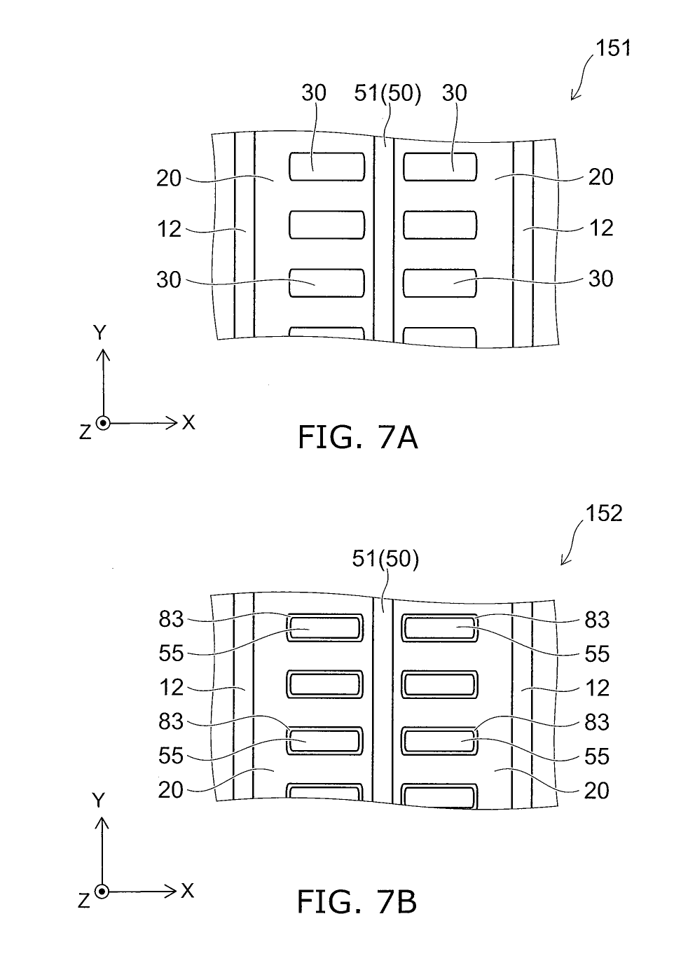

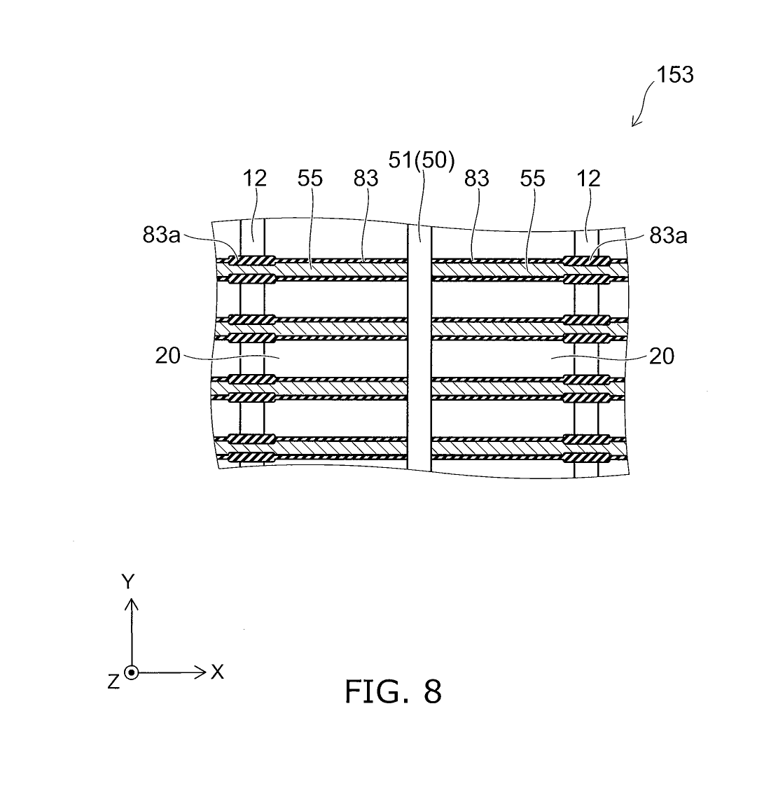

FIGS. 7A and 7B and 8 are schematic plan views illustrating the configuration of semiconductor devices according to a fifth embodiment.

Any of the above figures illustrates the state of a part of the semiconductor device when seen in the Z-axis direction.

FIG. 7A illustrates a semiconductor device 151 according to the fifth embodiment (first example). FIG. 7B illustrates a semiconductor device 152 according to the fifth embodiment (second example). FIG. 8 illustrates a semiconductor device 153 according to the fifth embodiment (third example).

In the semiconductor device 151 according to the fifth embodiment (first example) shown in FIG. 7A, the third semiconductor region 30 provided between the third portion 51 and the second portion 12 is provided so as to be separated from the third portion 51.

As described above, in the case where the third semiconductor region 30 is provided so as to be separated from the third portion 51, as compared with the case where the third semiconductor region 30 is in contact with the third portion 51, an area of the interface (Schottky barrier face) between the third portion 51 and the second semiconductor region 20 increases. Thereby, it is possible to reduce VF.

In the semiconductor device 152 according to the fifth embodiment (second example) shown in FIG. 7B, the fourth part 55 and the third insulating film 83 provided between the third portion 51 and the second portion 12 are provided so as to be separated from the third portion 51.

Therefore, when the fourth portion 55 and the third insulating film 83 are provided so as to be separated from the third portion 51, an area of the interface (Schottky barrier face) between the third portion 51 and the second semiconductor region 20 increases as compared with the case where the fourth portion 55 and the third insulating film 83 are in contact with the third portion 51. Thereby, VF can be reduced.

Additionally, for example, in the case of performing manufacturing process of providing the trench for forming the third portion 51 after forming the fourth portion 55 and the third insulating film 83, the etching for forming the trench is carried out only in the second semiconductor region 20. Thereby, etching conditions are simplified, and a trench can be formed with ease.

Moreover, in the semiconductor device 153 according to the fifth embodiment (third example) shown in FIG. 8, the fourth portion 55 and the third insulating film 83 that extend in the X-axis direction from the third portion 51 reach the second portion 12 that faces the third portion 51. With the foregoing configuration, it is possible to form in a lump the fourth portion 55 and the third insulating film 83 in the X-axis direction.

That is, when forming the fourth portion 55 and the third insulating film 83, first, a trench that penetrates the second semiconductor region 20 and the plurality of second portions 12 in the X-axis direction is formed. After that, a third insulating film 83 is formed on the inner wall surface of the trench. Then, a material of the fourth portion 55 is buried in the trench.

In the foregoing semiconductor device 153, when applying a voltage in a forward direction, a storage layer of electrons is formed on the side of the third insulating film 83 of the second semiconductor region 20, and it is possible to cause a current to flow from the third portion 51 into the second portion 12 at low resistance. Thereby, it is possible to reduce VF.

Additionally, with respect to the width of the third insulating film 83 along the Y-axis direction, the width of the region 83a in a vicinity of the portion overlapping with the second portion 12 is made larger than the width of other regions. That is, when forming the third insulating film 83 by thermal oxidation, since the impurity concentration in the second portion 12 is high, the portion in contact with the second portion 12 is oxidized to a large extent. This portion serves as the region 83a, so as to have a width larger than a width of other regions. As described above, since the thickness of the oxidized film in the area 83a is large, it is possible to bear the electric field in a vicinity of the second portion 12 in which the concentration of the electric field is easy to occur, thereby improving the breakdown voltage.

### Sixth Embodiment

A sixth embodiment relates to a method of manufacturing a semiconductor device.

First, an example of a manufacturing method of the semiconductor device 110 is explained.

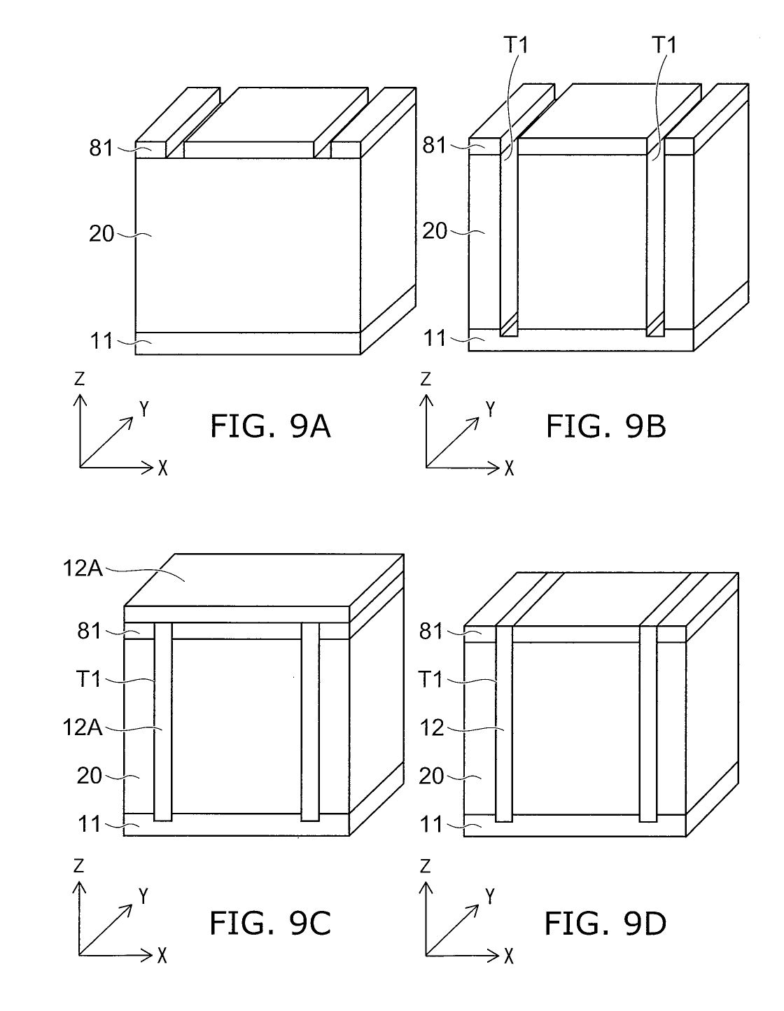

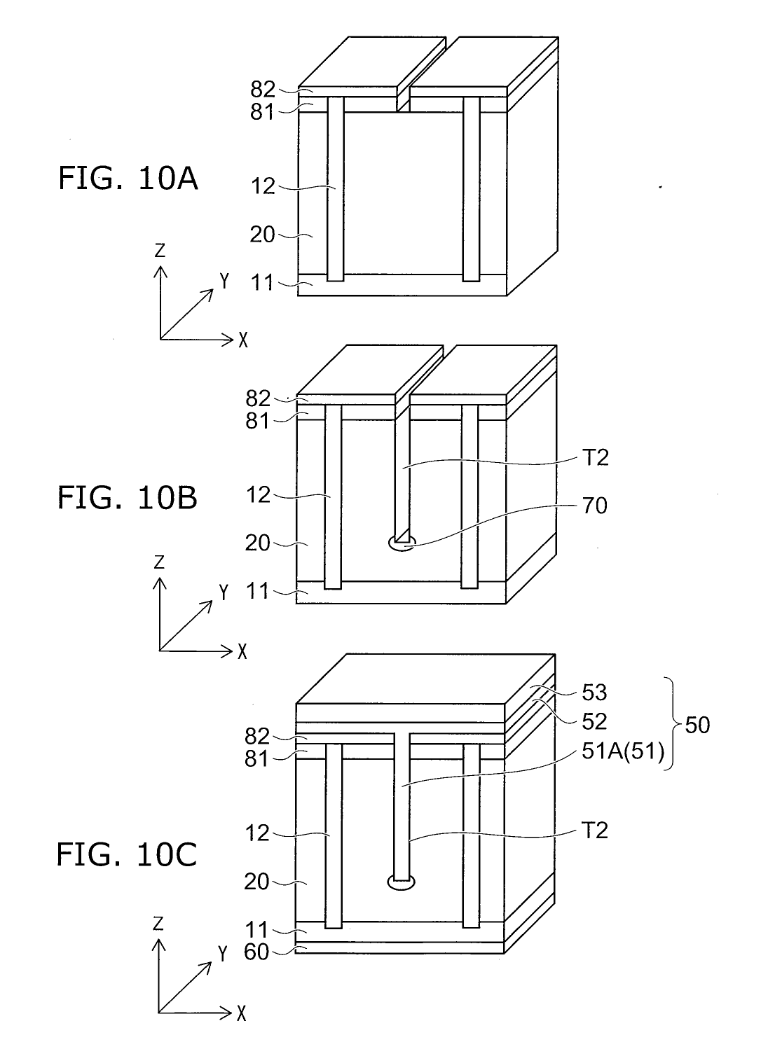

FIGS. 9A to 10C are schematic perspective views describing a method of manufacturing the semiconductor device.

First, as shown in FIG. 9A, on the first major surface 10a of the first portion 11 that is the first semiconductor region 10, for example, the second semiconductor region 20 is epitaxially grown. The first portion 11 is, for example, the n⁺-type silicon substrate. The second semiconductor region 20 is, for example, an n-type silicon epitaxial layer. Next, the first insulating film 81 is formed on the second semiconductor region 20, and an aperture is partially formed therein. For the first insulating film, for example, SiO₂ by the thermal oxidation is used.

Next, as shown in FIG. 9B, the second semiconductor region 20 and the first portion 11 are etched using the first insulating film 81 having the aperture, as a mask. As the etching, for example, RIE (Reactive Ion Etching) is used. Thereby, a trench T1 is formed at a depth reaching the middle of the first portion 11 from the second semiconductor region 20. Moreover, the trench T1 is formed so as to extend in the Y-axis direction.

Next, as shown in FIG. 9C, a second portion material 12A is buried in the trench T1. For example, polysilicon with a high impurity concentration is used as the second portion material 12A. The second portion material 12A is formed to cover the first insulating film 81.

Next, a part of the second portion material 12A is removed. Here, a portion of the second portion material 12A on the first insulating film 81 is removed until the aperture of the first insulating film 81 and the trench T1 is exposed. The second portion material 12A is removed, for example, by CMP (Chemical Mechanical Polishing). As shown in FIG. 9D, an exposed face of the first insulating film 81 and the second portion material 12A buried in the trench T1 is flattened. The second portion material 12A buried in the trench T1 serves as the second portion 12. The second portion 12 is, for example, an n⁺-type semiconductor pillar.

Next, as shown in FIG. 10A, the second insulating film 82 is formed on the first insulating film 81, and an aperture is formed in a part of the first insulating film 81 and the second insulating film 82. The aperture is formed between the two second portions 12 in the X-axis direction. For example, SiO₂ by the CVD (Chemical Vapor Deposition) is used for the second insulating film 82.

Next, as shown in FIG. 10B, the second semiconductor region 20 is etched by using the first insulating film 81 and the second insulating film 82 having the aperture, as a mask. For example, RIE is used as etching. Thereby, a trench T2 is formed in the second semiconductor region 20. The trench T2 is formed with a depth reaching the middle from above the second semiconductor region 20. Additionally, the trench T2 is formed so as to extend in the Y-axis direction.

After the trench T2 is formed, the electric field relaxation region 70 is formed in the second semiconductor region 20 in a vicinity of the bottom portion of the trench T2. For example, B (boron) is at an angle implanted into the bottom portion of the trench T2 by ion implantation to be thermally diffused. Thereby, the electric field relaxation region 70 is formed. The electric field relaxation region 70 is a semiconductor region of the first conductivity type whose impurity concentration is lower than an impurity concentration in the semiconductor region of the second conductivity type or the second semiconductor region 20.

Next, as shown in FIG. 10C, a third portion material 51A is buried in the trench T2. The third portion material 51A is, for example, a single layer of W, a stacked film of W and Al, a stacked film of Mo, Pt, TiW, V, Ti, or the like in place of W in the above stacked film, and Al. The stacked layered film used for the third portion material 51A can be a silicide layer that is an alloy with silicon. The third portion material 51A buried in the trench T2 serves as the third portion 51 that forms a Schottky junction with the second semiconductor region 20 by the sinter processing.

The third portion material 51A is formed to cover the second insulating film 82. This portion serves as the intermediate electrode 52. After that, the upper electrode 53 is formed on the intermediate electrode 52. For example, Al is used for the upper electrode 53. The first electrode 50 is formed, for example, from the third portion 51, the intermediate electrode 52 and the upper electrode 53.

Moreover, the second electrode 60 is formed under the first portion 11. For example, the second electrode 60 is a stacked film of Ti, Ni, and Au, a stacked film of Ti, Al, Cu, Ni and Au, and a stacked film of V, Al, Cu, Ni and Au.

Thereby, the semiconductor device 110 is completed. In the foregoing manufacturing method, the breakdown voltage can be controlled with ease by setting pitches in the X-axis direction of the adjoining trenches T1 or setting the specific resistance in the second semiconductor region 20. Moreover, the desired characteristics can be obtained with ease by controlling the depth of the trench T2 in which the third portion 51 is buried.

Next, another method of manufacturing the semiconductor device 110 is explained.

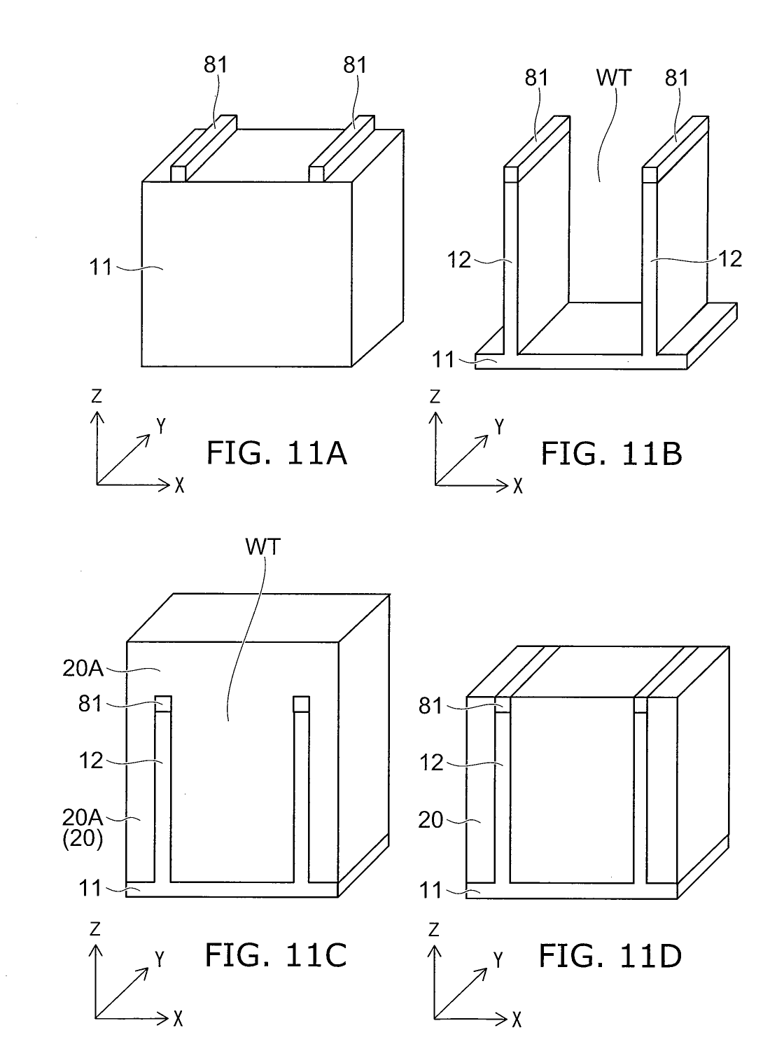

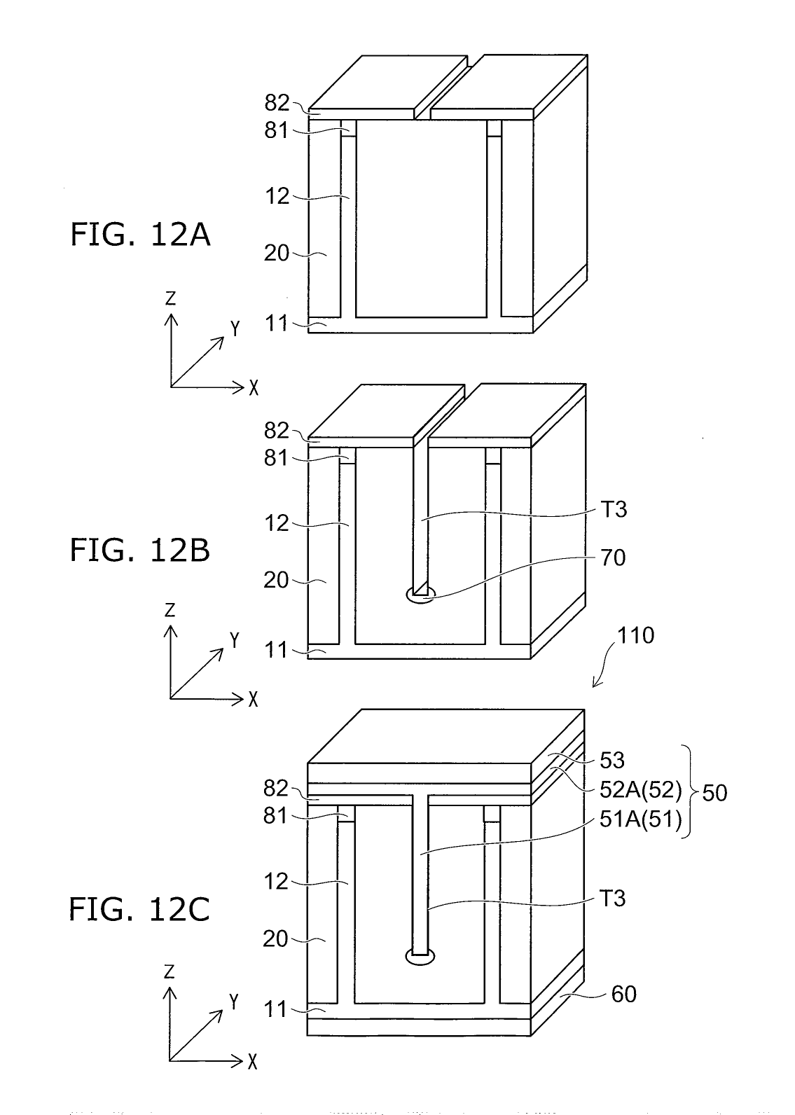

FIGS. 11A to 12C are schematic perspective views describing another method of manufacturing the semiconductor device.

First, as shown in FIG. 11A, the first insulating film 81 is formed on the first major surface 10a of the first portion 11 that is the first semiconductor region 10. For example, SiO₂ by the thermal oxidation is used for the first insulating film 81. Then, an aperture is partially formed in the first insulating film 81. When seen in the Z-axis direction, the portion where the first insulating film 81 is left is the portion where the second portion 12 is formed in the subsequent process.

Next, as shown in FIG. 11B, the first portion 11 is etched by using the first insulating film 81 remaining, as a mask. The part removed by this etching is defined to be a wide trench WT. In contrast, the part masked with the first insulating film 81 serves as the second portion 12 that extends from the first portion 11 in the Z-axis direction.

Next, as shown in FIG. 11C, the second semiconductor material 20A is, for example, epitaxially grown on the first portion 11. The second semiconductor material 20A is, for example, an n-type silicon. A second semiconductor material 20A is buried in a plurality of the second portions 12 on the first portion 11, i.e., in the wide trench WT. The second semiconductor material 20A buried in the wide trench WT serves as the second semiconductor region 20.

Next, a part of the second semiconductor material 20A is removed. Here, a portion of the second semiconductor material 20A is removed until the upper portion of the first insulating film 81 is exposed. The second semiconductor material 20A is removed, for example, by CMP. As shown in FIG. 11D, an exposed face of the first insulating film 81 and the second semiconductor region 20 is flattened.

Next, as shown in FIG. 12A, the second insulating film 82 is formed on the first insulating film 81 and the second semiconductor region 20 as formed flat, and an aperture is formed partially in the second insulating film 82. The aperture is formed between the two second portions 12 in the X-axis direction. For example, SiO₂ by the CVD is used for the second insulating film 82.

Next, as shown in FIG. 12B, the second semiconductor region 20 is etched by using the second insulating film 82 having the aperture, as a mask. For the etching, for example, RIE is used. Thereby, a trench T3 is formed with a depth reaching the middle from above the second semiconductor region 20. Moreover, the trench T3 is formed so as to extend in the Y-axis direction.

After the trench T3 is formed, the electric field relaxation region 70 is formed in the second semiconductor region 20 in a vicinity of the bottom portion of the trench T3. For example, B(boron) is at an angle implanted into the bottom portion of the trench T3 by ion implantation to be thermally diffused. Thereby, the electric field relaxation region 70 is formed. The electric field relaxation region 70 is a semiconductor region of the first conductivity type whose impurity concentration is lower than an impurity concentration in the semiconductor region of the second conductivity type and the second semiconductor region 20.

Next, as shown in FIG. 12C, the third portion material 51A is buried in the trench T3. The third portion material 51A is, for example, a single layer of W, a stacked layered film of W and Al, a stacked layered film of Mo, Pt, TiW, V, Ti, or the like in place of W in the above stacked layered film and Al. The stacked layered film used for the third portion material 51A can be a silicide layer that is an alloy with silicon. The third portion material 51A buried in the trench T3 serves as the third portion 51 that forms a Schottky junction with the second semiconductor region 20 by the sinter processing.

The third portion material 51A is formed to cover the second insulating film 82. This portion serves as the intermediate electrode 52. After that, on the intermediate electrode 52, the upper electrode 53 is formed. For the upper electrode 53, for example, Al is used. The first electrode 50 is formed, for example, from the third portion 51, the intermediate electrode 52, and the upper electrode 53.

Moreover, the second electrode 60 is formed under first portion 11. For example, second electrode 60 is a multilayer film of the multilayer film of Ti—Ni—Au, the multilayer film of Ti—Al—Cu—Ni—Au, and V—Al—Cu—Ni—Au.

Thereby, the semiconductor device 110 is completed.

In the foregoing manufacturing method, it is possible to control the breakdown voltage with ease by setting the width of the wide trench WT in the X-axis direction, or setting the specific resistance in the second semiconductor region 20. Moreover, the desired characteristics can be obtained with ease by controlling the depth of the wide trench WT and the depth of the trench T3 in which the third portion 51 is to be buried.

Next, one example of the method for manufacturing the semiconductor device 120 will be described.

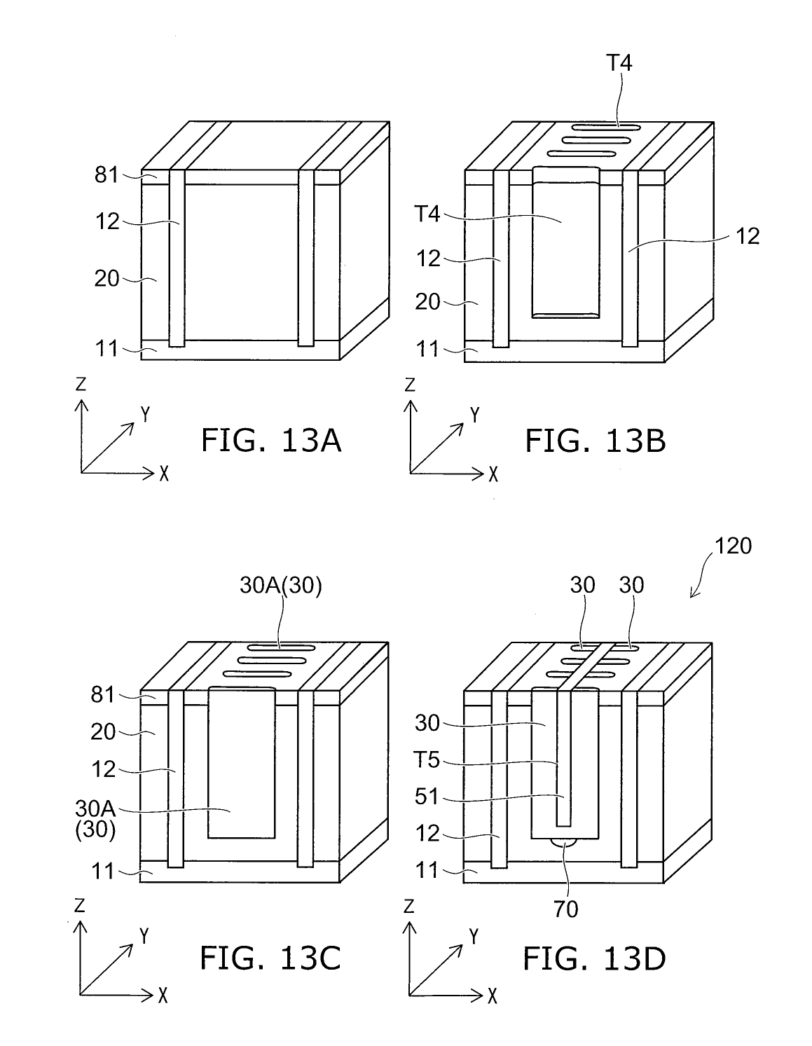

FIGS. 13A to 13D are schematic perspective views describing a method of manufacturing a semiconductor device.

First, as shown in FIG. 13A, the second portion 12 and the second semiconductor region 20 are formed on the first portion 11. This manufacturing method is the same as the manufacturing method illustrated in FIGS. 9A to 9D. The manufacturing method illustrated in FIGS. 11A to 11D may be adopted.

Next, as shown in FIG. 13B, a plurality of trenches T4 are formed in the second semiconductor region 20. The depth direction of the trench T4 is the Z-axis direction. The trench T4 extends in the X-axis direction. Thereby, the aperture of the trench T4 has a narrow and long shape. The trenches T4 are provided in a plurality at a predetermined interval in the Y-axis direction. The trenches T4 are formed, for example, by RIE to the second semiconductor region 20.

Next, the third semi-conducting material 30A of the second conductivity type is buried in the trench T4 as shown in FIG. 13C, and the third semiconductor region 30 is formed in the trench T4. The third semiconductor region 30 is, for example, a semiconductor pillar of the p-type.

Next, as shown in FIG. 13D, a trench T5 is formed in the third semiconductor region 30 and the second semiconductor region 20. The trench T5 is formed so as to be shallower than the depth of the third semiconductor region 30 in the Z-axis direction. The trench T5 is formed so as to extend over the plurality of third semiconductor regions 30 in the Y-axis direction. The trench T5 is formed in the second semiconductor region 20 and the third semiconductor region 30. After forming the trench T5, the electric field relaxation region 70 is formed in a vicinity of the bottom portion of the trench T5. Next, the third portion 51 is buried in the trench T5.

After that, the upper electrode 53 and the second electrode 60 not shown are formed. Thereby, the semiconductor device 120 is completed.

Next, one example of a method for manufacturing a semiconductor device 130 is explained.

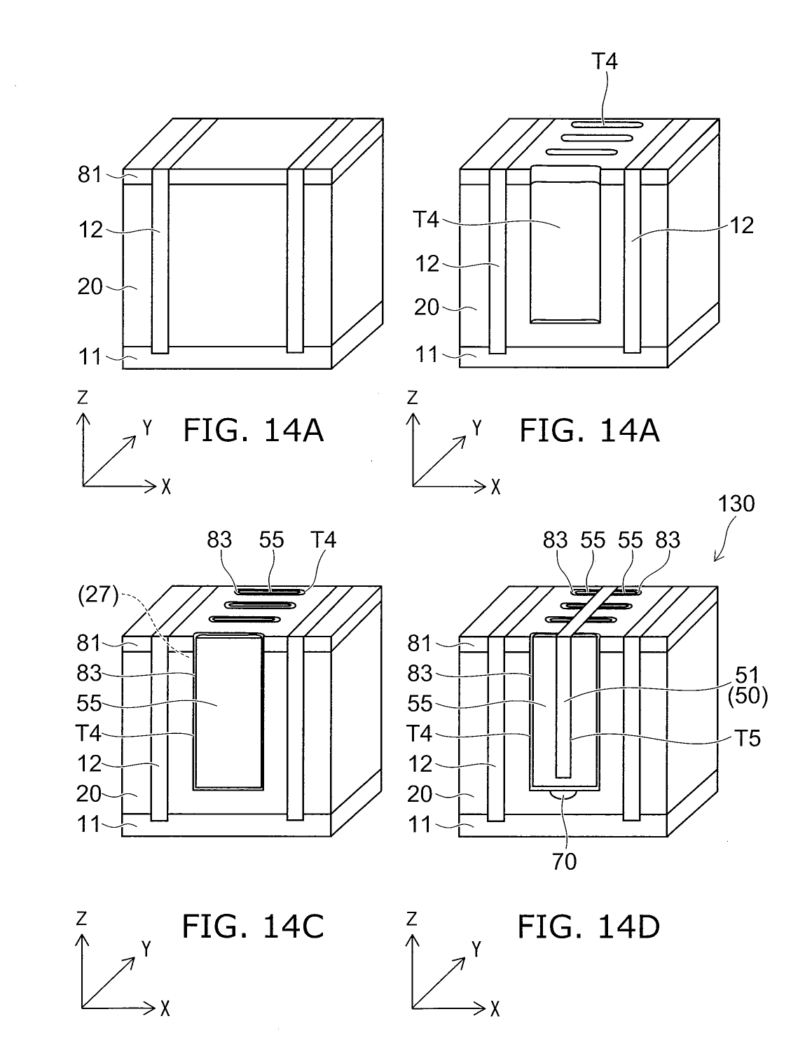

FIGS. 14A to 14D are schematic perspective views describing a method for manufacturing a semiconductor device.

First, as shown in FIG. 14A, the second portion 12 and the second semiconductor region 20 are formed on the first portion 11. This manufacturing method is the same as the manufacturing method illustrated in FIGS. 9A to 9D. The manufacturing method illustrated in FIGS. 11A to 11D may be adopted.

Next, as shown in FIG. 14B. a plurality of trenches T4 are formed in the second semiconductor region 20. The depth direction of the trench T4 is the Z-axis direction. The trench T4 extends in the X-axis direction. Thereby, the aperture of the trench T4 has a narrow long shape. The trenches T4 are provided in a plurality at a predetermined interval in the Y-axis direction. The trenches T4 are formed, for example, by RIE to the second semiconductor region 20.

Next, as shown in FIG. 14C, the third insulating film 83 is formed on the inner wall of the trench T4. For the third insulating film 83, for example, SiO₂, BSG (Boron Silicate Glass) or the like is used. After forming the BSG as the third insulating film 83, the p⁺-type layer may be formed by diffusing B by thermal diffusion, for example, to be thinner to the side of Si, i.e., the second semiconductor region 20. Thereby, the fourth semiconductor region 27 of the second conductivity type is provided on the side of the third insulating film 83 in the second semiconductor region 20. After that, an electrically conductive material serving as the fourth portion 55 is buried inside the trench T4.

Next, as shown in FIG. 14D, the trench T5 is formed in the fourth portion, the third insulating film 83 and the second semiconductor region 20. The trench T5 is formed shallower than the depth of the fourth portion 55 in the Z-axis direction. The trench T5 is formed so as to extend over the plurality of fourth portions and the third insulating film 83 in the Y-axis direction. The trench T5 is formed in the second semiconductor region 20, the third insulating film 83 and the fourth portion 55. After forming the trench T5, the electric field relaxation region 70 is formed in a vicinity of the bottom portion of the trench T5. Next, the third portion 51 is buried in the trench T5.

After that, the upper electrode 53 and the second electrode 60 not shown are formed. Thereby, the semiconductor device 130 is completed.

In the planar MPS, while the direction in which the p-type layer corresponding to the third semiconductor region 30 extends is the Z-axis direction, in the semiconductor device 130, the direction in which the third semiconductor region 30 extends is the X-axis direction. Therefore, when forming the third semiconductor region 30, a degree of freedom in shape along the X-Y plane is high. Therefore, as to the shape of the third semiconductor region 30 when seen in the Z-axis direction, it is possible to manufacture the third semiconductor region 30 having a complicated shape with ease, for example, by setting the width on the side closer to the Schottky barrier face to be wider or narrower than the width on the side distal from the Schottky barrier face, etc.

Moreover, it is possible to freely set the concentration in the third semiconductor region 30. That is, by stacking a plurality of thin epitaxial layers with different concentrations, it is possible to make the third semiconductor region 30 have a concentration gradient of the impurities.

Moreover, in the case of using the BSG as the third insulating film 83, it is possible to form the p⁺-type layer in the second semiconductor region 20 by solid phase diffusion of B and fill the inside of the p⁺-type layer with the third portion 51. By forming the p⁺-type layer (fourth semiconductor region 27) in a wide region of the second semiconductor region 20 in contact with the third insulating film 83, a depletion layer extends sufficiently when a reverse voltage is applied, which in turn makes it possible to reduce IR. Additionally, while it is necessary to from the p⁺-type layer in a wide region of the second semiconductor region 20 in contact with the third insulating film 83 to maximize the IR reduction effect, it is possible to form the p⁺-type layer with ease by using the BSG.

Moreover, in the case of using SiO₂ as the third insulating film 83, after forming the trench T5, a p⁺-layer (fourth semiconductor region 27) may be formed in the second semiconductor region 20 in contact with the SiO₂ by the vapor-phase diffusion of the p-type impurity, or by implanting B or the like at an angle into a side wall of the trench T4 by ion implantation.

Next, another manufacturing method of the semiconductor device 140 will be described.

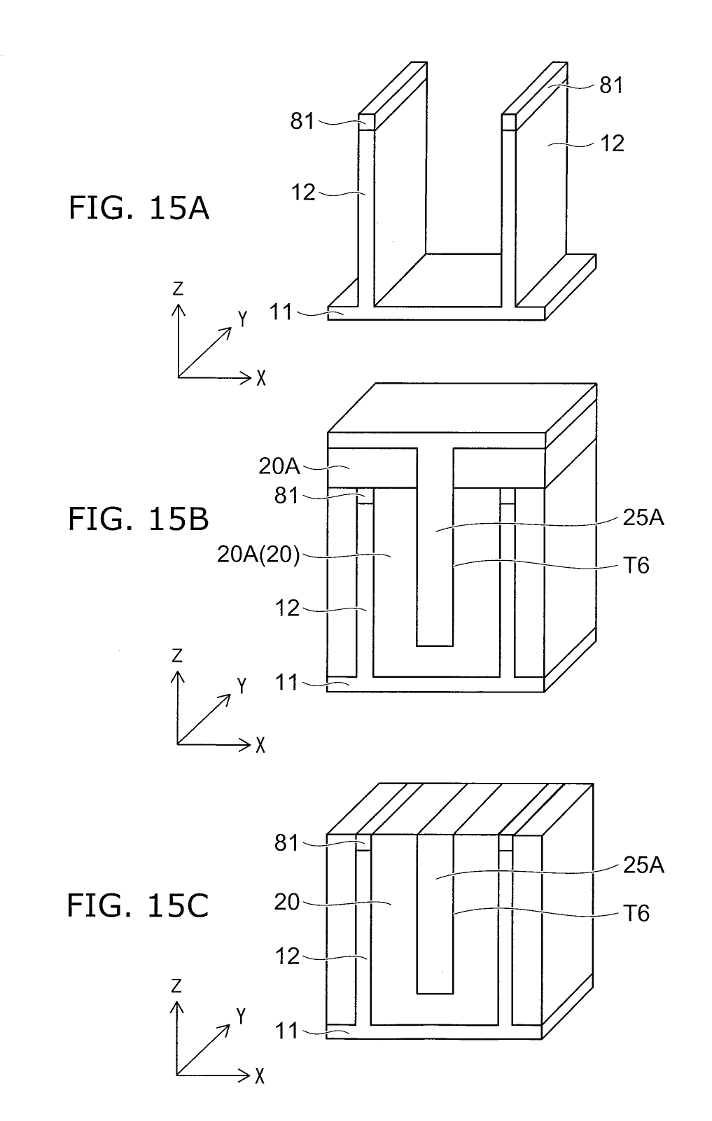

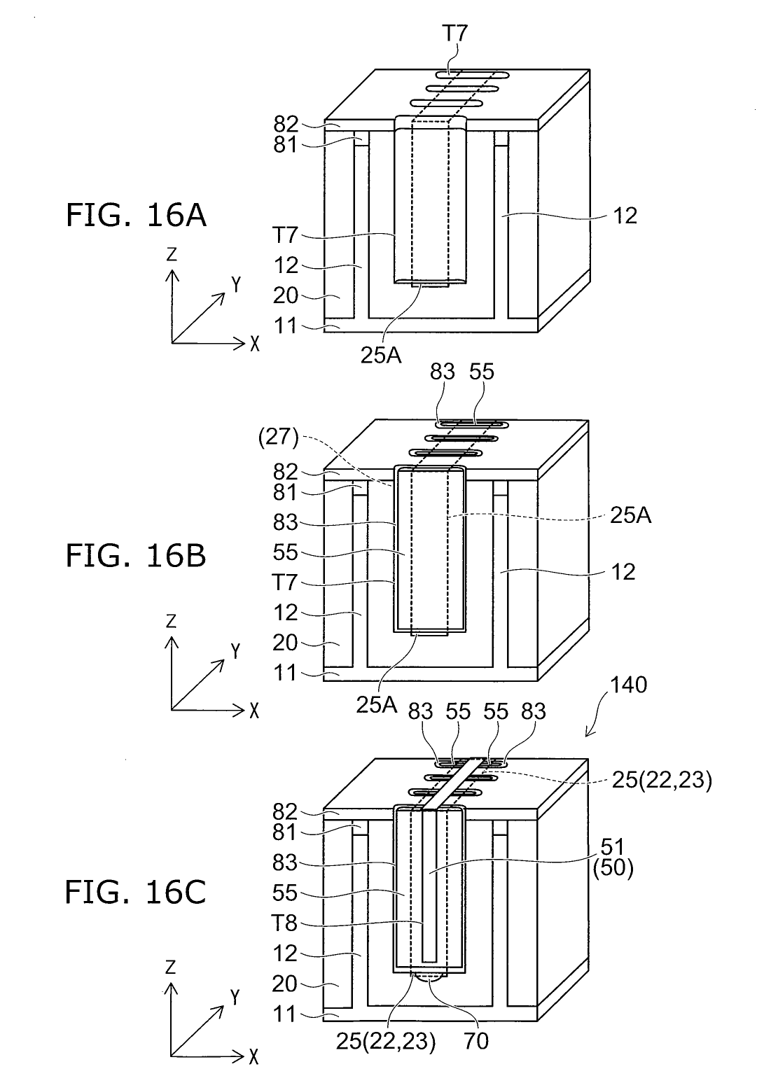

FIGS. 15A to 16C are schematic perspective views describing a method of manufacturing the semiconductor device.

First, as shown in FIG. 15A, the second portion 12 that extends in the Z-axis direction is formed on the first portion 11. This manufacturing method is the same as the manufacturing method illustrated in FIGS. 11A and 11B.

Next, as shown in FIG. 15B, the second semiconductor material 20A is, for example, epitaxially grown on the first portion 11. The second semiconductor material 20A is, for example, the n-type silicon. The second semiconductor material 20A is buried in the plurality of the second portions 12 on the first portion 11. The second semiconductor material 20A buried in the plurality of second portions 12 serves as the second semiconductor region 20. Then, a trench T6 is formed in the second semiconductor region 20, and a concentration adjustment material 25A is buried in the trench T6. The concentration adjustment material 25A is a material to be formed in the second concentration region 22 having an impurity concentration lower than the impurity concentration in the first concentration region 21. A material serving as the third concentration region 23 having the impurity concentration higher than the impurity concentration in the first concentration region 21 may be used as the concentration adjustment material 25A.

Next, a part of the concentration adjustment material 25A is removed. Here, the concentration adjustment material 25A is removed to an extent that upper portions of the second semiconductor region 20 and the concentration adjustment material 25A in the trench T6 are exposed. The concentration adjustment material 25A is removed, for example, by the CMP. As shown in FIG. 15C, the exposed surfaces of the first insulating film 81, the second semiconductor region 20 and the concentration adjustment material 25A are flattened.

Then, as shown in FIG. 16A, a plurality of trenches T7 are formed in the second semiconductor region 20 and the concentration adjustment material 25A. The depth direction of the trench T7 is the Z-axis direction. The depth of the trench

T7 is slightly shallower than the depth of the concentration adjustment material 25A. Moreover, the trench T7 extends in the X-axis direction. Thereby, an aperture of the trench T7 has a narrow and long shape. Moreover, the trenches T7 are provided in a plurality at a predetermined interval in the Y-axis direction. The trench T7 is formed, for example, by RIE to the second semiconductor region 20.

Next, as shown in FIG. 16B, the third insulating film 83 is formed on the inner wall of the trench T7. For the third insulating film 83, for example, SiO₂, BSG or the like is used. Additionally, after forming the BSG as the third insulating film 83, the p⁺-type layer may be formed by diffusing B by thermal diffusion, for example, to be thinner to the side of Si, i.e., the second semiconductor region 20. Thereby, the fourth semiconductor region 27 of the second conductivity type is provided on the side of the third insulating film 83 of the second semiconductor region 20. After that, the material to be formed in the fourth portion 55 is buried in the trench T7.

Then, as shown in FIG. 16C, the trench T8 is formed in the fourth portion 55, the third insulating film 83 and the second semiconductor region 20. The trench T8 is formed shallower than the depth of the fourth portion 55 in the Z-axis direction. The trench T8 is formed so as to extend over the plurality of fourth portions 55 and the third insulating film 83 in the Y-axis direction. After forming the trench T8, the electric field relaxation region 70 is formed in a vicinity of the bottom portion of the trench T8. Next, the third portion 51 is buried in the trench T8. After the third portion 51 is formed, the concentration adjustment region 25 is formed between the plurality of fourth portions 55 and the third insulating film 83.

After that, the upper electrode 53 and the second electrode 60 not shown are formed. Thereby, the semiconductor device 140 is completed.

In the semiconductor device 140, the direction in which the fourth portion 55 extends is the X-axis direction. Therefore, when forming the fourth portion 55, a degree of freedom in shape along the X-Y plane is high. Therefore, for the shape of the fourth portion 55 when seen from the Z-axis direction, it is possible to manufacture the fourth portion 55 of complicated shape with ease, for example, by setting the width on the side closer to the Schottky barrier face larger or narrower than the width on the side distal from the Schottky barrier face, etc.

For the method of forming the concentration adjustment region 25 along the Schottky barrier face, other than the method shown in FIGS. 15A to 16C, for example, the concentration adjustment region 25 may be formed by implanting B or the like at an angle into the side wall of the trench T2 by the ion implantation and performing the thermal diffusion after forming the trench T2 shown in FIG. 10B. Similarly, the concentration adjustment region 25 may be formed by implanting B or the like at an angle by the ion implantation and performing the thermal diffusion after forming the trench T3 shown in FIG. 12B and the trench T5 shown in FIGS. 13D and 14D.

Thereby, it is possible to manufacture the concentration adjustment region 25 with ease so as to have a thickness and an impurity concentration as desired.

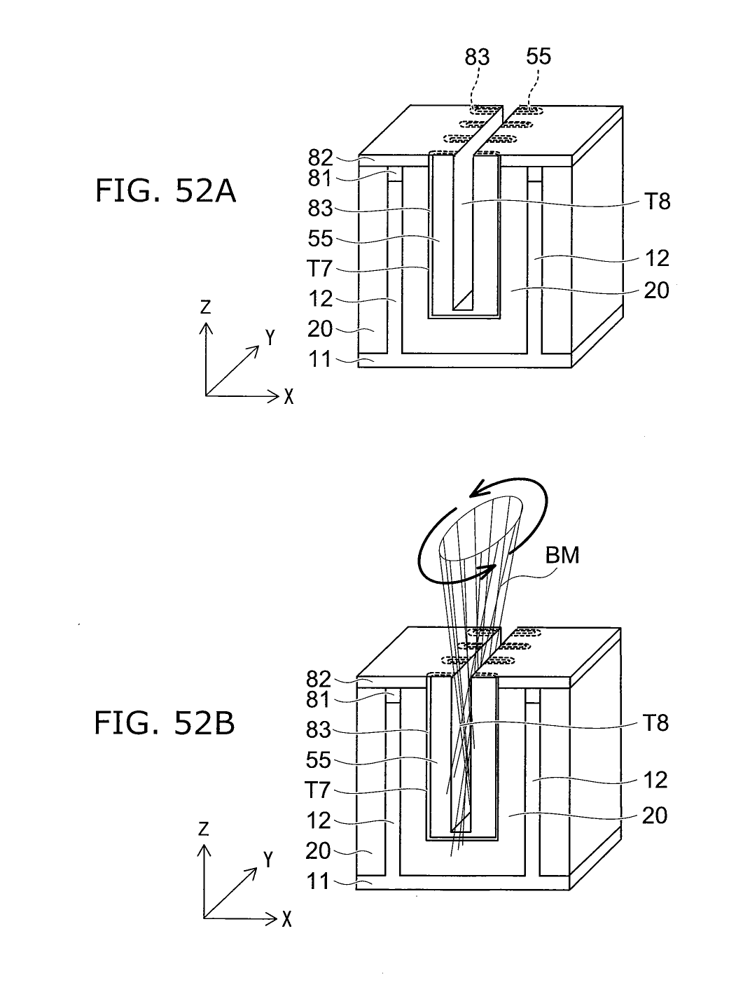

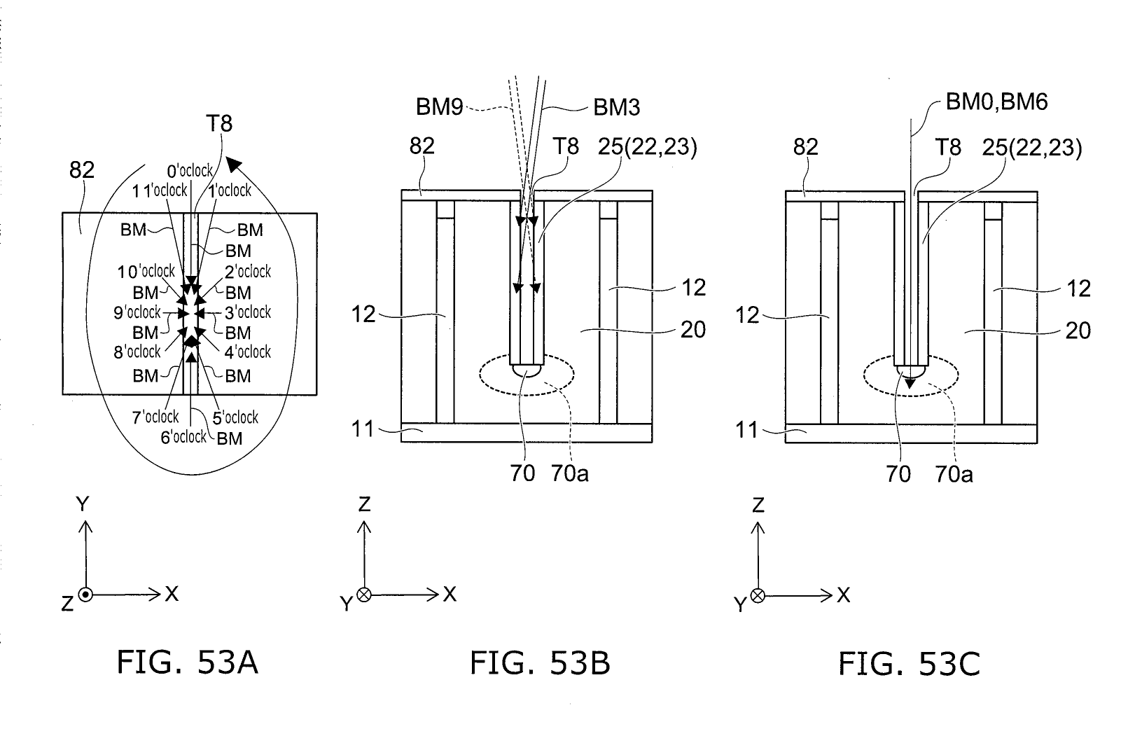

FIGS. 52A to 53C are schematic views describing the ion implantation by rotations.

This example shows a manufacturing method of forming the concentration adjustment region 25 and the electric field relaxation region 70 (70a) by the ion implantation by rotations.

FIG. 52A is a schematic perspective view illustrating a state in which the trench T8 is formed. In the case of adopting the ion implantation by rotations, the trench T7 shown in FIGS. 16A and 16B are formed, and the fourth portion 55 and the third insulating film 83 are formed without forming the concentration adjustment material 25A shown in FIG. 15C.

After that, the trench T8 is formed as shown in FIG. 52A.

Next, as shown in FIG. 52B, ion BM such as B or the like is implanted to the trench T8 at an angle while rotating the ion BM. The ion implantation by rotations may be performed by rotating an ion beam or rotating the structure body in which the ion BM is to be implanted.

FIG. 53A is a schematic plan view when seen from the side of the aperture of the trench T8.

Ion BM is at an angle injected from the ion implanter at a prescribed angle with respect to the trench T8. In the ion implanter, the condition is set for making the ion BM reach the bottom portion of the trench. T8. In this state, the incident direction of the ion BM is rotated with respect to the trench T8.

Here, for convenience in explanations, one of the directions in which the trench T8 extends is defined to be the 0 o'clock direction (Y-axis direction), and the other direction is defined to be the 6 o'clock direction. The direction 30 degrees rotated to the right from the 0 o'clock direction is defined to be the 1 o'clock direction, the 2 o'clock direction, the 3 o'clock direction, . . . , the 10 o'clock direction, and the 11 o'clock direction, respectively. The incident direction of the ion BM indicates the direction of the ion BM projected onto the plane when seen from the side of the aperture of the trench T8 as shown in FIG. 53A.

When rotating the incident direction of the ion BM by 360 degrees, the ion BM reaches the bottom portion of the trench T8 when the ion BM is injected from the 0 o'clock direction and the 6 o'clock direction along the direction in which the trench T8 extends. In contrast, when the ion BM is injected in the 3 o'clock direction and the 9 o'clock direction perpendicular to the direction in which the trench T8 extends, the ion BM reaches the side wall of the trench T8.

FIG. 53B is a schematic cross-sectional view showing the state in which ion is injected in the 3 o'clock direction and the 9 o'clock direction.

FIG. 53C is a schematic cross-sectional view showing the state in which ion is injected in the 0 o'clock direction and the 6 o'clock direction.

As shown in FIG. 53B, the ion MB3 injected in the 3'oclock direction and the ion BM9 to be injected in the 9'oclock direction are implanted in a large amount into the side wall of the trench T8. As shown in FIG. 53C, the ion BMO to be injected in the 0 o'clock direction and the ion BM6 to be injected in the 6 o'clock direction are implanted in a large amount into the bottom portion of the trench T8.

In the case where the incident direction of the ion BM is rotated by 360 degrees, the closer to the 0 o'clock direction and the 6 o'clock direction along the direction in which the trench T8 extends, the ion MB reaches the deeper position from the aperture. In contrast, the closer to the 3 o'clock direction and the 9 o'clock direction along the direction perpendicular to the direction in which the trench T8 extends, the ion MB reaches the shallower position from the aperture.

For example, when the ion BM is injected in the 3 o'clock direction and the 9 o'clock direction, the ion BM is implanted into the side wall of the trench T8. When the ion BM is injected in the 2 o'clock direction, 4 o'clock direction, 8 o'clock direction, and 10 o'clock direction, the ion BM is implanted into the side wall and the bottom portion of the trench T8. When the ion BM is injected in the 1 o'clock direction, 5 o'clock direction, 7 o'clock direction, and 11 o'clock direction, the ion BM is implanted into the side wall and the bottom portion of the trench T8. When the ion BM is injected in the 0 o'clock direction and 6 o'clock direction, the ion BM is implanted into the bottom portion of the trench T8.

By implanting the ion BM into the side wall of the trench T8, the concentration adjustment region 25 is formed. Moreover, by implanting the ion BM into the bottom portion of the trench T8, the electric field relaxation region 70 (70a) is formed. That is, by rotating the incident direction of the ion BM, the concentration adjustment region 25 and the electric field relaxation region 70 (70a) are formed in the same process.

Here, the amount of the ion implanted in the side wall of trench T8 is smaller than the amount of ion implanted in the bottom portion. In the side wall, since the ion is implanted at a shallow angle with respect to the face of the side wall, the elastic reflection of the ion BM is generated according to the angle. Thereby, the amount of the ion implanted is reduced.

In contrast, the amount of the ion implanted in the bottom portion of the trench T8 is larger as compared with the amount of the ion implanted in the side wall. The amount of the ion implanted becomes larger in the bottom portion since the ion implantation is performed at a deeper angle with respect to the face of the bottom portion. When the ion implantation is performed by rotating the ion BM, the amount of the ion implanted in the bottom portion of the trench T8 automatically becomes larger as compared with the amount of the ion implanted in the side wall.

Since the ion BM can be implanted into the bottom portion of the trench T8 at sufficient concentration, it is possible to ensure the sufficient size of the electric field relaxation region 70 (70a).

Although descriptions have been given through the use of the example in which the incident direction of the ion BM is rotated by 360 degrees, the ion BM may be implanted for each of the plurality of directions (for example, 0 o'clock, 3 o'clock, 6 o'clock, 9 o'clock).

### Seventh Embodiment

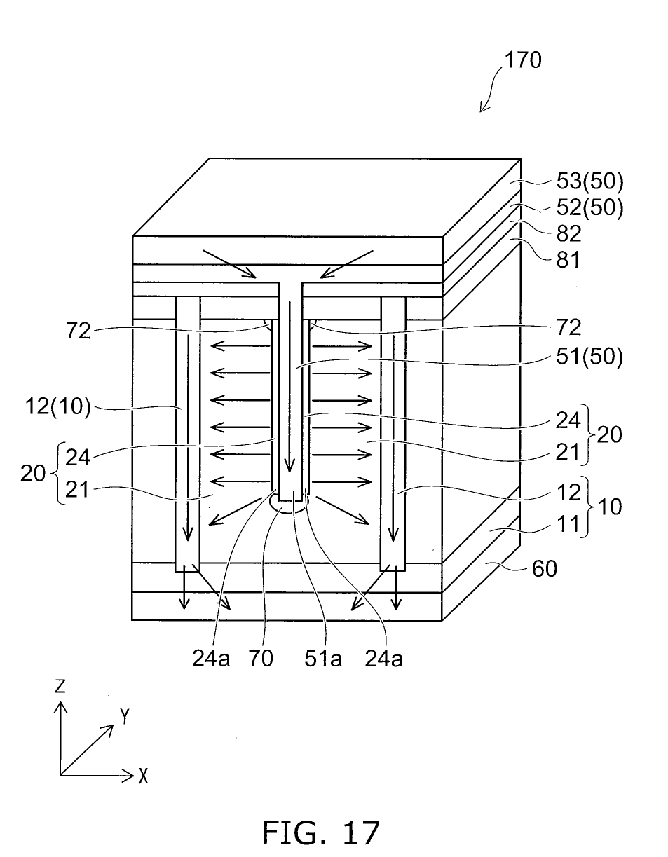

FIG. 17 is a schematic perspective view illustrating the configuration of a semiconductor device according to a seventh embodiment.

As shown in FIG. 17, in a semiconductor device 170 according to the seventh embodiment, a fourth concentration region 24 is included in the second semiconductor region 20.

The fourth concentration region 24 is provided between the first concentration region 21 and the third portion 51.

The fourth concentration region 24 is in contact with the third portion 51 and extends from the first insulating film 81 to a vicinity of the end portion 51a of the third portion 51 along the Z-axis direction.

An impurity concentration in the fourth concentration region 24 is lower than the impurity concentration in the first concentration region 21. The specific resistance in the fourth concentration region 24 is higher than the specific resistance in the first concentration region 21.

The electric field relaxation region 70 is formed under the end portion 51a of the third portion 51 and under an end portion 24a of the fourth concentration region 24 in the first concentration region 21. Further, the semiconductor region 72 of the second conductivity type is provided on a side of the first insulating film 81 of the fourth concentration region 24 in the first concentration region 21.

In the semiconductor device 170, since the fourth concentration region 24 is provided, it is possible to suppress a surface electric field of the third portion 51, and reduce IR.

### Another Example of Seventh Embodiment

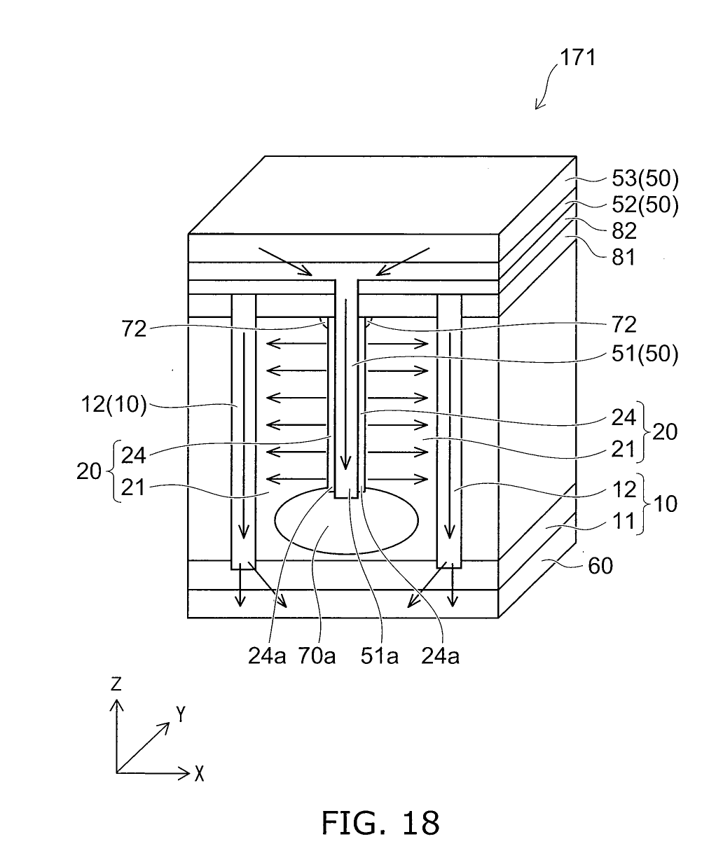

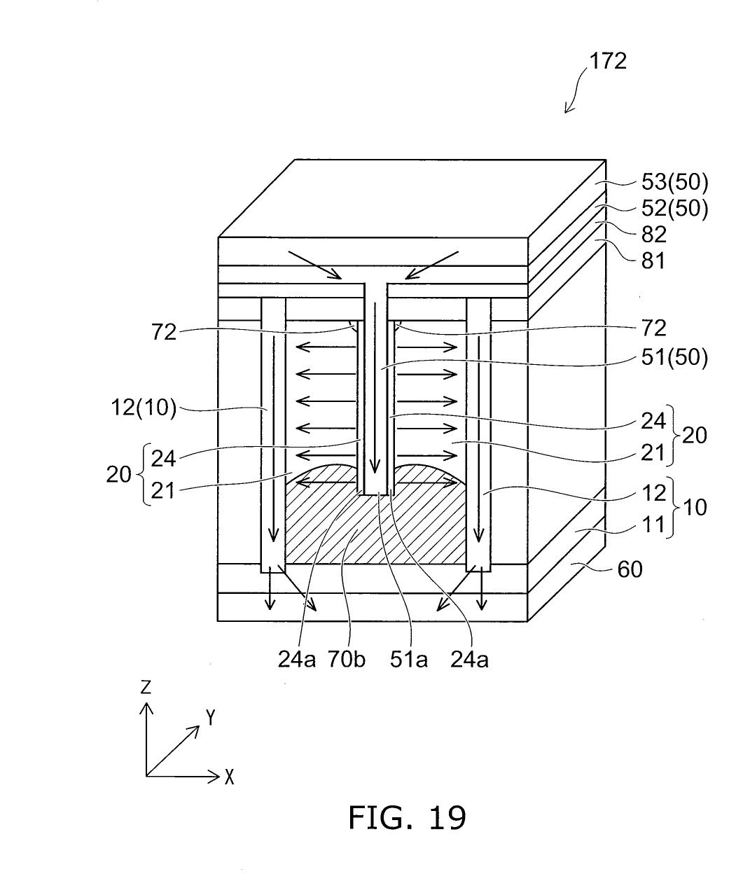

FIGS. 18 and 19 are schematic perspective views illustrating the configuration of semiconductor devices according to another example of the seventh embodiment.

As shown in FIG. 18, in a semiconductor device 171 according to another example of the seventh embodiment, an electric field relaxation region 70a, that is larger than the electric field relaxation region 70 of the semiconductor device 170 shown in FIG. 17, is provided.

The electric field relaxation region 70a is a semiconductor region of the first conductivity type whose specific resistance is higher than the specific resistance in the semiconductor region of the second conductivity type or the second semiconductor region 20.

The electric field relaxation region 70a in the first concentration region 21 is provided under the end portion 51a of the third portion 51, under the end portion 24a of the fourth concentration region 24 and at a part on a side of the side face of the end portion 24a.

The electric field relaxation region 70a is provided so as to surround the end portion 51a of the third portion 51 and the end portion 24a of the fourth concentration region 24. Moreover, the electric field relaxation region 70a is provided in a larger region as compared with the electric field relaxation region 70 shown in FIG. 17. For example, the electric field relaxation region 70a extends along the X-axis from the end portion 51a and the end portion 24a to a vicinity of the second portion 12. Further, the electric field relaxation region 70a extends along the Z-axis from the end portion 51a and the end portion 24a to a vicinity of the first portion 11.

In the semiconductor device 171, since the electric field relaxation region 70a is provided, the electric field at the end portion 51a of the third portion 51 is relaxed, and the breakdown voltage can be made higher.

As shown in FIG. 19, in a semiconductor device 172 according to another example of the seventh embodiment, an electric field relaxation region 70b that is larger than the electric field relaxation region 70a of the semiconductor device 171 as described earlier is provided.

The electric field relaxation region 70b is a semiconductor region of the first conductivity type whose specific resistance is higher than the specific resistance in the semiconductor region of the second conductivity type and the second semiconductor region 20.

The electric field relaxation region 70b extends from the end portion 51a and the end portion 24a along the X-axis direction to reach the second portion 12. Furthermore, the electric field relaxation region 70a extends from the end portion 51a and the end portion 24a along the Z-axis to reach the first portion 11. When the electric field relaxation region 70b is the first conductivity type, the impurity concentration profile between the end portion 51a and the second portion 12 and the impurity concentration profile between the end portion 51a and the first portion 11 in the electric field relaxation region 70b are continuously changed from the end portion 51a to the first portion 11 and the second portion 12, respectively.

In the semiconductor device 172, since the electric field relaxation region 70b is provided, the electric field at the end portion 51a of the third portion 51 is further relaxed as compared with the case where the electric field relaxation region 70a is provided, and the semiconductor device 172 having a high breakdown voltage can be provided.

### Eighth Embodiment

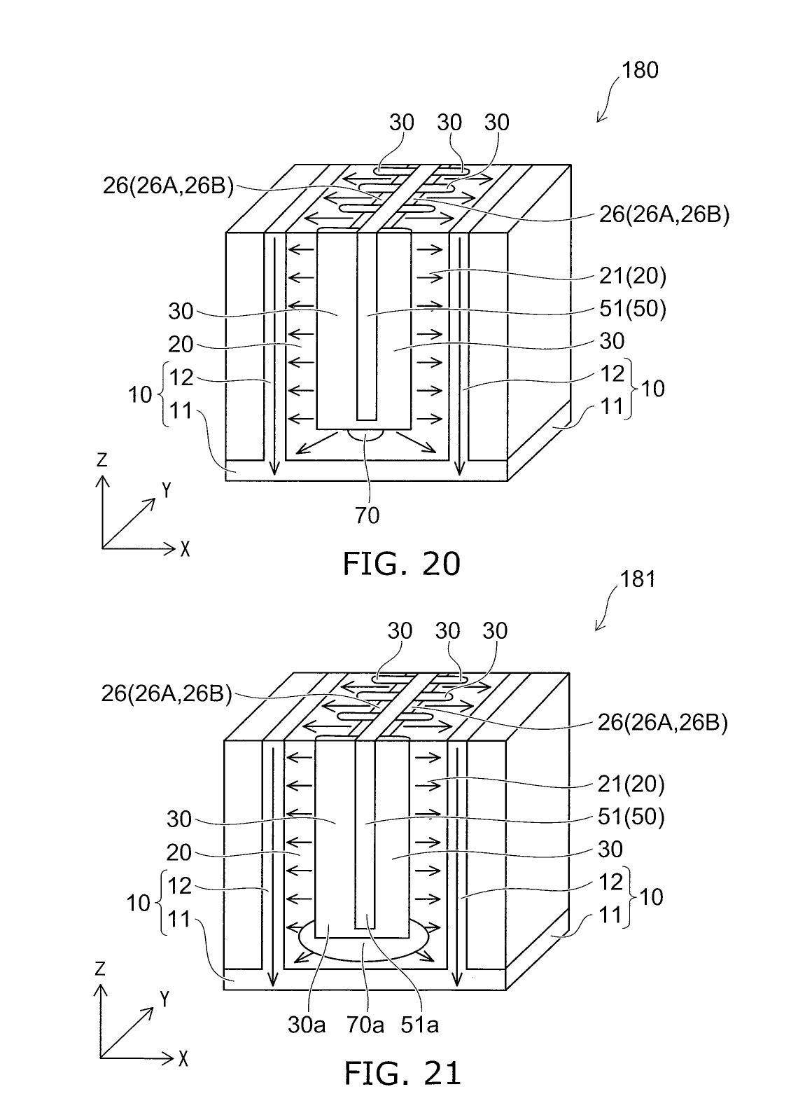

FIG. 20 is a schematic perspective view illustrating a structure of a semiconductor device according to an eighth embodiment.

In FIG. 20, the first insulating film 81, the second insulating film 82, the intermediate electrode 52 and the upper electrode 53 are omitted.

As shown in FIG. 20, a semiconductor device 180 according to the eighth embodiment includes the configuration of the semiconductor device 120 shown in FIG. 4. In the semiconductor device 180, the concentration adjustment region 26 is included in the second semiconductor region 20.

The concentration adjustment region 26 is provided between the first concentration region 21 and the third portion 51.

The concentration adjustment region 26 can be a fifth concentration region 26A having an impurity concentration lower than the impurity concentration in the first concentration region 21 or a sixth concentration region 26B having an impurity concentration higher than the impurity concentration in the first concentration region 21.

In the case where the fifth concentration region 26A is provided as the concentration adjustment region 26, it is possible to reduce the Schottky lowering effect by increasing the resistance in a vicinity of the Schottky barrier face. Thereby, as compared with the case where the concentration adjustment region 26 is not provided, depletion layers are pinched off at a still lower voltage, and it is possible to relax the electric field at the Schottky barrier face. Therefore, a reduction in IR can be achieved even when a material with a relatively low φB such as V or the like is used as the material of the first portion 51.

Moreover, in the case where the sixth concentration region 26B is provided as the concentration adjustment region 26, it is possible to reduce VF by reducing the resistance in a vicinity of the Schottky barrier face. Here, in the case of using the sixth concentration region 26B, φB is reduced by the Schottky lowering effect as compared with the case of using the fifth concentration region 26A. However, by using a material with a relatively large φB (for example, Mo with φB=0.67 volt (V)) as the material of the first portion 51, it is possible to suppress IR.

### Another Example of Eighth Embodiment

FIG. 21 is a schematic perspective view illustrating the configuration of a semiconductor device according to another example of the eighth embodiment.

In FIG. 21, the first insulating film 81, the second insulating film 82, the intermediate electrode 52 and the upper electrode 53 are omitted.

As shown in FIG. 21, in a semiconductor device 181 according to another example of the eighth embodiment, the electric field relaxation region 70a that is larger than the electric field relaxation region 70 of the semiconductor device 180 shown in FIG. 20 is provided.

The electric field relaxation region 70a is a semiconductor region of the second conductivity type or a semiconductor region of the first conductivity type whose specific resistance is higher than the specific resistance in the second semiconductor region 20.

The electric field relaxation region 70a in the first concentration region 21 is provided under the end portion 51a of the third portion 51, under an end portion 30a of the third semiconductor region 30 and at a part on a side of the side face of the end portion 30a.

The electric field relaxation region 70a is provided so as to surround the end portion 51a of the third portion 51 and the end portion 30a of the third semiconductor region 30. Moreover, the electric field relaxation region 70a is provided in a larger region as compared with the electric field relaxation region 70 shown in FIG. 20. For example, the electric field relaxation region 70a extends along the X-axis from the end portion 51a and the portion 30a to a vicinity of the second portion 12. Furthermore, the electric field relaxation region 70a extends along the Z-axis from the end portion 51a and the end portion 30a to a vicinity of the first portion 11.

In the semiconductor device 181, since the electric field relaxation region 70a is provided, the electric field at the end portion 51a of the third portion 51 is relaxed, and the breakdown voltage can be made higher.

In order to manufacture the above-described semiconductor devices 170, 171, 172, 180 and 181, for example, after forming the trench T2 shown in FIG. 10B or after forming the trench T3 shown in FIG. 12B, impurities may be implanted by the ion implantation into the fourth concentration region 24, the electric field relaxation regions 70a and 70b, the fifth concentration region 26A and the sixth concentration region 26B to be caused to diffuse.

### Ninth Embodiment

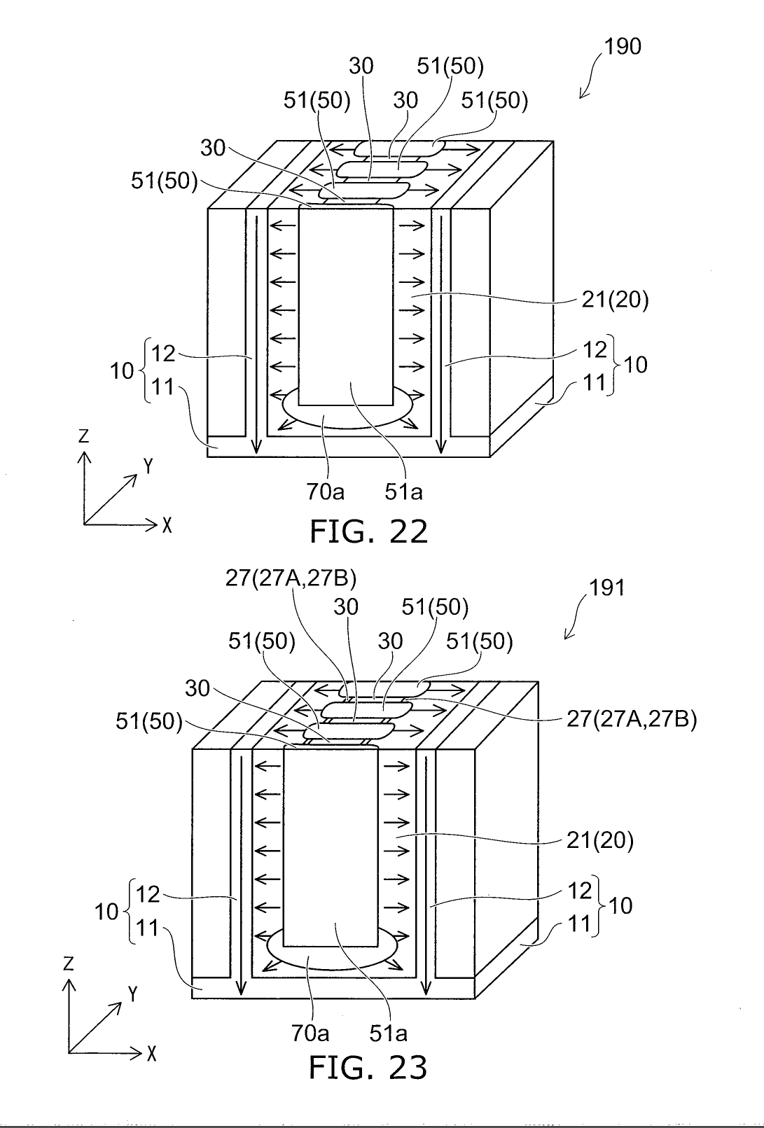

FIG. 22 is a schematic perspective view illustrating a structure of a semiconductor device according to a ninth embodiment.

In FIG. 22, the first insulating film 81, the second insulating film 82, the intermediate electrode 52 and the upper electrode 53 are omitted.

As shown in FIG. 22, a semiconductor device 190 includes the plurality of third portions 51 and the third semiconductor region 30 provided between the plurality of the third portions 51. When seen along the Z-axis direction, the third portion 51 extends along the X-axis direction. Further, when seen along the Z-axis direction, the plurality of third portions 51 are provided so as to be separated from one another along the Y-axis direction.

That is, when seen along the Z-axis direction, the third portion 51 and the third semiconductor region 30 are disposed alternately along the Y-axis direction.

The semiconductor device 190 may be provided with the electric field relaxation region 70a. The electric field relaxation region 70a is provided under the end portion 51a of the third portion 51 and at a part on a side of the side face of the end portion 51a in the first concentration region 21. The electric field relaxation region 70a is provided so as to surround the end portion 51a of the third portion 51.

In the semiconductor device 190, since the third semiconductor region 30 is provided between the plurality of third portions 51, a depletion layer is formed so as to cover the third portion 51 when a reverse voltage is applied, thereby reducing IR.

### Another Example of Eighth Embodiment

FIG. 23 is a schematic perspective view illustrating a structure of a semiconductor device according to another example of the ninth embodiment.

In FIG. 23, the first insulating film 81, the second insulating film 82, the intermediate electrode 52 and the upper electrode 53 are omitted.

As shown in FIG. 23, in the semiconductor device 190 according to another example of the ninth embodiment, the fourth semiconductor region 27 is included in the second semiconductor region 20.

The fourth semiconductor region 27 is provided in a vicinity of the interface between the third portion 51 and the second semiconductor region 20, and in a vicinity of an interface with the third semiconductor region 30 and the second semiconductor region 20.

There are the case where the fourth semiconductor region 27 is a seventh concentration region 27A with an impurity concentration lower than the impurity concentration in the first concentration region 21 and the case where the concentration adjustment region 27 is an eighth concentration region 27B with an impurity concentration higher than the impurity concentration in the first concentration region 21.

The effect achieved in the case where the seventh concentration region 27A is provided is the same as the effect achieved in the case where the fifth concentration region 26A is provided. The effect achieved in the case where the eighth concentration region 27B is provided is the same as the effect achieved in the case where the sixth concentration region 26B is provided.

### Tenth Embodiment

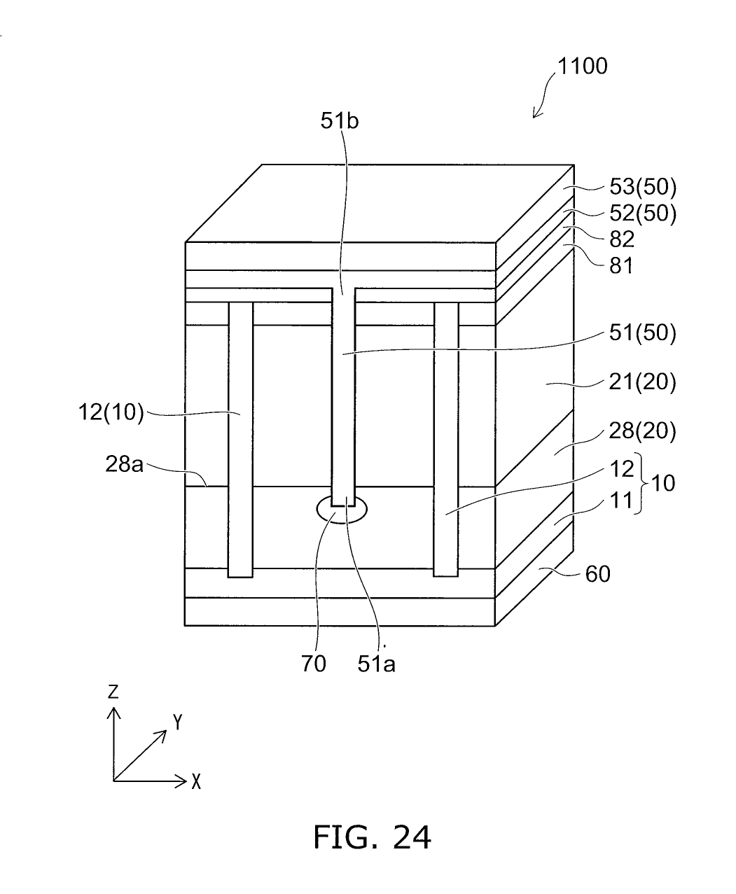

FIG. 24 is a schematic perspective view illustrating a structure of a semiconductor device according to a tenth embodiment.

As shown in FIG. 24, in a semiconductor device 1100 according to the tenth embodiment, a ninth concentration region 28 is included in the second semiconductor region 20.

The ninth concentration region 28 is provided between the first concentration region 21 and the first portion 11. An upper face 28a of the ninth concentration region 28 is provided above a lower face of the end portion 51a of the third portion 51. That is, the third portion 51 is provided so as to reach a middle of the ninth concentration region 28 from the intermediate electrode 52 along the Z-axis direction.

Moreover, a part on the lower side of the second portion 12 is surrounded by the ninth concentration region 28.

A specific resistance of the ninth concentration region 28 is higher than the specific resistance in the first concentration region 21. An impurity concentration in the ninth concentration region 28 is lower than the impurity concentration in the first concentration region 21.

In the semiconductor device 1100, the electric field relaxation region 70 is provided so as to surround the end portion 51a of the third portion 51 in the ninth concentration region 28. The electric field relaxation region 70 may not necessarily be provided.

The ninth concentration region 28 is formed by diffusing B (boron) into the second semiconductor region 20 or by the epitaxial growth on the first portion 11.

In the case where the ninth concentration region 28 is formed by diffusing B(boron) in the second semiconductor region 20, the specific resistance of the ninth concentration region 28 is higher than the specific resistance in the first concentration region 21.

In the case where the ninth concentration region 28 is formed by the epitaxial growth on the first portion 11, the impurity concentration in the ninth concentration region 28 is lower than the impurity concentration in the first concentration region 21.

In the semiconductor device 1100, since the ninth concentration region 28 is provided, the electric field at the end portion 51a of the third portion 51 is relaxed, and the breakdown voltage can be made higher.

### Eleventh Embodiment

An eleventh embodiment relates to a method of manufacturing a semiconductor device.

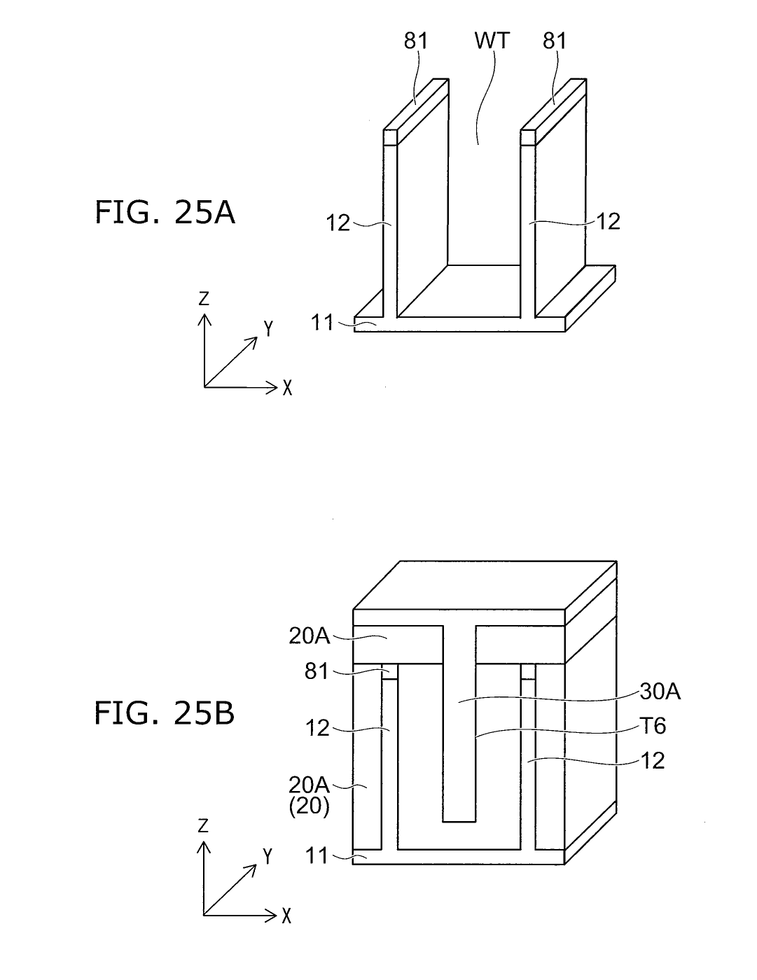

FIGS. 25A to 27 are schematic perspective views describing a method for manufacturing the semiconductor device according to the ninth embodiment.

First, as shown in FIG. 25A, the first insulating film 81 is formed in the first portion 11, and the first portion 11 is etched by using this first insulating film 81 as a mask. The portion removed by this etching is the wide trench WT. The portion masked with the first insulating film 81 serves as the second portion 12 that extends from the first portion 11 in the Z-axis direction.

Next, as shown in FIG. 25B, the second semiconductor material 20A is, for example, epitaxially grown on the first portion 11. The second semiconductor material 20A is, for example, an n-type silicon. The second semiconductor material 20A is buried between a plurality of the second portions 12 on the first portion 11. The second semiconductor material 20A buried between the plurality of second portions 12 serves as the second semiconductor region 20. Then, the trench T6 is formed in the second semiconductor region 20, and the third semiconductor material 30A is buried in the trench T6.

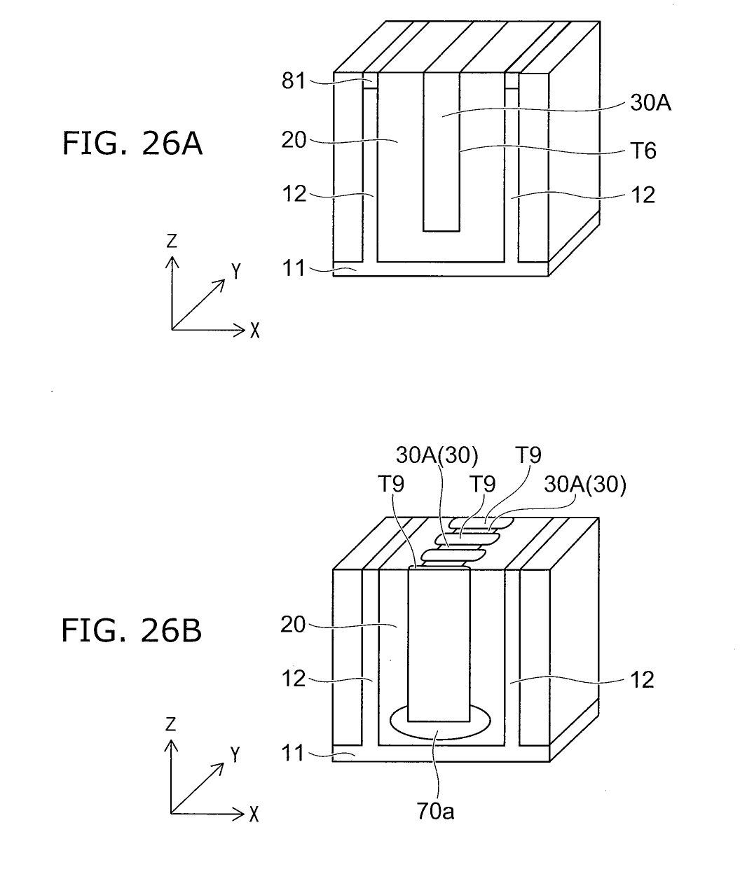

Then, a part of the third semiconductor material 30A is removed. Here, the third semiconductor material 30A is removed to an extent that upper portions of the first insulating film 81, the second semiconductor region 20 and the third semiconductor material 30A in the trench T6 are exposed. The third semiconductor material 30A is removed, for example, by the CMP. As shown in FIG. 26A, the exposed face of the first insulating film 81, the second semiconductor region 20, and the third semiconductor material 30A are flattened. Here, the first insulating film 81 may be removed by the CMP. In the embodiment, an example is shown in the case where the first insulating film 81 is removed by the CMP.

Next, as shown in FIG. 26B, a plurality of trenches T9 are formed in the second semiconductor region 20 and the third semiconductor material 30A. The depth direction of the trench T9 is the Z-axis direction. The depth of the trench T9 is deeper than the depth of the third semiconductor material 30A. Moreover, the trench T9 seen in the X-axis direction has an aperture having a narrow and long shape (for example, oval type and oval) that extends in the X-axis direction. The trenches T9 are provided in a plurality at a predetermined interval in the Y-axis direction. In addition, the trenches T9 are formed, for example, in the second semiconductor region 20 and the third semiconductor material 30A by RIE. By forming the trenches T9, the third semiconductor material 30A is divided into the third semiconductor regions 30. After forming the trenches T9, the electric field relaxation region 70a is formed in the second semiconductor region 20 in a vicinity of the bottom portions of the trenches T9.

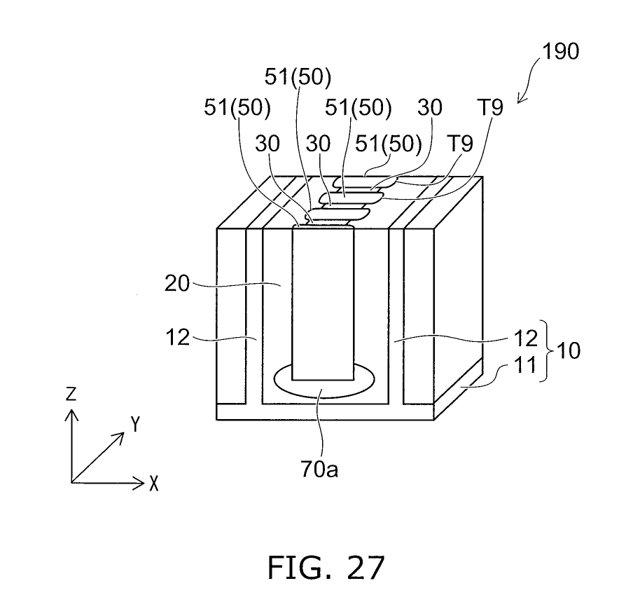

Next, as shown in FIG. 27, a material for the third portion 51 is buried in the trenches T9. After that, the upper electrode 53 and the second electrode 60 not shown are formed. Thereby, the semiconductor device 190 is completed.

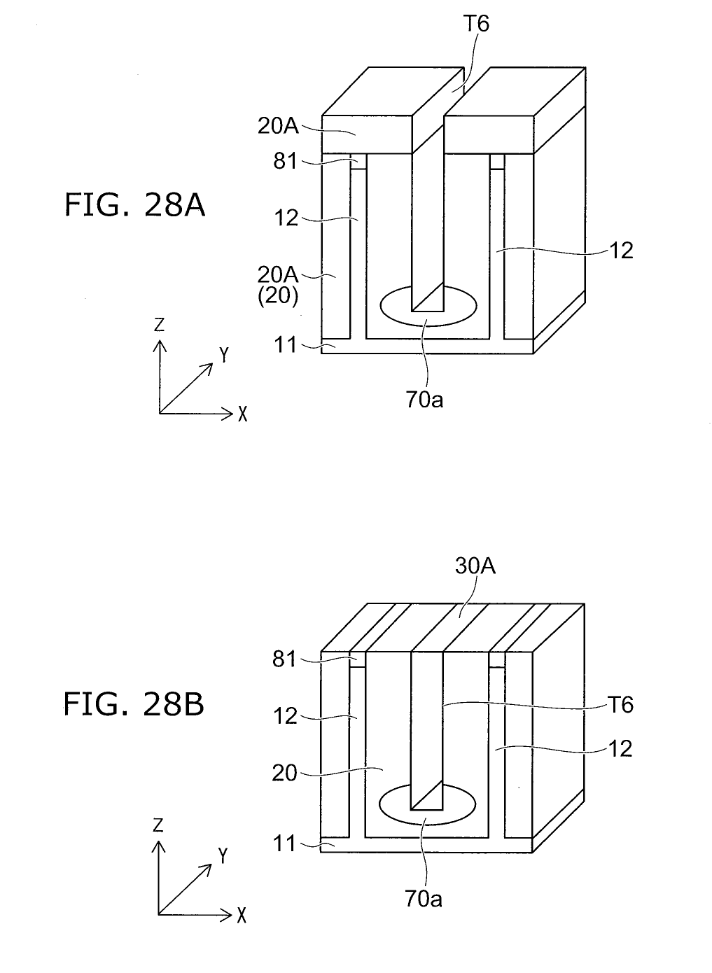

FIGS. 28A and 28B are schematic perspective views describing another example of the eleventh embodiment.

As shown in FIG. 28A, the second portion 12 is formed on the first portion 11, and the second semiconductor material 20A is buried between the plurality of second portions 12. Up to forming the trench T6 in the second semiconductor material 20A, the method is the same as the method illustrated in FIGS. 25A and 25B.

Next, after forming the trench T6, the electric field relaxation region 70a is formed in the second semiconductor region 20 in a vicinity of the bottom portion of the trench T6.

Next, as shown in FIG. 28B, the third semiconductor material 30A is buried in the trench T6. After the third semiconductor material 30A is buried in the trench T6, the trench T9 is formed, and the third portion 51 is buried in the trench T9 as in the same manner as the processes shown in FIGS. 26B to 27. Thereby, the semiconductor device 190 is completed.

### Twelfth Embodiment

A twelfth embodiment relates to a method of manufacturing a semiconductor device.

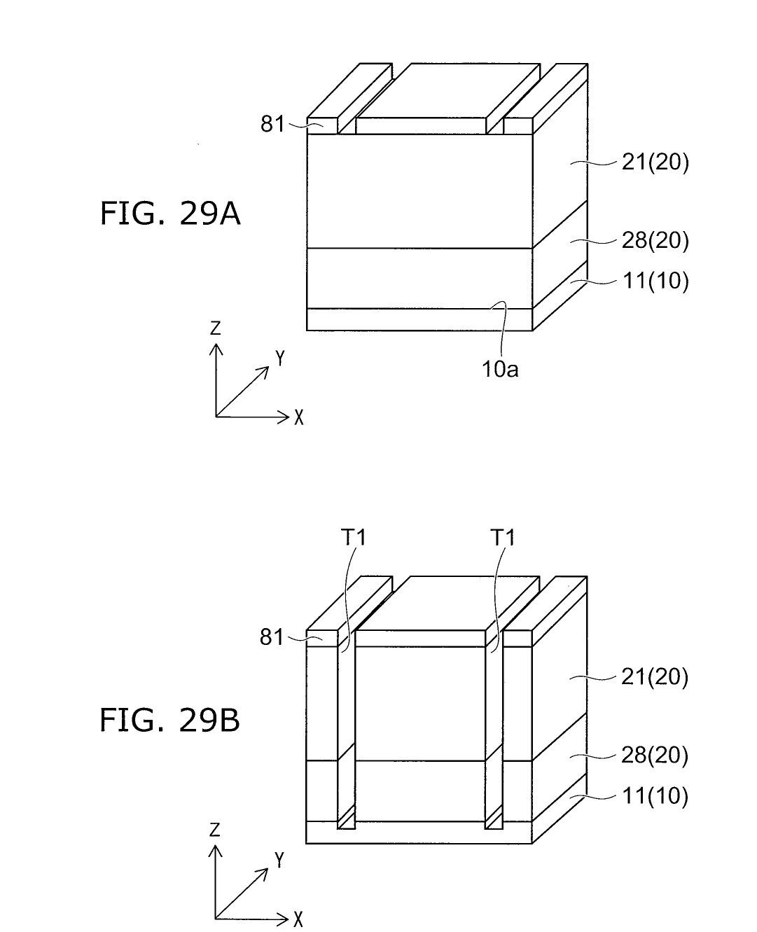

FIG. 29A to FIG. 32 are schematic perspective views describing a method for manufacturing the semiconductor device according to the tenth embodiment.

First, as shown in FIG. 29A, on the first major surface 10a of the first portion 11 that is the first semiconductor region 10 the ninth concentration region 28 of the second semiconductor region 20 is, for example, epitaxially grown. The ninth concentration region 28 is, for example, an n⁻-type silicon epitaxial layer. Further, the first concentration region 21 is, for example, epitaxially grown on the ninth concentration region 28. The first insulating film 81 is formed on the first concentration region 21, and an aperture is partially formed therein.

Next, as shown in FIG. 29B, the first concentration region 21, the ninth concentration 28 and the first portion 11 are etched (for example, by RIE) by using the first insulating film 81 having the aperture, as a mask. Thereby, the trench T1 is formed at a depth reaching the middle of the first portion 11 from the first concentration region 21. Moreover, the trench T1 is formed so as to extend in the Y-axis direction.

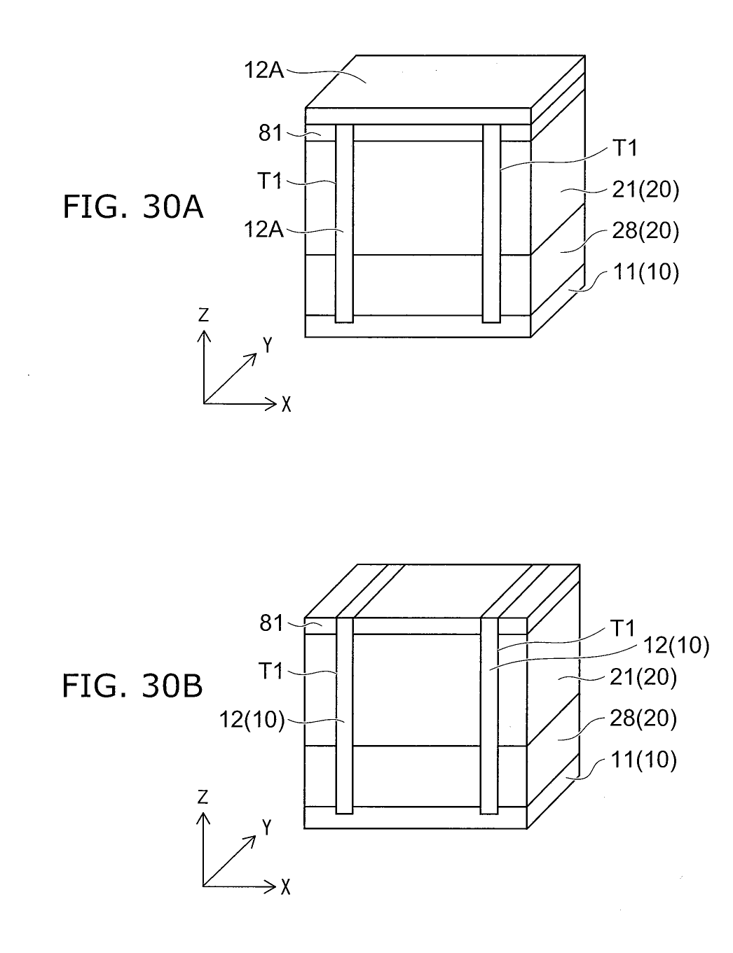

Then, as shown in FIG. 30A, the second portion material 12A is buried in the trench T1. As the second portion material 12A, for example, polysilicon with the high impurity concentration is used. The second portion material 12A is formed to cover the first insulating film 81.

Next, as shown in FIG. 30B, a part of the second portion material 12A is removed. Here, a portion of the second portion material 12A above the first insulating film 81 is removed until the apertures of the first insulating film 81 and the trench T1 are exposed. The second portion material 12A is removed, for example, by the CMP. The exposed face of the second portion material 12A buried in the first insulating film 81 and the trench T1 is flattened. The second portion material 12A buried in the trench T1 serves as the second portion 12.

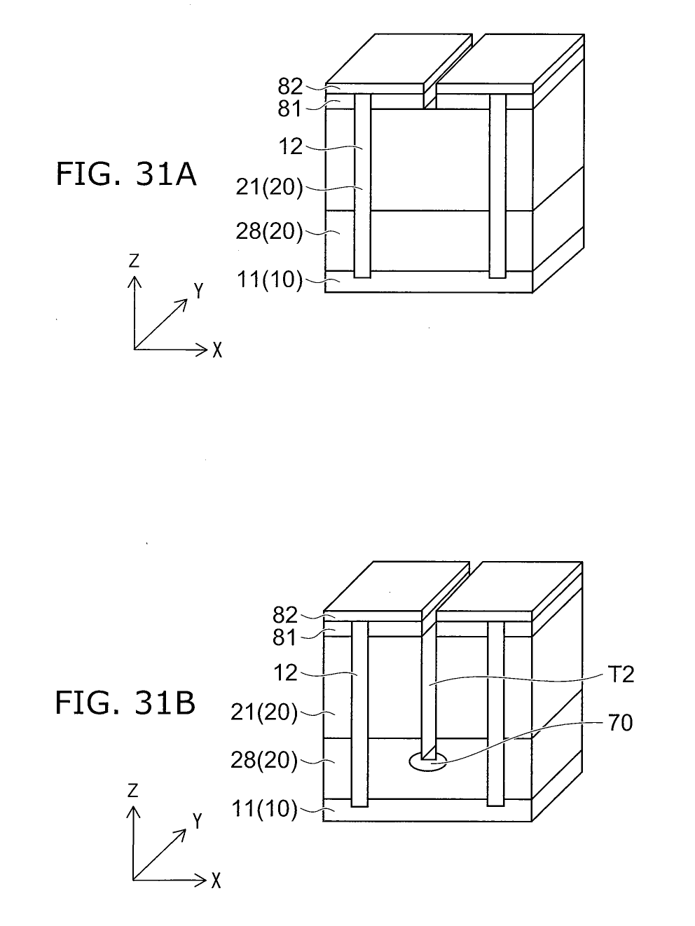

Then, as shown in FIG. 31A, the second insulating film 82 is formed on the first insulating film 81, and an aperture is formed in a part of the first insulating film 81 and the second insulating film 82. The aperture is provided at a position between the two second portions 12 in the X-axis directions.

Next, as shown in FIG. 31B, the first concentration region 21 and the ninth concentration 28 are etched (for example, by RIE) by using the first insulating film 81 and the second insulating film 82 having the aperture, as a mask. Thereby, the trench T2 is formed at a depth reaching the middle of the ninth concentration region 28 from above the first concentration region 210. Moreover, the trench T2 is formed so as to extend in the Y-axis direction.

After forming the trench T2, the electric field relaxation region 70 is formed in the ninth concentration region 28 in a vicinity of the bottom portion of the trench T2.

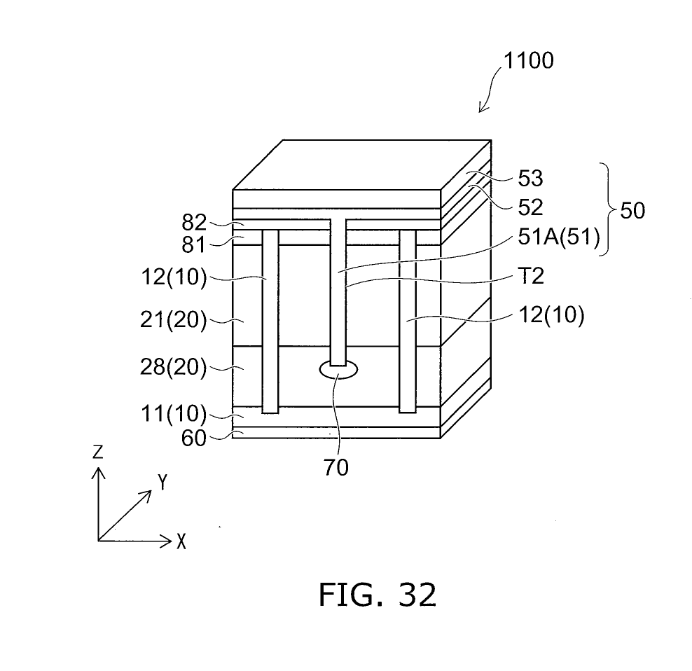

Then, as shown in FIG. 32, the third portion material 51A is buried in the trench T2. The third portion material 51A buried in the trench T2 serves as the third portion 51 that forms a Schottky junction with the second semiconductor region 20 by the sinter processing.

The third portion material 51A is formed to cover on the second insulating film 82. This portion serves as the intermediate electrode 52. After that, the upper electrode 53 is formed on the intermediate electrode 52. The first electrode 50 is formed, for example, from the third portion 51, the intermediate electrode 52, and the upper electrode 53.

Furthermore, the second electrode 60 is formed under the first portion 11. Thereby, the semiconductor device 1100 is completed.

### Another Example of Twelfth Embodiment

Next, another example of the twelfth embodiment will be described.

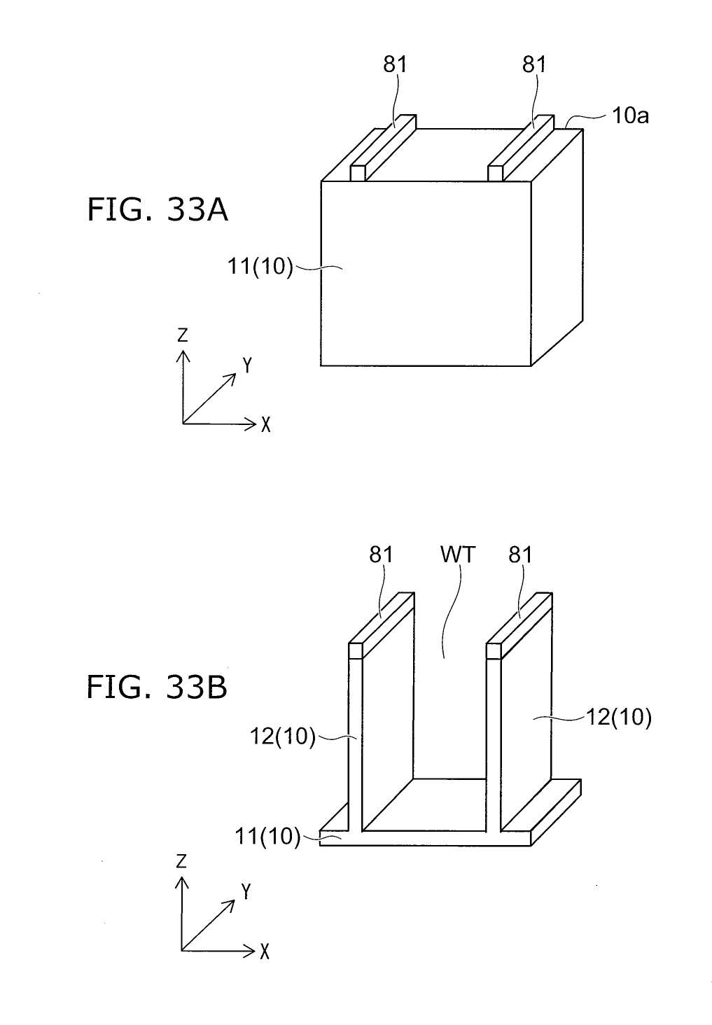

FIG. 33A to FIG. 38 are schematic perspective views describing another example of the method of manufacturing the semiconductor device according to the tenth embodiment.

First, as shown in FIG. 33A, the first insulating film 81 is formed on the first major surface 10a of the first portion 11, i.e., the first semiconductor region 10. Then, an aperture is formed in a part of the first insulating film 81. The position at which the first insulating film 81 is left is the position where the second portion 12 is formed in the subsequent process when seen in the Z-axis direction.

Next, as shown in FIG. 33B, the first portion 11 is etched by using the first insulating film 81 remaining, as a mask. The part removed by this etching serves as the wide trench WT. In contrast, the part masked with the first insulating film 81 serves as the second portion 12 that extends from the first portion 11 in the Z-axis direction.

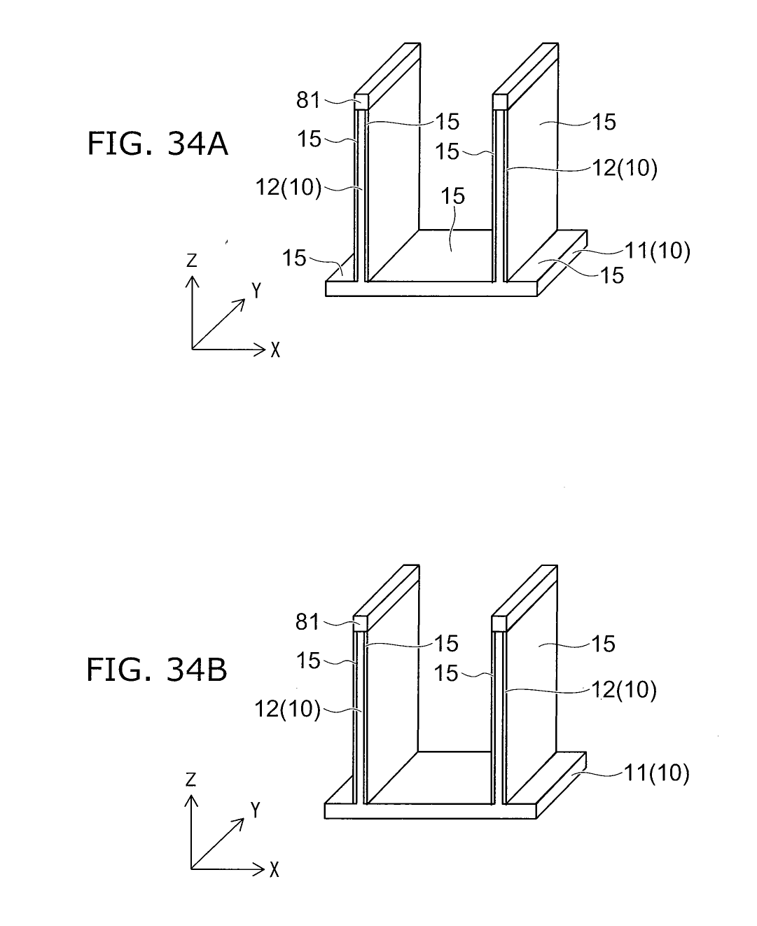

Then, as shown in FIG. 34A, the insulating film is formed on surfaces of the first portion 11 and the second portion 12. Then, as shown in FIG. 34B, the insulating film 15 on the first portion 11 is removed. The insulating film 15 is left on the surface of the second portion 12,.

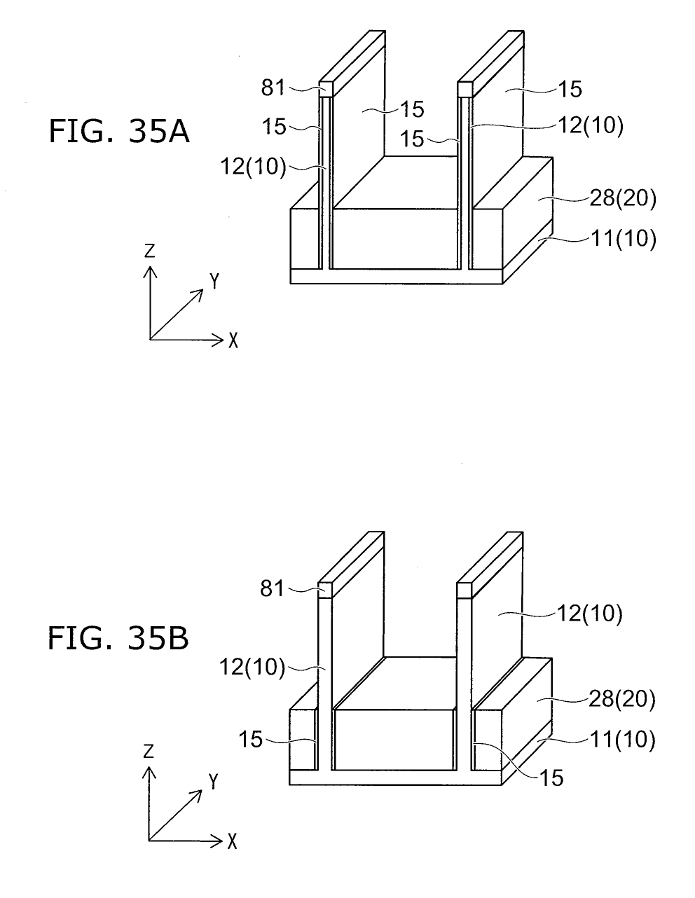

Next, as shown in FIG. 35A, for example, the ninth concentration region 28 is epitaxially grown on the first portion 11. The ninth concentration region 28 is not grown on the insulating film 15. Therefore, the ninth concentration region 28 is grown on the first portion 11 along the Z-axis direction. The ninth concentration region 28 is formed to a height such that a part of the lower side of the second portion 12 is buried.

Then, as shown in FIG. 35B, the insulating film as exposed on the upper side of the ninth concentration region 28 is removed. Thereby, the second portion 12 is exposed on the upper side of the ninth concentration region 28.

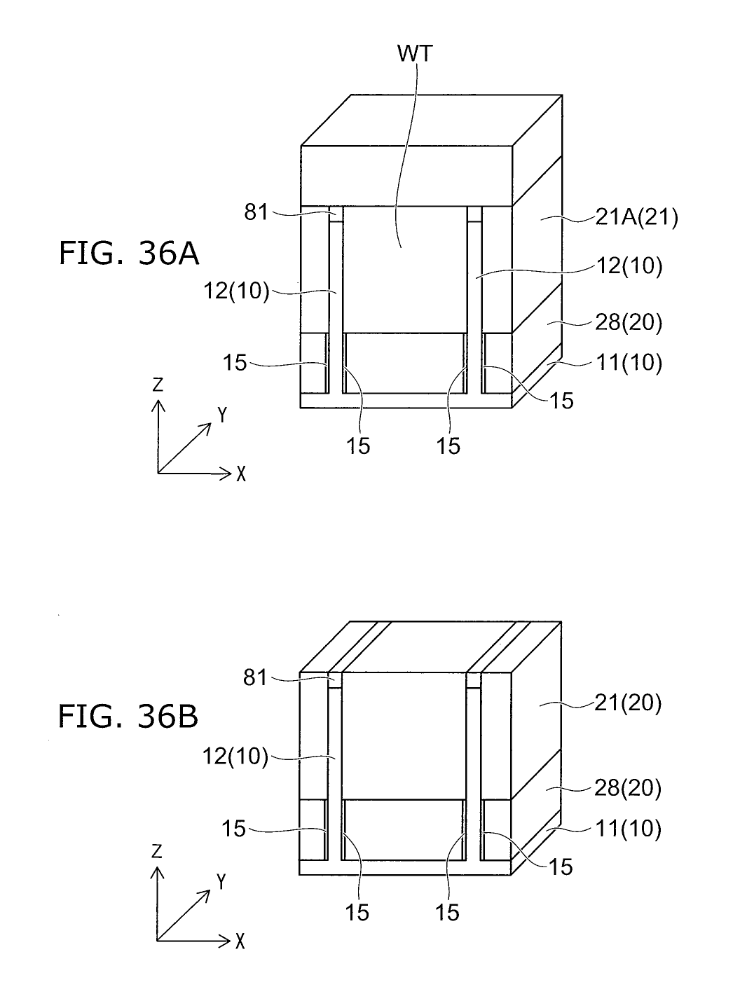

Next, as shown in FIG. 36A, the first concentration region material 21A is, for example, epitaxially grown on the first portion 11. The first concentration material 21A is, for example, n-type silicon. Since the insulating film 15 has been removed in the earlier processing, the first concentration region material 21 is grown also on the second portion 12 as well as on the ninth concentration region 28.

The first concentration region material 21A buried between the plurality of second portions 12 on the ninth concentration region 28 serves as the first concentration region 21.

Next, a part of the first concentration region material 21A is removed. Here, the first concentration region material 21A is removed to an extent that an upper portion of the first insulating film 81 is exposed. The first concentration region material 21A is removed, for example, by the CMP. As shown in FIG. 36B, the exposed faces of the first insulating film 81 and the first concentration region 21 are flattened.

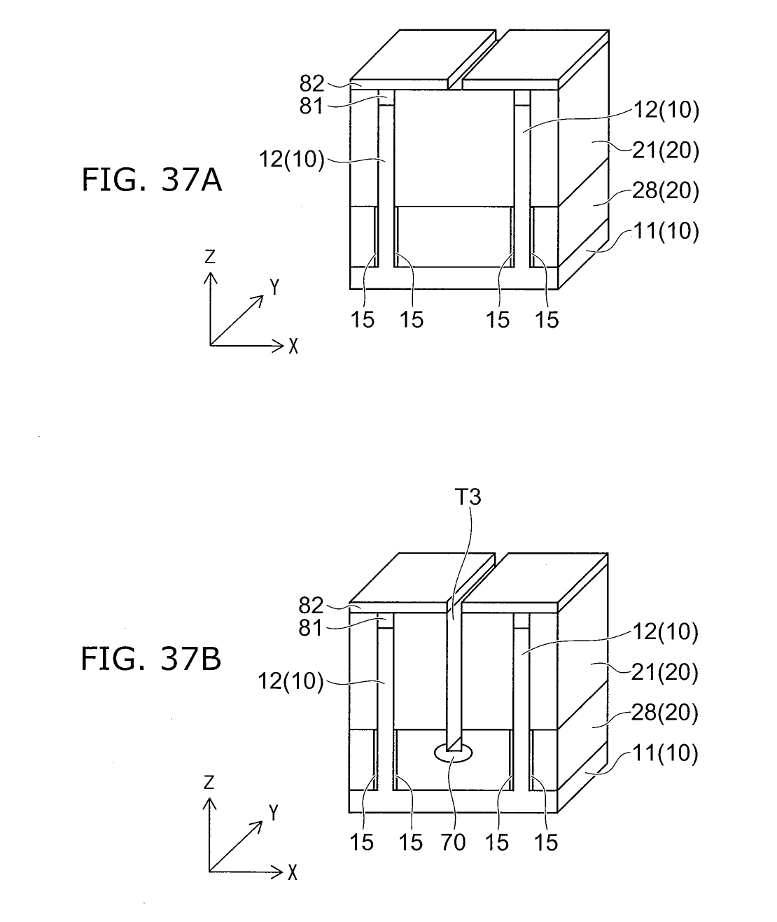

Then, as shown in FIG. 37A, the second insulating film 82 is formed on the first insulating film 81 and the first concentration region 21 which have been flattened, and an aperture is formed in a part of the second insulating film 82. The aperture is formed between the two second portions 12 in the X-axis direction.

Next, as shown in FIG. 37B, the first concentration region and the ninth concentration region 28 are etched (for example, by RIE) by using the second insulating film 82 having the aperture, as a mask. Thereby, the trench T3 is formed. The trench TE is formed so as to extend from the upper side of the first concentration region 21 to the depth reaching the middle of the ninth concentration region 28. The trench T3 is formed so as to extend in the Y-axis direction.

After forming the trench T3, the electric field relaxation region 70 is formed in the ninth concentration region 28 in a vicinity of the bottom portion of the trench T3.

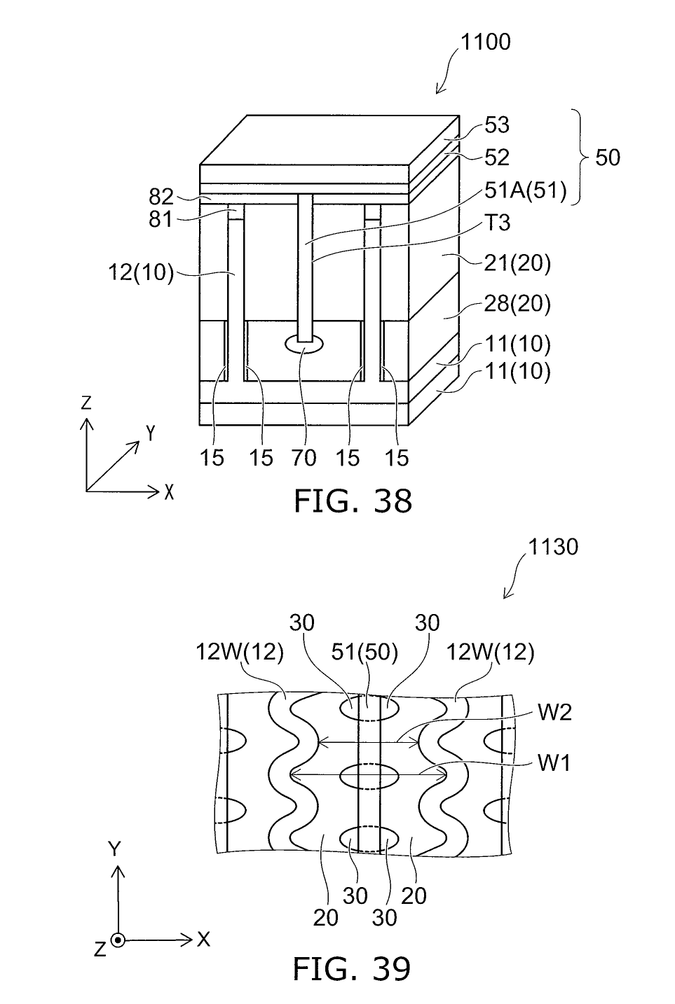

As shown in FIG. 38, the third portion material 51A is buried in the trench T2. The third portion material 51A buried in the trench T2 serves as the third portion 51 that forms a Schottky junction with the second semiconductor region 20 by the sinter processing.

The third portion material 51A is formed to cover the second insulating film 82. This portion serves as the intermediate electrode 52. After that, the upper electrode 53 is formed on the intermediate electrode 52. The first electrode is formed from the third portion 51, the intermediate electrode 52, and the upper electrode 53.

Furthermore, the second electrode 60 is formed under the first portion 11. Thereby, the semiconductor device 1100 is completed.

In the semiconductor device 1100 manufactured by the foregoing method, the insulating film 15 is formed between the ninth concentration region 28 and the second portion 12.

### Thirteenth Embodiment

FIG. 39 is a schematic plan view illustrating the configuration of a semiconductor device according to a thirteenth embodiment.

In FIG. 39, the first insulating film 81, the second insulating film 82, the intermediate electrode 52 and the upper electrode 53 are omitted.

As shown in FIG. 39, a semiconductor device 1130 according to the thirteenth embodiment includes at least the second semiconductor region 20, the third semiconductor region 30, the second portion 12 and the third portion 51 as in the semiconductor device 120 according to the second embodiment shown in FIGS. 4A and 4B. In the second semiconductor device 1130, the outer shape of the second portion 12 when seen along the Z-axis direction has a wave shape (second portion 12W).

The wave shapes of the adjacent two second portions 12W along the X-axis direction have the same period. However, the respective phases differ by 180 degrees. Thereby, as to the interval along the X-axis of these two second portions 12W, the widest interval W1 and the narrowest interval W2 are repeated. The third semiconductor region 30 is provided at a position such that the region 30 has the width W1 between the two second portions 12A. For example, the shape of the face of the second portion 12W facing the third semiconductor region 30 is similar to the shape of the face of the third semiconductor region 30 facing the second portion 12. That is, a part of the outer shape of the third semiconductor region 30 along the Z-axis is similar to the outer shape along the Z-axis of the second portion 12W.

### Fourteenth Embodiment

A fourteenth embodiment relates to a method of manufacturing a semiconductor device.

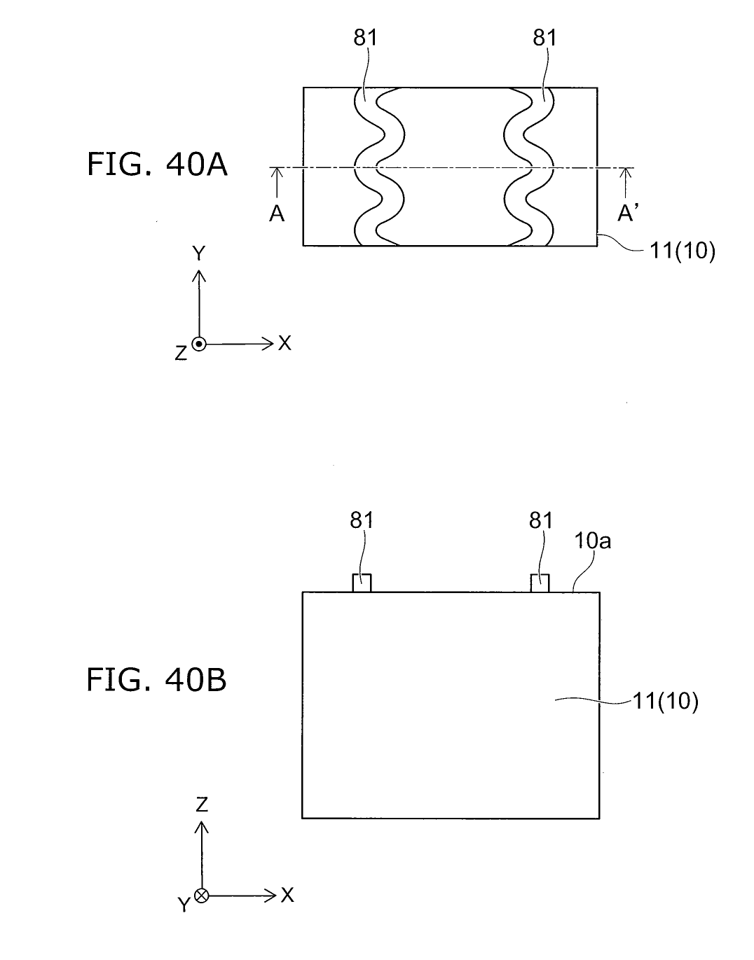

FIGS. 40A to 48B are schematic views describing a method of manufacturing the semiconductor device according to the thirteenth embodiment.

In each of FIG. 40A to FIG. 48B, A shows a schematic plan view, and B shows a schematic cross-sectional view taken along the line A-A′ shown in A.

First, as shown in FIGS. 40A and 40B, the first insulating film 81 is formed on the first major surface 10a of the first portion 11, i.e., the first semiconductor region 10. Then, the first insulating film 81 is patterned in a wave shape. The shape along the Z-axis of the first insulating film 81 after the patterning has the same wave shape as the shape along the Z-axis of the first insulating film 81. The shape along the Z-axis of the first insulating film 81 after the patterning has the same wave shape as the shape as the shape along the Z-axis of the second portion 12W (see FIG. 39).

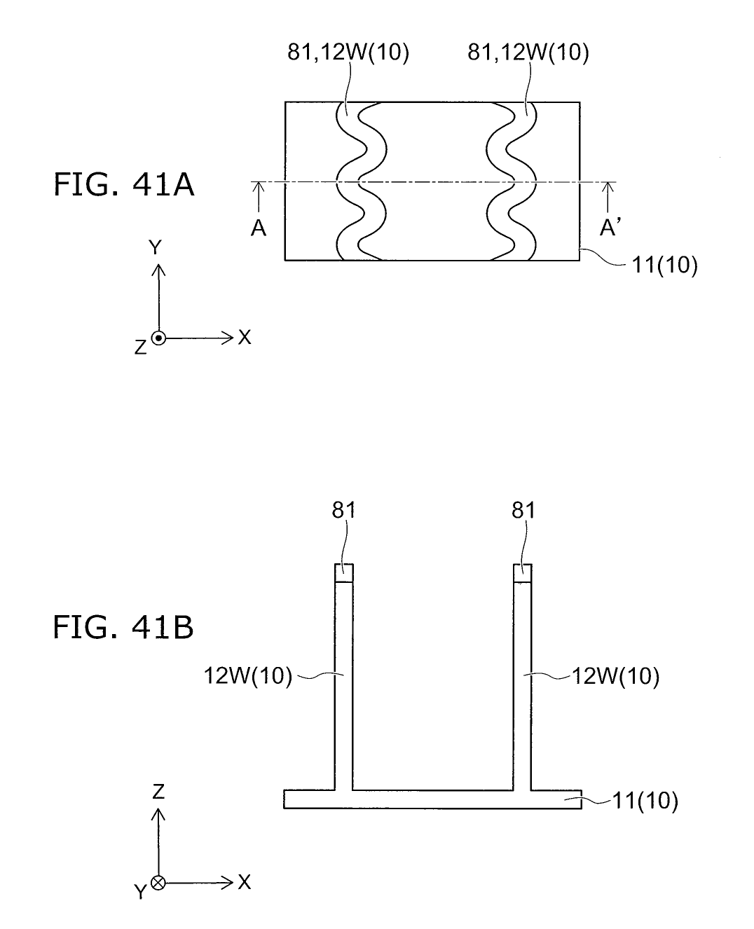

Next, as shown in FIGS. 41A and 41B, the first portion 11 is etched by using the first insulating film 81 remaining, as a mask. The part masked with the first insulating film 81 in this etching serves as the second portion 12W that extends in the Z-axis direction. The shape along the Z-axis of the second portion 12W is the same wave shape as the shape of the first insulating film 81.

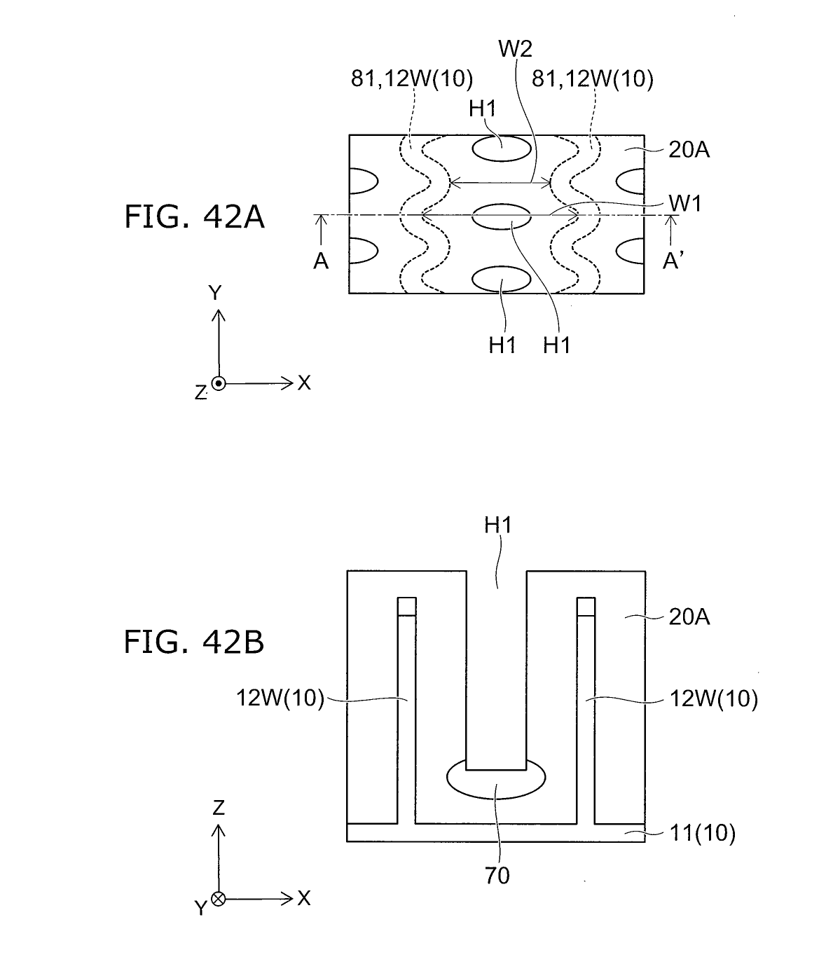

As shown in FIGS. 42A and 42B, the epitaxial growth of the second semiconductor material 20A is performed. The second semiconductor material 20A is grown on the surface of the first portion 11 and the surface of the second portion 12W. As the crystal growth proceeds, the second semiconductor material 20A is buried at the portion of the narrow interval W2 between the adjacent two second portions 12. Although the second semiconductor material 20A is formed also at the portion of the wide interval W2 between the adjacent two second portions 12W, a space is left in a part of the portion of the interval W1. This space serves as the holes H1.

Since the wide interval W1 and the narrow interval W2 which are provided between the adjacent two second portions 12W are repetitively provided, the holes H1 provided in the portion of the wide interval W1 are provided in a plurality along the Y-axis direction.

After the portion of the interval W2 is filled with the second semiconductor material 20A, when the time etc. of the crystal growth of the portion of the interval W1 with the second semiconductor material 20A is adjusted , the aperture size and the depth of the holes H1 are adjusted.

After forming the second semiconductor material 20A, the electric field relaxation region 70 is formed in the second semiconductor material 20A in a vicinity of the bottom portions of the holes H1.

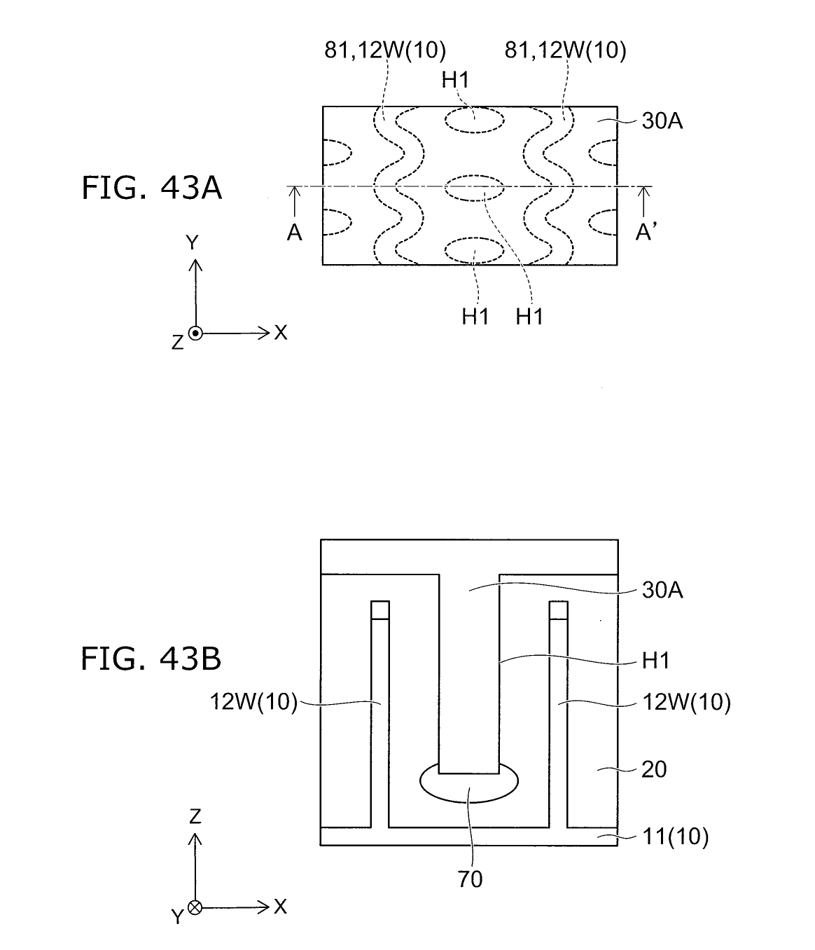

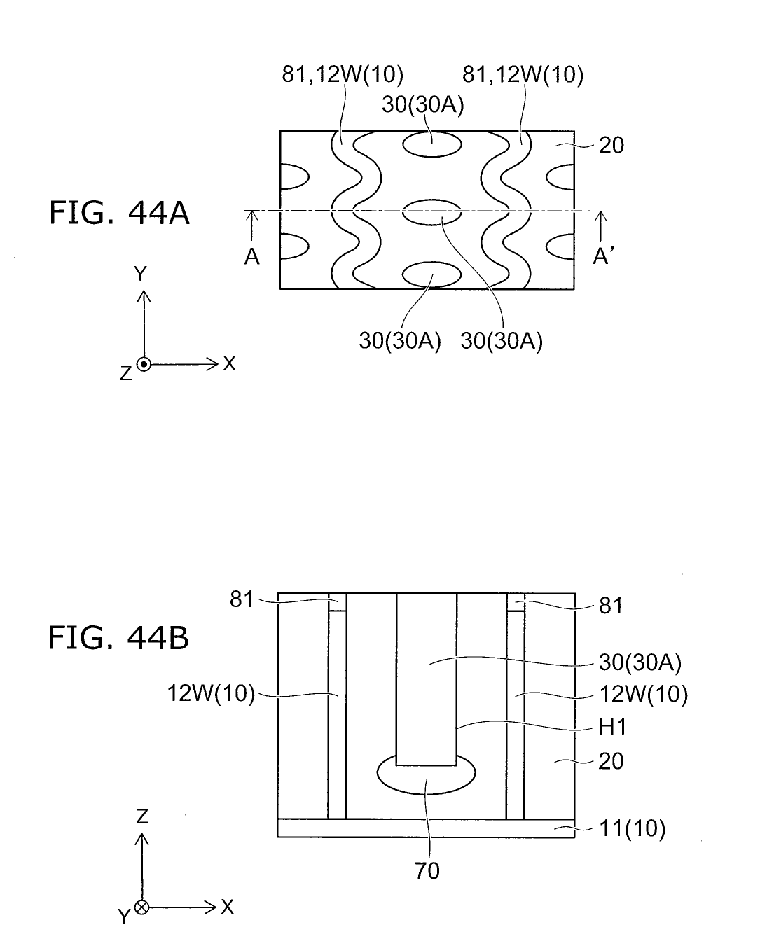

Next, as shown in FIGS. 43A and 43B, the third semiconductor material 30A is buried in the holes H1. The third semiconductor material 30A is also formed on the upper side of the semiconductor region 20. Next, as shown in FIGS. 44A and 44B, the third semiconductor material 30A formed on the upper side of the second semiconductor region 20 is removed, for example, by the CMP. The exposed face is flattened by the CPM. The third semiconductor material 30A that remains in the holes H1 serves as the third semiconductor region 30.

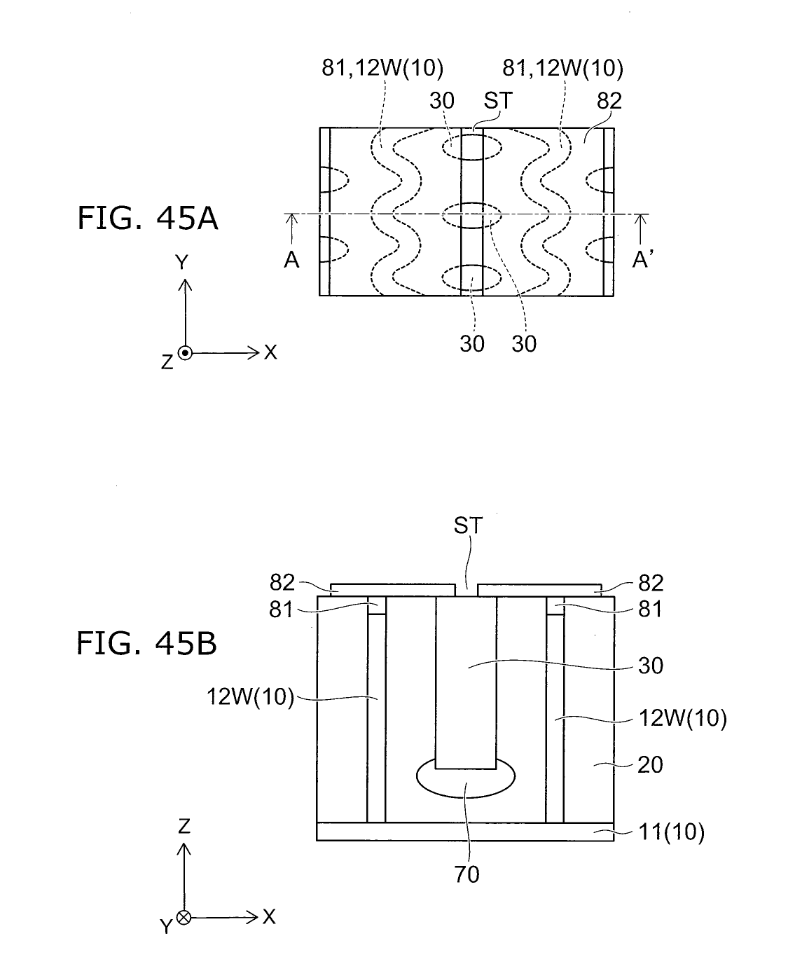

Next, as shown in FIGS. 45A and 45B, the second insulating film 82 is formed on the flattened exposed face, and an aperture ST is formed in a part of the second insulating film 82. The aperture ST is formed between the two second portions 12 so as to penetrate the plurality of third semiconductor regions in the Y-axis direction.

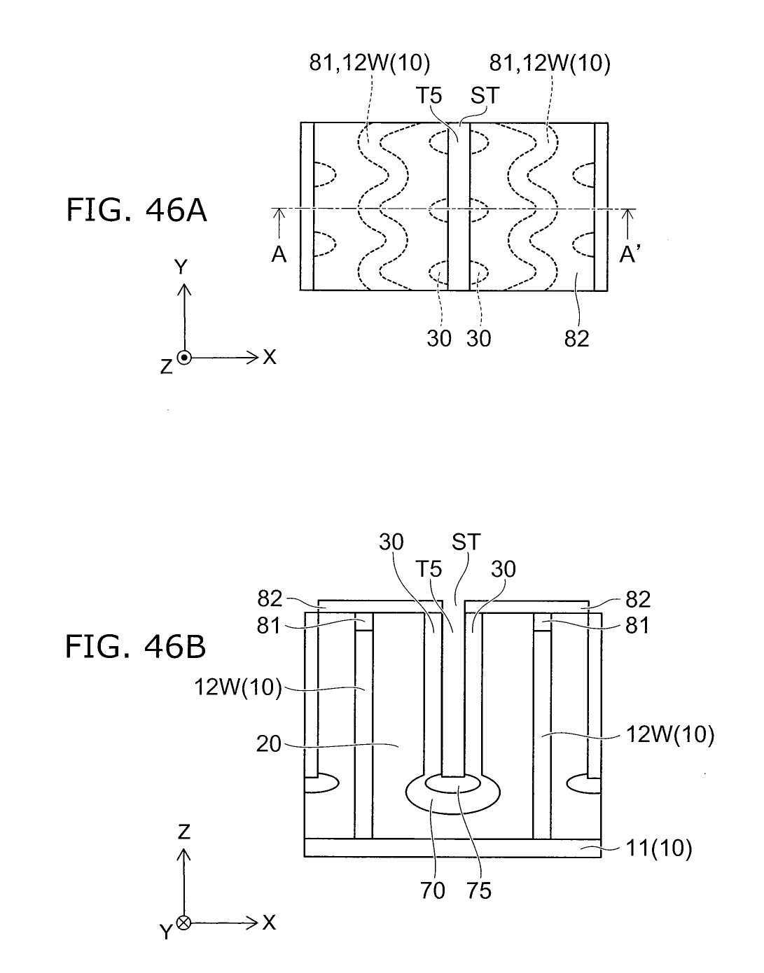

Then, as shown in FIGS. 46A and 46B, the trench T5 is formed in the third semiconductor region 30 and the second semiconductor region 20 via the aperture ST of the second insulating film 82. The trench T5 is formed so as to be shallower than the depth of the third semiconductor region 30 in the Z-axis direction. The trench T5 is formed so as to penetrate the plurality of third semiconductor regions 30 in the Y-axis direction. After forming the trench T5, the electric field relaxation region 75 is formed as necessary in a vicinity of the bottom portion of the trench T5.

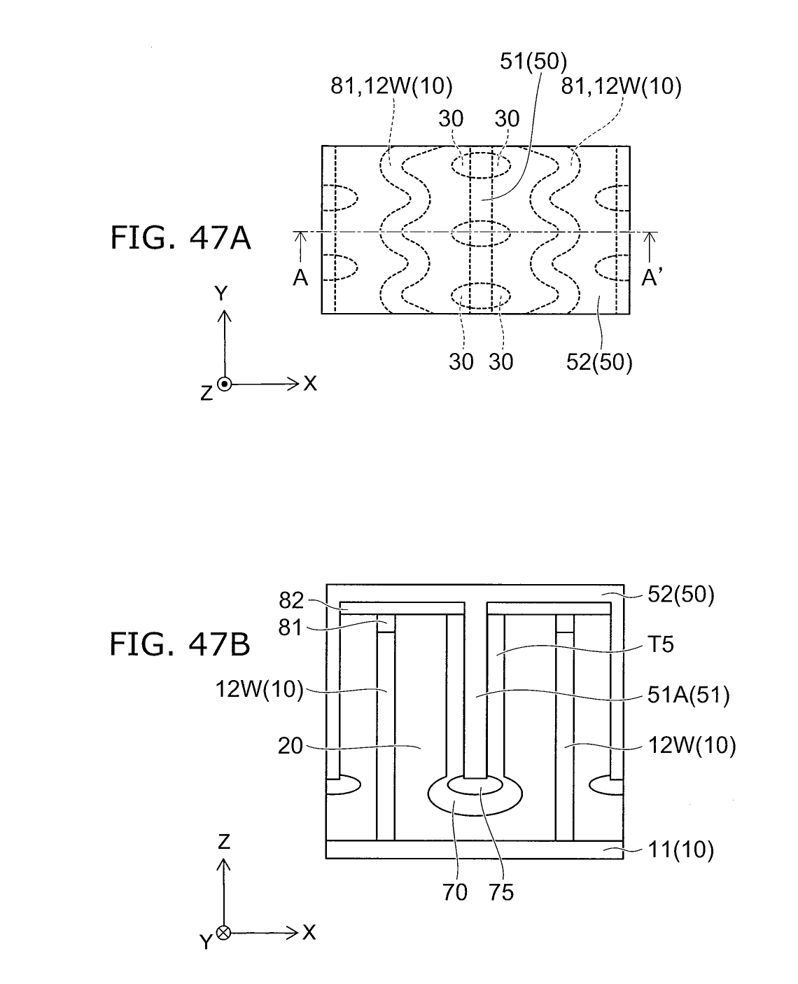

Next, as shown in FIGS. 47A and 47B, the third portion material 51A is buried in the trench T5. The third portion material 51A buried in the trench T5 serves as the third portion 51. The third portion material 51A is formed to cover the second insulating film 82. This portion serves as the intermediate electrode 52. The intermediate electrode 52 is flattened.

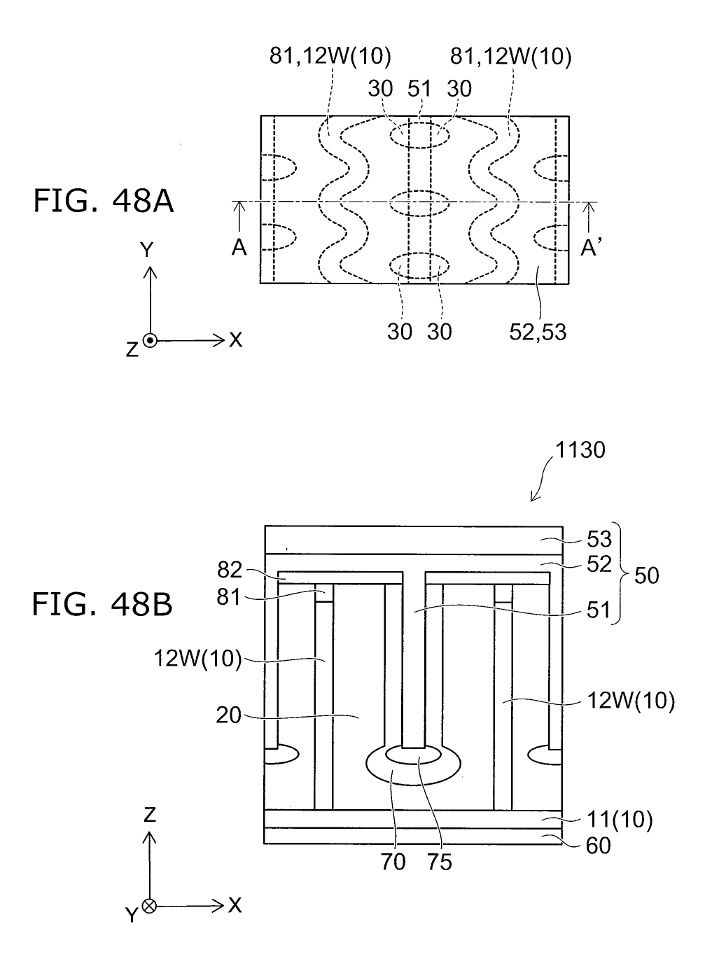

Next, as shown in FIGS. 48A and 48B, the upper electrode 53 is formed on the intermediate electrode 52. Furthermore, the second electrode 60 is formed under the first portion 11. Thereby, the semiconductor device 1130 is completed.

According to the foregoing manufacturing method, the trench formed in the manufacturing process of the semiconductor device 1130 is only the trench T5.

### Fifteenth Embodiment

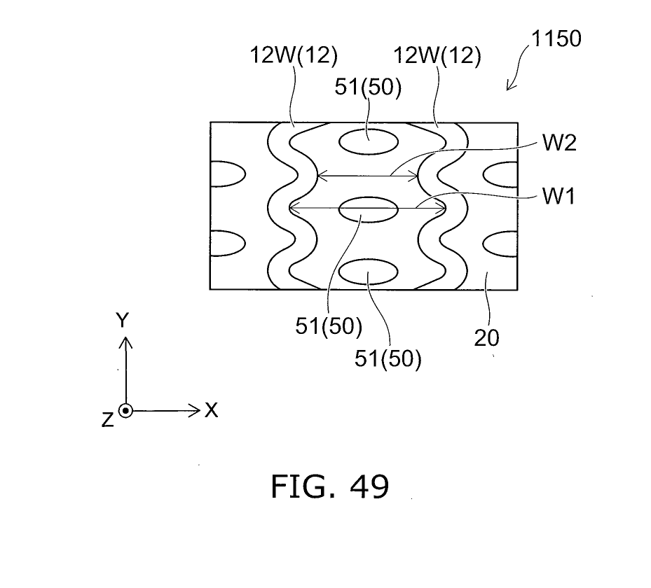

FIG. 49 is a schematic plan view illustrating the configuration of a semiconductor device according to a fifteenth embodiment.

In FIG. 49, the first insulating film 81, the second insulating film 82, the intermediate electrode 52 and the upper electrode 53 are omitted.

As shown in FIG. 49, a semiconductor device 1150 according to the fifteenth embodiment includes at least the second semiconductor region 20, the second portion 12 and the third portion 51. In the second semiconductor device 1150, the shape of the second portion 12 when seen along the Z-axis direction has a wave shape (second portion 12A). The second portion 12W is the same as the second portion 12W of the semiconductor device 1130.

The third portion 51 is formed at the position between the two second portions 12W so as to have the width W1. The shape of the third portion 51 when seen in the Z-axis direction is an elliptical, oval or circular shape. For example, the shape of the third portion 51, facing the second portion 12W is similar to the shape of the face of the second portion 12W, facing the third portion 51. That is, a part of the outer shape of the third portion 51 when seen in the Z-axis direction is similar to the outer shape of the second portion 12W when seen in the Z-axis direction.

In the semiconductor device 1150, since the shape of the second portion 12W when seen in the Z-axis direction is a wave shape, an area of the interface between the second portion 12W and the second semiconductor region 20 per the same length along the Y-axis direction is increased as compared with the case of the semiconductor device provided with the second portion 12 in a linear shape when seen in the Z-axis direction.

Moreover, in the semiconductor device 1150, the face of the third portion 51, facing the second portion 12W follows the same of the second portion 12W. Therefore, as compared with the device having the second portion 12 and the third portion 51 in linear shape, the current path (the current path formed between the second portion 12W and the third portion 51) per the same length along the Y-axis increases. Thereby, VF is reduced in the semiconductor device 1150. In contrast, in the case of obtaining the same VF as that obtained in the device having the liner second portion 12 and the third portion 51, the size of the element along the Y-axis can be reduced in the semiconductor device 1150.

### Sixteenth Embodiment

A sixteenth embodiment relates to a method of manufacturing a semiconductor device.

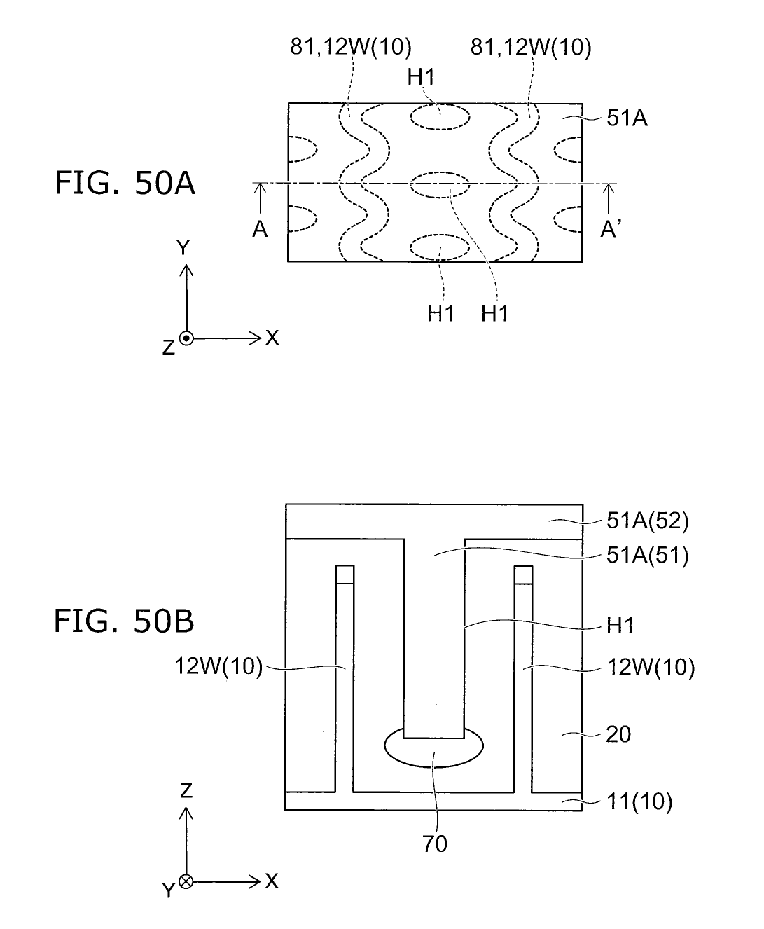

FIGS. 50A to 50B are schematic views describing a method of manufacturing the semiconductor device according to the fifteenth embodiment.

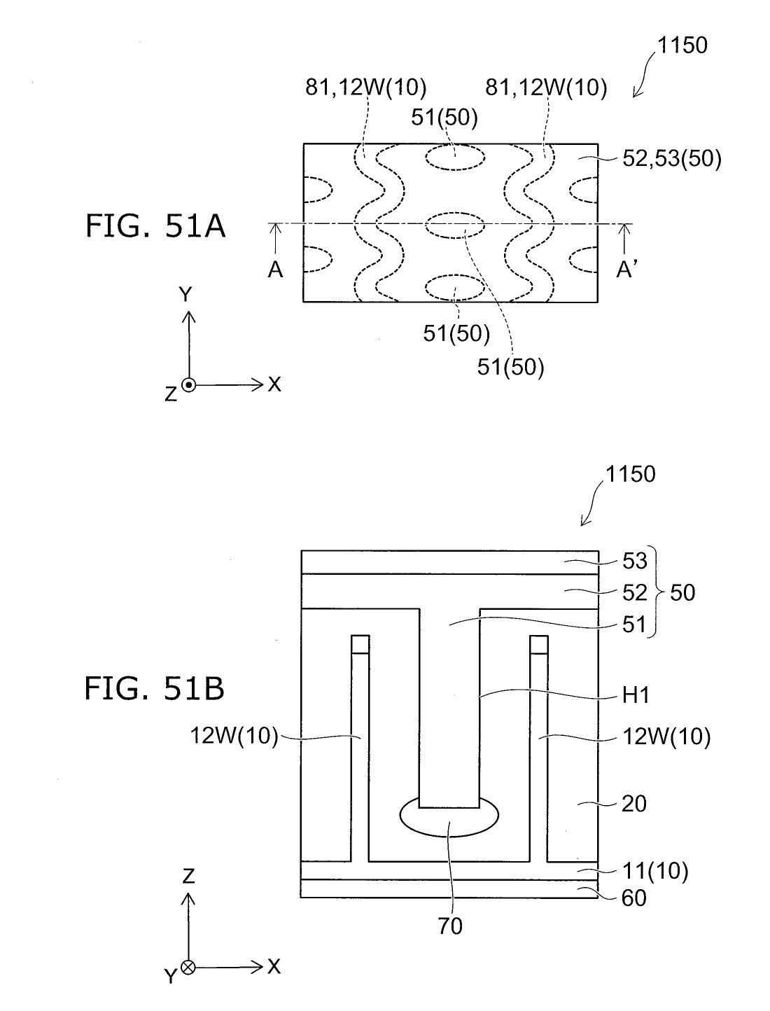

In each of FIG. 50A to FIG. 51B, A shows a schematic plan view, and B shows a schematic cross-sectional view taken along the line A-A′ shown in A.

First, the second portion 12W in a wave shape is formed on the upper portion 11, and the second semiconductor region 20 is formed between the plurality of the second portions 12W to form holes H1 at the portion of a wide interval W1 between the adjacent two second portions 12W. Up to this stage, the processes are the same as the processes in the fourth embodiment shown in FIG. 40A to FIG. 42B.

Next, as shown in FIGS. 50A and 50B, the third portion material 51A is buried in the holes H1. The third portion material 51A is formed also on the upper side of the second semiconductor region 20. The surface of the third portion material 51A is flattened. The portion of the third portion material 51A, buried in the holes H1 serves as the third portion 51. The portion formed on the upper side of the second semiconductor region 20 of the third portion material 51A serves as the intermediate electrode 52.

Then, as shown in FIGS. 51A and 51B, the upper electrode 53 is formed on the intermediate electrode 52.

Furthermore, the second electrode 60 is formed under the first portion 11. Thereby, the semiconductor device 1150 is completed.

### Seventeenth Embodiment

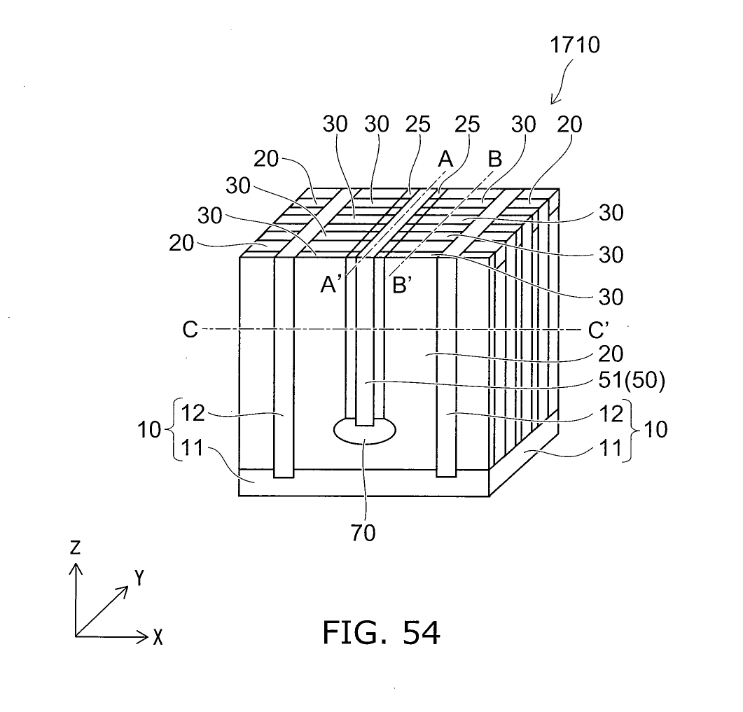

FIG. 54 is a schematic perspective view illustrating the configuration of a semiconductor device according to a seventeenth embodiment.

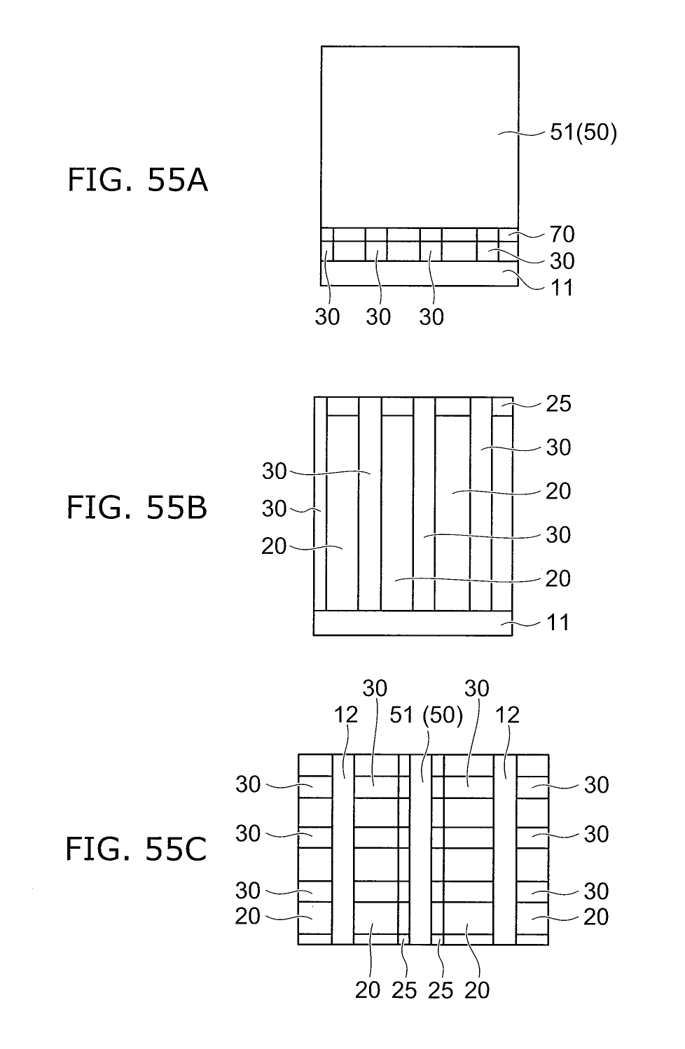

FIGS. 55A to 55C are schematic cross-sectional views of the semiconductor device according to the seventeenth embodiment.

FIG. 55A is a schematic cross-sectional view along A-A′ line shown in FIG. 54, FIG. 55B is a schematic cross sectional view along B-BC′ line shown in FIG. 54, and FIG. 55C is a schematic cross-sectional view along C-C′ line shown in FIG. 54.

In FIG. 54 and FIGS. 55A to 55C, the upper electrode 53 and the second electrode 60 are omitted.

As shown in FIG. 54, a semiconductor device 1710 according to the seventeenth embodiment is different in the configuration of the third semiconductor region 30 compared with the semiconductor device 120 (see FIG. 4) according to the second embodiment.

As shown in FIGS. 55A to 55C, the third semiconductor region 30 in the semiconductor device 1710 is in contact with the first portion 11. Furthermore, the third semiconductor region 30 in the semiconductor device 1710 extends from the second portion 12 to the third portion 51. That is, the third semiconductor region 30 in the semiconductor device 1710 penetrates through the second semiconductor region 20 provided between the second portion 20 and the third portion 30 in the X-axis direction.

The semiconductor device 1710 is provided with a plurality of third semiconductor regions 30. The plurality of third semiconductor regions 30 are disposed at a predetermined interval in the Y-axis direction.

The concentration adjustment region 25 may be provided between the third portion 51 and the second portion 12.

In the foregoing configuration of the third semiconductor region 30, when a reverse voltage is applied to the semiconductor device 1710, the depletion layer at the interface (pn junction face) between the third semiconductor region 30 and the second semiconductor region 20 spreads between the second portion 12 and the third portion 51, and the breakdown voltage can be improved.

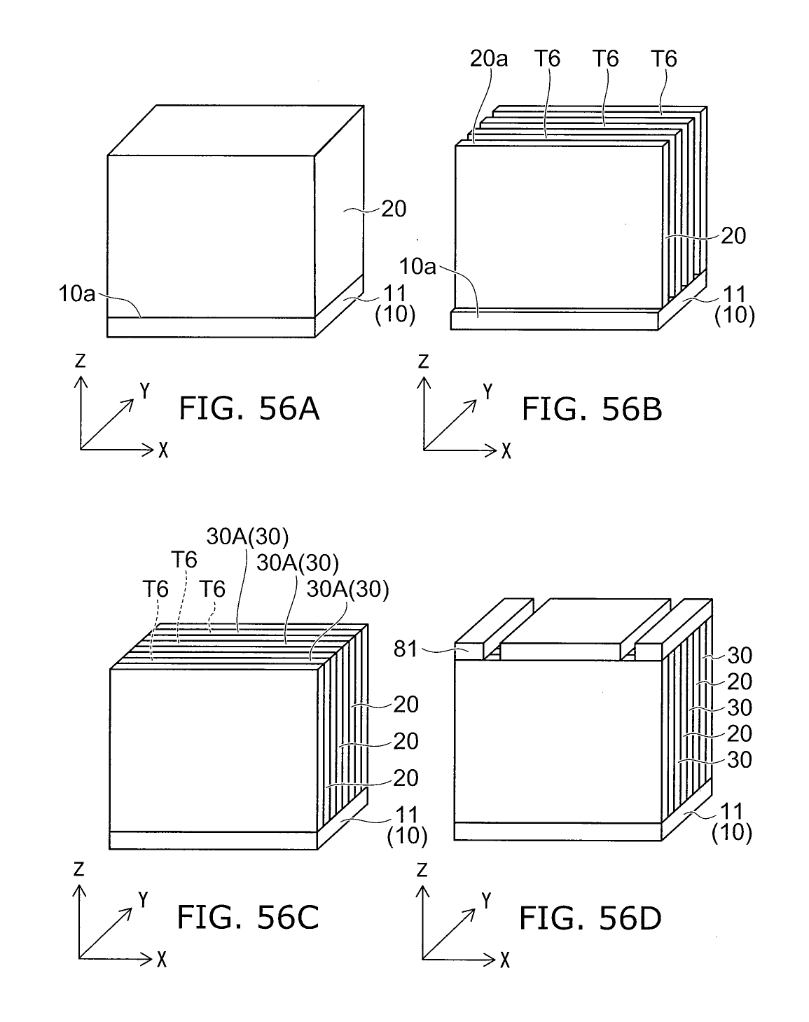

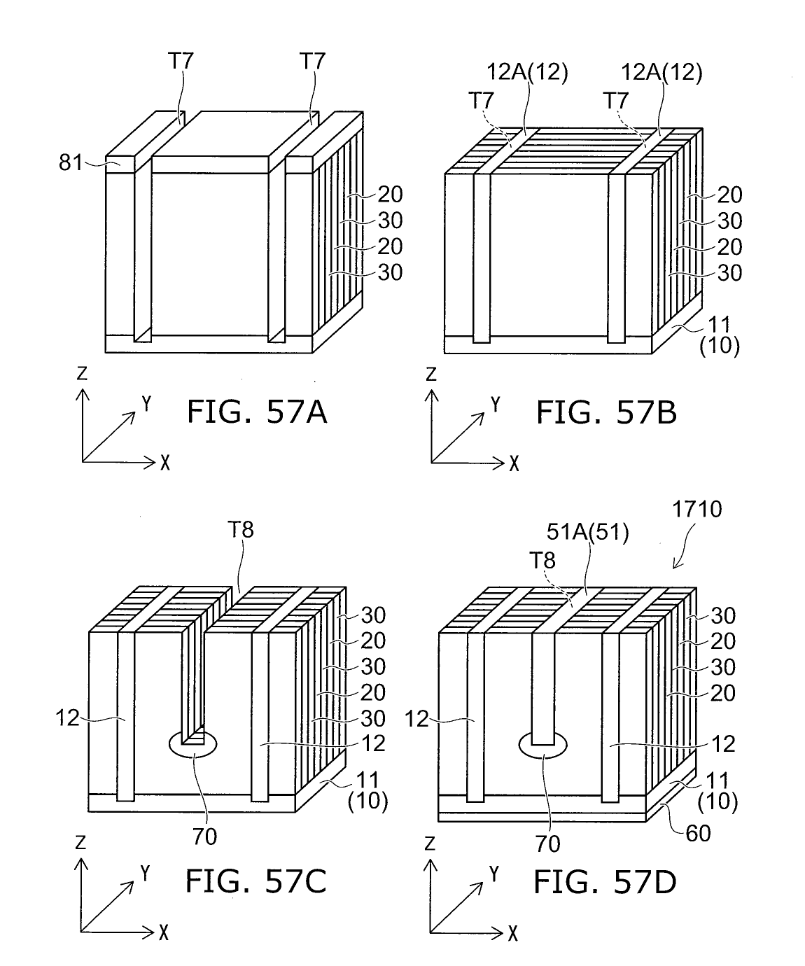

FIG. 56A to FIG. 57D are schematic perspective views illustrating a method for manufacturing the semiconductor device according to the seventeenth embodiment.

First, as shown in FIG. 56A, the second semiconductor region 20 is, for example, epitaxially grown on the first major surface 10a of the first portion 11 that is the first semiconductor region 10.

Next, as shown in FIG. 56B, a plurality of trenches T6 are formed in the second semiconductor region 20. The plurality of trenches T6 are provided at a predetermined interval in the Y-axis direction. The trenches extend in the X-axis direction and have a depth reaching at least the first major surface 10a of the first portion 11 from an upper surface of the second semiconductor region 20.

In order to form the trenches T6, a mask (not shown) including an aperture on the upper surface 20a is formed and the second semiconductor region 20 is etched via the aperture of the mask by using RIE or the like.

Next, as shown in FIG. 56C, the third semiconductor region material 30A is formed in the plurality of trenches T6. After that, the surface of the third semiconductor region material 30A is flattened by CMP or the like. Thereby, the second semiconductor region 20 and the third semiconductor region 30 are alternately formed on the first portion 11.

Next, as shown in FIG. 56D, the first insulating film 81 is formed on the second semiconductor region 20 and the third semiconductor region 30, and an aperture is formed in the part. SiO₂ formed by thermal oxidation is illustratively used for the first insulating film 81. The second semiconductor region 20 and the third semiconductor region 30 are etched by RIE or the like using the first insulating film 81 including the aperture as a mask. Thereby, as shown in FIG. 57A, a plurality of trenches T7 are formed at a depth reaching the first portion 11 from the upper surface 20a of the second semiconductor region 20 and the third semiconductor region 30. The plurality of trenches T7 extend in the Y-axis direction to be formed.

Next, as shown in FIG. 57B, the second portion material 12A is buried in the trench T7. Polysilicon with a high impurity concentration is, for example, used for the second portion material 12A. The surface of the second portion material is removed, for example, by CMP. Thereby, the second portion 12 is formed in the trench T7.

Next, as shown in FIG. 57C, the trench T8 is formed between the two first portions 12. The trench T8 is formed, for example, by RIE. The trench T8 is formed with a depth reaching the middle from above the second semiconductor region 20 and the third semiconductor region 30. The trench T8 extends in the Y-axis direction to be formed.

After the trench T8 is formed, the electric field relaxation region 70 is formed in the second semiconductor region 20 and the third semiconductor region 30 in a vicinity of the bottom portion of the trench T8. For example, B(boron) is at an angle implanted into the bottom portion of the trench T8 by ion implantation to be thermally diffused. Thereby, the electric field relaxation region 70 is formed.

Next, as shown in FIG. 57D, the third portion material 51A is buried into the trench T8. The third portion material 51A is, for example, a single layer of W, a stacked film of W—Al, or a stacked film forming from Mo, Pt, TiW, V, Ti or the like in place of W in the stacked film of W—Al. The stacked film used as the third portion material 51A may be a silicide layer that is an alloy with silicon. The third portion material 51A buried into the trench T8 serves as the third portion 51 that form a Schottky junction with the second semiconductor region 20 by the sinter processing.

The third portion material 51A is formed to cover the second insulating film 82. This formed portion serves as the intermediate electrode 52. After that, the upper electrode not shown is formed. The second electrode 60 is formed under the first portion 11.

Thereby, the semiconductor device 1710 is completed.

A method for manufacturing the semiconductor device 1710 other than the above is possible. For example, manufacturing is also possible in expanding the trench T4 shown in FIG. 13B in the X-axis direction to the second portions 12 and forming to reach the first portion 11 in the Z-axis direction, and then performing similar processes to FIGS. 13C to 13D.

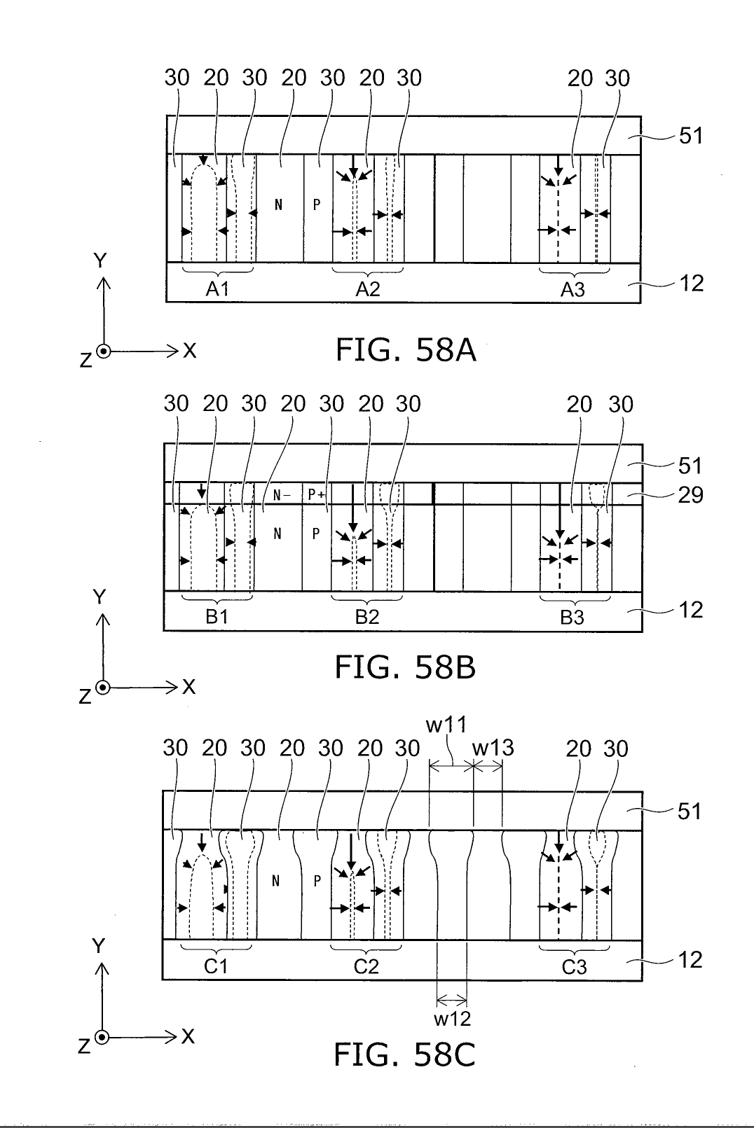

FIGS. 58A to 58C are schematic views illustrating various aspects of the semiconductor device according to the seventeenth embodiment.

FIGS. 58A to 58C show plan views of partial portions between the second portion 12 and the third portion 51 in the semiconductor device 1710.

In an example shown in FIG. 58A, the third semiconductor region 30 is provided with a generally constant between the second portion 12 and the third portion 51. The plurality of third semiconductor region 30 are disposed at a generally constant interval.

In this example, a super junction is formed by charge balance between the adjacent second semiconductor region 20 and the third semiconductor region 30. Reducing VF of a semiconductor device is achieved by the super junction structure.

In a portion shown by Al in FIG. 58A, a depletion region at an initial stage of depletion (for example, applying a voltage of approximately 10% of the breakdown voltage) is shown by a dotted line. In the second semiconductor region 20, the depletion region spreads toward inside the semiconductor region 30 from the interface between the second semiconductor region 20 and the third portion 51 and the interface between the second semiconductor region 20 and the third semiconductor region 30.

In the third semiconductor region 30, the depletion region spreads toward inside the third semiconductor region 30 from the interface between the third semiconductor region 30 and the second semiconductor region 20.

In a portion shown by A2 in FIG. 58A, a depletion region just before complete depletion (for example, applying a voltage of approximately 70% of the breakdown voltage) is shown by a dotted line. The depletion region shown by A2 is more depleted than the depletion region shown by A1.

Thereby, when applying the reverse voltage to the semiconductor device 1710, the second semiconductor region 20 and the third semiconductor region 30 is almost completely depleted and the breakdown voltage can be improved.

In a portion shown by A3 in FIG. 58A, a depletion region after completely depleted (for example, applying a voltage of approximately 90% of the breakdown voltage) is shown by a dotted line. Both the second semiconductor region 20 and the third semiconductor region 30 are almost completely depleted.

In an example shown in FIG. 58B, a concentration adjustment region 29 is included in the second semiconductor region 20 and the third semiconductor region 30. The concentration adjustment region 29 is provided on a side of the third portion 51 of each of the second semiconductor region 20 and the third semiconductor region 30. For example, in the n-type second semiconductor region 20, an impurity concentration on a side of the third portion 51 of the second semiconductor region 20 is lower than an impurity concentration on a side of the second portion 12 of the second semiconductor region 20 by providing the concentration adjustment region 29. For example, in the case where the second semiconductor region 20 on the second portion 12 side is n-type, the second semiconductor region 20 on the third portion 51 side is n⁻-type.

In the p-type third semiconductor region 30, an impurity concentration on the third portion 51 side of the third semiconductor region 30 is higher than an impurity concentration on the second portion 12 side of the third semiconductor region 30 by providing the concentration adjustment region 29. For example, in the case where the third semiconductor region 30 on the second portion 12 side is p-type, the third semiconductor region 30 on the third portion 51 side is n⁻-type.

In a portion shown by B1 in FIG. 58B, a depletion region at an initial stage of depletion (for example, applying a voltage of approximately 10% of the breakdown voltage) is shown by a dotted line. In the second semiconductor region 20, the depletion progresses toward inside the semiconductor region 30 from the interface between the second semiconductor region 20 and the third portion 51 and the interface between the second semiconductor region 20 and the third semiconductor region 30. At this time, the concentration adjustment region 29 (n⁻-type region) of the second semiconductor region 20 is completely depleted. Thereby, an electric field at an interface between the concentration adjustment region 29 and the third portion 51 is kept low and a high voltage leak current can be reduced.

In the third semiconductor region 30, the depletion region spreads toward inside the third semiconductor region 30 from the interface between the third semiconductor region 30 and the second semiconductor region 20.

In a portion shown by B2 in FIG. 58B, a depletion region just before complete depletion (for example, applying a voltage of approximately 70% of the breakdown voltage) is shown by a dotted line. The depletion region shown by B2 is more depleted than the depletion region shown by B1. At this time, complete depletion progresses in the concentration adjustment region 29 of the second semiconductor region 20. Thereby, an electric field at an interface between the concentration adjustment region 29 and the third portion 51 is kept low and a low voltage leak current can be reduced.

In a portion shown by B3 in FIG. 58B, a depletion region after completely depleted (for example, applying a voltage of approximately 90% of the breakdown voltage) is shown by a dotted line. Both the second semiconductor region 20 and the third semiconductor region 30 are almost completely depleted. At this time, a portion not completely depleted exists in the concentration adjustment region 29 (r-type region) of the third semiconductor region 30. Thereby, the electric filed at the interface between the concentration region 29 and the third portion 51 is continuously kept low and a high voltage leak current can be reduced.

As described above, in the structure shown in FIG. 58B, the charge balance between the second semiconductor region 20 and the third semiconductor region 30 forms the super junction structure. Thereby, reducing VF of the semiconductor device 1710 is achieved.

On the other hand, when the reverse voltage is applied in the third portion 51 side of the second semiconductor region 20 and the third semiconductor region 30, while the complete depletion progresses in the second semiconductor region 20, a portion not depleted remains in the third semiconductor region 30. Thereby, the electric field at the Schottky interface (Schottky barrier face) between the third portion 51 and the second semiconductor region 20 is suppressed from increasing and the leak current can be reduced.

In an example shown in FIG. 58C, a width w11 on the third portion 51 side of the third semiconductor region 30 is more widely provided than a width w12 on the second portion 12 side. The width w11 on the third portion 51 side of the third semiconductor region 30 is more widely provided than a width w13 on the third portion 51 side of the second semiconductor region 20. Furthermore, the plurality of third semiconductor regions 30 are disposed at a generally constant interval

In a portion shown by C1 in FIG. 58C, a depletion region at an initial stage of depletion (for example, applying a voltage of approximately 10% of the breakdown voltage) is shown by a dotted line. In the second semiconductor region 20, the depletion region spreads toward inside the semiconductor region 30 from the interface between the second semiconductor region 20 and the third portion 51 and the interface between the second semiconductor region 20 and the third semiconductor region 30.

In the third semiconductor region 30, the depletion region spreads toward inside the third semiconductor region 30 from the interface between the third semiconductor region 30 and the second semiconductor region 20. At this time, since the width on the third portion 51 side of the third semiconductor region 30 is narrower than the width on the third portion 51 side of the second semiconductor region 20, the the third semiconductor region 30 is more depleted than the second semiconductor region 20.

In a portion shown by C2 in FIG. 58C, a depletion region just before the complete depletion (for example, applying a voltage of approximately 70% of the breakdown voltage) is shown by a dotted line. The depletion region shown by C2 is more depleted than the depletion region shown by C1. At this time, the complete depletion progresses in the second semiconductor region 20. Thereby, an electric field at an interface between the second semiconductor region 20 and the third portion 51 is continuously kept low and a high voltage leak current can be reduced.

As described above, in the structure shown in FIG. 58C, the charge balance between the second semiconductor region 20 and the third semiconductor region 30 forms the super junction structure. Thereby, reducing VF of the semiconductor device 1710 is achieved.

On the other hand, when the reverse voltage is applied in the third portion 51 side of the second semiconductor region 20 and the third semiconductor region 30, while the complete depletion progresses in the second semiconductor region 20, a portion not depleted remains in the third semiconductor region 30. Thereby, the electric field at the Schottky interface (Schottky barrier face) between the third portion 51 and the second semiconductor region 20 is suppressed from increasing and the leak current can be reduced.

FIG. 59 is a view illustrating characteristics of a leak current.

FIG. 59 shows characteristics F1 to F3 of the leak current. The characteristic F1 is a leak characteristic in the configuration example shown in FIG. 59A, the characteristic F2 is a characteristic in the configuration example shown in FIG. 58B, the characteristics F3 is a characteristic in the configuration example shown in FIG. 58C.

In FIG. 59, a horizontal axis represents a reverse voltage VR, and a vertical axis represents a leak current IR.

As shown in FIG. 59, in the characteristics F1 to F3, the leak current IR is effectively suppressed in order of the characteristic F2, the characteristic F3 and the characteristic F1.

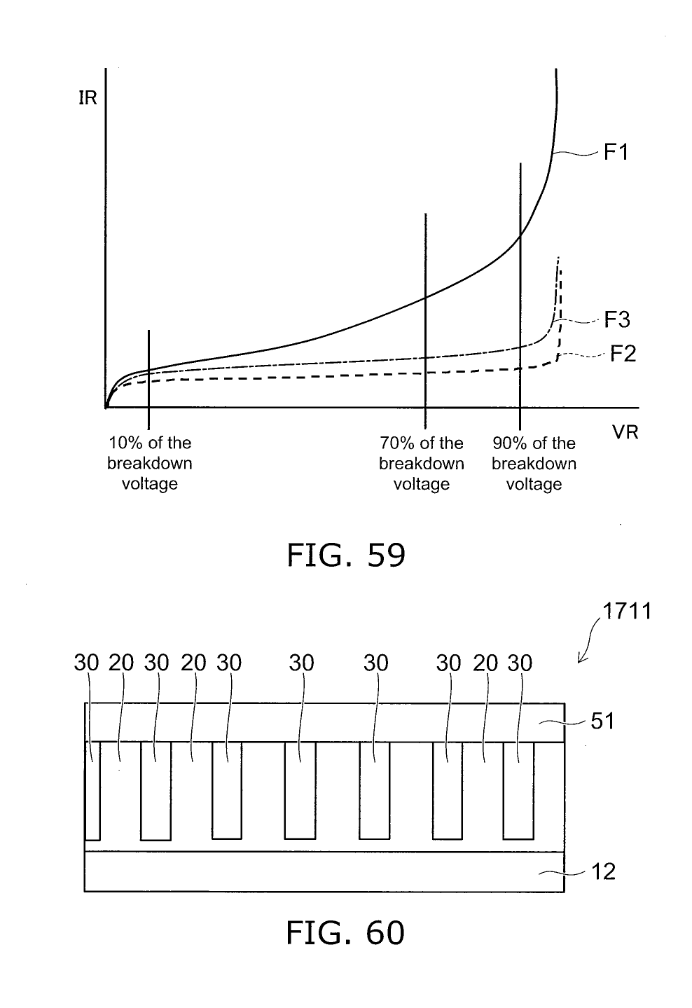

FIG. 60 is a schematic view showing another example of the semiconductor device according to the seventeenth embodiment.

FIG. 60 shows a plan view of a partial portion between the second portion 12 and the third portion 51. A semiconductor device 1711 has the configuration in which the third semiconductor region 30 of the semiconductor device 1170 shown in FIG. 54 does not reach the second portion 12. The third semiconductor region 30 reaches the first portion 11.

As described above, the structure in which the third semiconductor region 30 may not reach the second portion 12 can be applied to various aspects shown in FIGS. 58A to 58C.

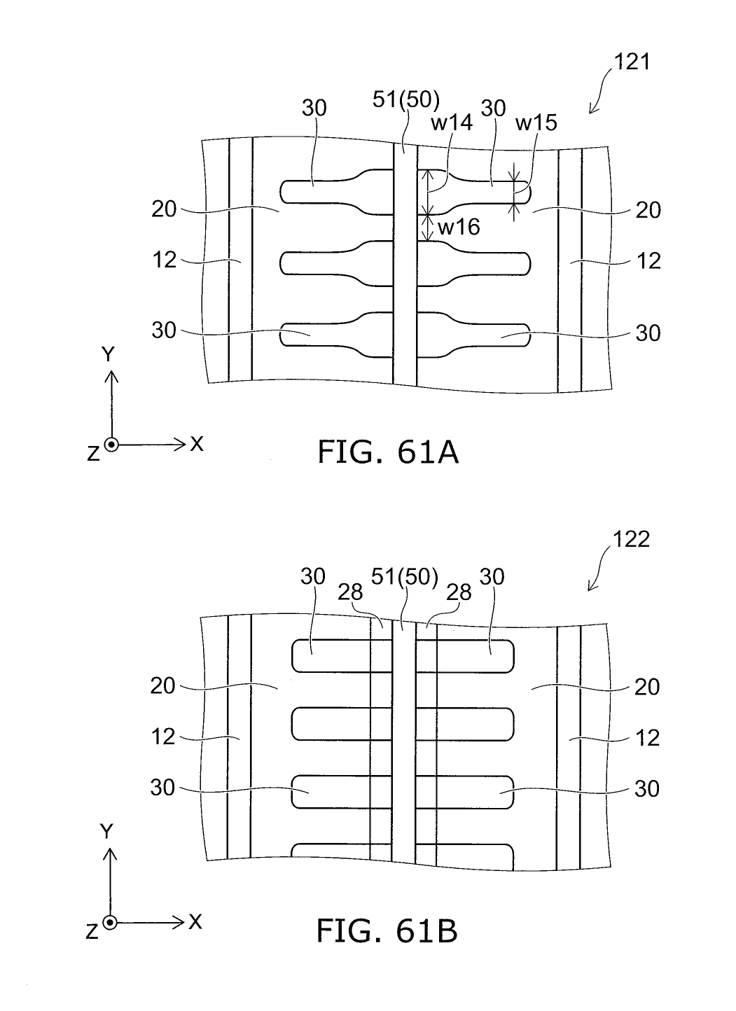

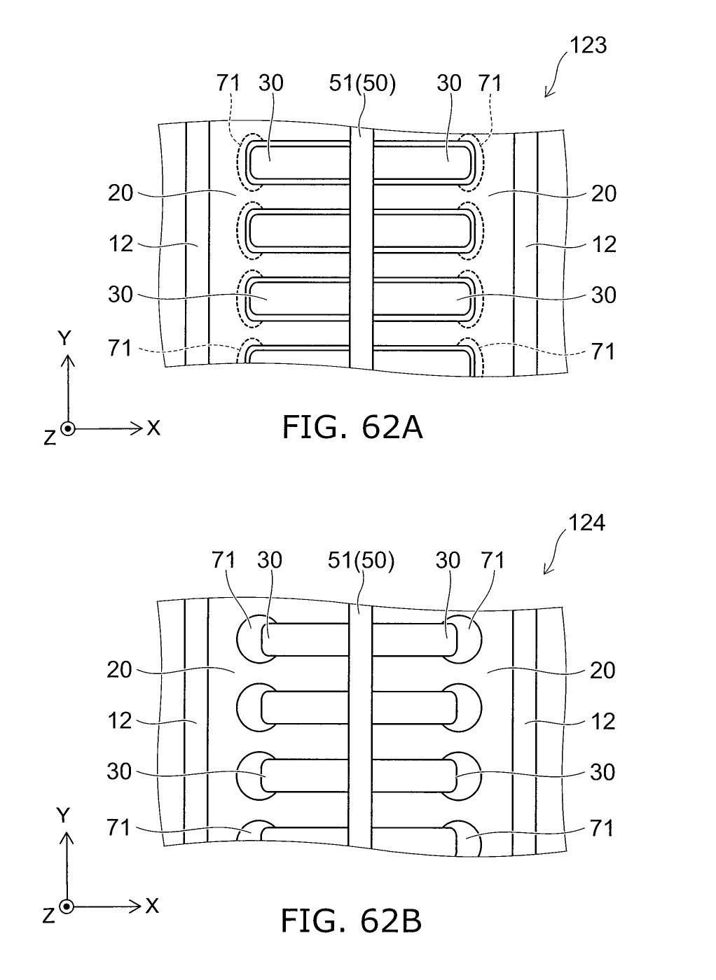

FIG. 61A to FIG. 62B are schematic plan views showing a variation of the second embodiment.

In a semiconductor device 121 shown in FIG. 61A, a width w14 on the third portion 51 side of the third semiconductor region 30 is more widely provided than a width w15 on the second portion 12 side. The width w14 on the third portion 51 side of the third semiconductor region 30 is more widely provided than a width w16 on the third portion 51 side.

In the semiconductor device 121, balance adjustment between the width w14 of the third semiconductor region 30 and the width w16 of the second semiconductor region 20 adjusts the charge balance between the third semiconductor region 30 and the second semiconductor region 20. For example, a charge amount in the third semiconductor region 30 is the same as that in the second semiconductor region 20, the super junction structure is formed and reduction of VF can be achieved.

Since the width w14 is wider than the width w15, when the reverse voltage is applied, while the complete depletion progresses in the second semiconductor region 20, the portion not depleted remains in the third semiconductor region 30. Thereby, the electric field at the Schottky interface (Schottky barrier face) between the third portion 51 and the second semiconductor region 20 is suppressed from increasing and the leak current can be reduced.

In a semiconductor device 122 shown in FIG. 61B, a concentration adjustment region 28 is provided on the third portion 51 side of the second semiconductor region 20. In contrast to the n-type second semiconductor region 20, the concentration adjustment region 28 is n⁺-type.

Thereby, a specific resistance of a portion of the second semiconductor region 20 provided with the concentration adjustment region 28 is lower than a specific resistance of a portion not provided with the concentration adjustment region 28.

Thus, in the semiconductor device 122, an ON resistance is lowered and then the reduction of VF is achieved.

In a semiconductor device 123 shown in FIG. 61B, doped polysilicon is used for the third semiconductor region 30. Doped polysilicon is polysilicon doped with, for example, boron.

For manufacturing this semiconductor device 123, as shown in FIG. 13C, the doped silicon is used for the third semiconductor material 30 buried in the trench T4. The doped polysilicon is buried in the trench T4 by, for example, CVD. After burying the doped polysilicon in the trench T4, the impurity (for example, boron) is diffused by a thermal treatment. Thereby, a diffusion region 31 (for example, p⁺-type) is formed around the third semiconductor region 30.

By using the doped polysilicon for the third semiconductor region 30, the third semiconductor region 30 is easily formed by CVD or the like, and manufacturing cost of the semiconductor device 123 is reduced.

In a semiconductor device 124 shown in FIG. 62B, an electric field relaxation region 71 is provided in a vicinity of an end portion on the second portion 12 side of the third semiconductor region 30 between the third semiconductor region 30 and the second portion 12 in the second semiconductor region 20. The electric field relaxation region 71 is a p⁻-type or n⁻-type region. Providing the electric field relaxation region 71 relaxes the electric field concentration at the end portion of the third semiconductor region 30 on the second portion 12 side, and improves the breakdown voltage.

The electric field relaxation region 71 may be applied to the semiconductor device 123 shown in FIG. 62A. In the case where the electric field relaxation region 71 is applied to the semiconductor device 123, the electric field relaxation region 71 is a p-type, p⁻-type or n⁻-type region. Thereby, the breakdown voltage of the semiconductor device 123 is improved.

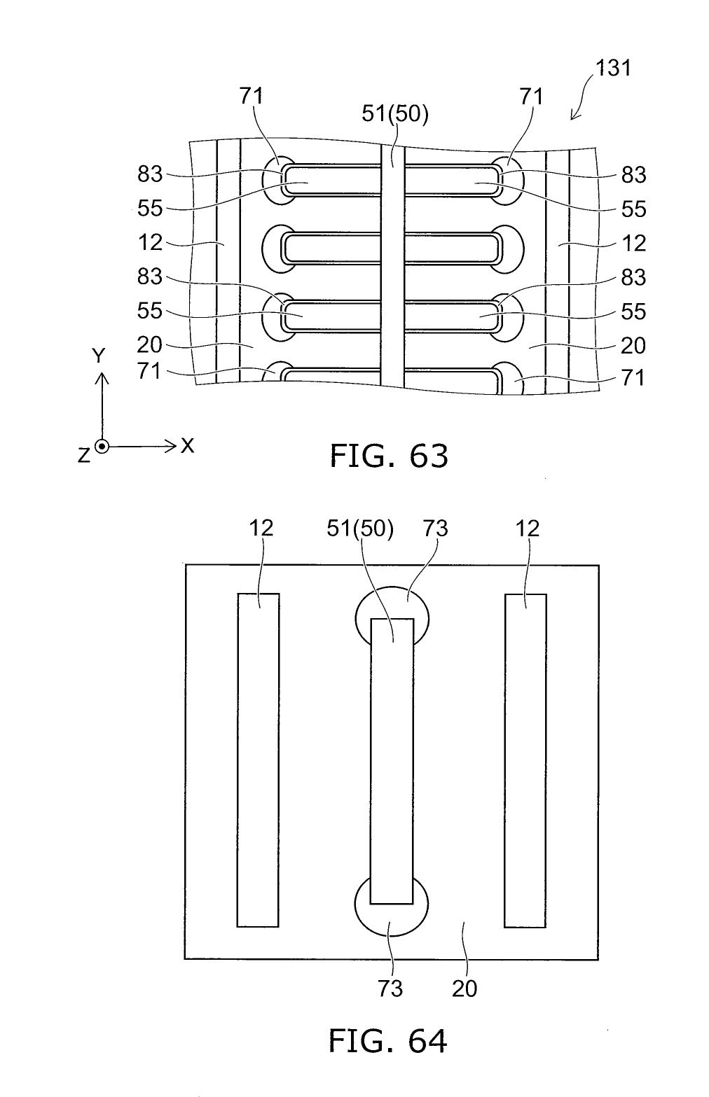

FIG. 63 is a schematic plan view showing a variation of the third embodiment.

A semiconductor device 131 shown in FIG. 63 is a variation of the semiconductor device 130 (see FIGS. 6A to 6B) according to the third embodiment.

In the semiconductor device 131, the electric field relaxation region 71 is provided in a vicinity of the end portion on the second portion 12 side of the fourth portion 55 between the third insulating film 83 and the second portion 12 in the second semiconductor region 20. The electric field relaxation region 71 of the semiconductor device 131 is a p-type, p⁻-type or n⁻-type region. Providing the electric field relaxation region 71 relaxes the electric field concentration at the end portion on the second portion 12 side of the fourth portion 55, and improves the breakdown voltage.

In FIG. 64, for convenience of description, the third portion 51, the second portion 12 and the second semiconductor region 20 are shown. An electric field relaxation region 73 is provided in a vicinity of the end portion 51a of the third portion 51 in the second semiconductor region 20. The electric field relaxation region 73 is a p-type, p⁻-type or n⁻-type region. Providing the electric field relaxation region 73 relaxes the electric field concentration at the end portion 51 of the third portion 51, and improves the breakdown voltage.

This electric field relaxation region 73 can be applied to the semiconductor devices according to any embodiments described above.

As described above, according to the semiconductor device and the manufacturing method according to the embodiment, it is possible to reduce a drop in forward voltage without increasing the element area.

Although the embodiment and modifications thereof are described above, the invention is not limited to these examples. For example, additions, deletions, or design modifications of components or appropriate combinations of the features of the embodiments appropriately made by one skilled in the art in regard to the embodiments or the modifications thereof described above are within the scope of the invention to the extent that the purport of the invention is included.

For example, in each of the above embodiments and variations, descriptions have been given for the case where the first conductivity is the n-type, and the second conductivity is the p-type. However, the embodiment is practicable also in the case where the first conductivity type is the p-type and the second conductivity type is the n-type.

In any of the foregoing semiconductor devices 120, 130 and 140, the length (depth) of the third portion 51 in the Z-axis direction is formed shallower than the depth of the trench T4 in the Z-axis direction. However, the length (depth) of the third portion 51 in the Z-axis direction may be formed in the same depth as the trench T4 or deeper than the trench T4.

Moreover, the first insulating film 81 provided on the second portions 12 and 12W is not necessarily needed in the semiconductor device. That is, may be removed by etching or by the CMP after using the first insulating film 81 as a mask for forming the second portion 12 or 12W in midstream of manufacturing the semiconductor device.

Furthermore, in each of the foregoing embodiments and variations, descriptions have been given on the MOSFET using Si (silicon) for the semiconductor. However, as the semiconductor, a compound semiconductor such as SiC (silicon carbide) or GaN (gallium nitride) or the like, or a wide band gap semiconductor such as a diamond or the like may be used.

In the embodiments described above, the semiconductor regions having impurity concentrations adjusted have been described as examples of the electric field relaxation regions 70, 71, 72 and 73, however the electric field relaxation regions 70, 71, 72 and 73 may be regions made of insulating materials.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

### (First Aspect)

According to a first aspect of the embodiment, there is provided a semiconductor device, comprising:
a first semiconductor region of a first conductivity type, including a first portion including a first major surface and a second portion extending in a first direction perpendicular to the first major surface on the first major surface;
a first electrode including a third portion that is a metal region provided so as to face the second portion, and provided so as to be separated from the first semiconductor region;
a second semiconductor region of the first conductivity type provided between the second portion and the third portion, including a first concentration region having an impurity concentration lower than an impurity concentration in the first semiconductor region, and forming a Schottky junction with the third portion; and
a second electrode provided on an opposite side of the first major surface of the first portion and being in conduction with the first portion.

### (Second Aspect)

There is provided a device according to the first aspect, further comprising a first electric field relaxation region provided between the third portion and the first portion.

### (Third Aspect)

There is provided a device according to the first aspect, further comprising a third semiconductor region of the second conductivity type, the third semiconductor region extending in a second direction connecting the third portion and the second portion, extending in the first direction, and being in conduction with the first electrode.

### (Fourth Aspect)

There is provided a device according to the third aspect, wherein the third semiconductor region is in contact with the first portion.

### (Fifth Aspect)

There is provided a device according to the third aspect, wherein the third semiconductor region extends from the second portion to the third portion and is in contact with the first portion.

### (Sixth Aspect)

There is provided a device according to the third aspect, wherein in the adjacent second semiconductor region and the third semiconductor region, an impurity concentration in the third semiconductor region is higher than the impurity concentration in the second semiconductor region.

### (Seventh Aspect)

There is provided a device according to the third aspect, wherein charge balance is unbalanced in the adjacent second semiconductor region and the third semiconductor region.

### (Eighth Aspect)

There is provided a device according to the third aspect, wherein charge balance is balanced in the adjacent second semiconductor region and the third semiconductor region.

### (Ninth Aspect)

There is provided a device according to the third aspect, wherein a width of the third semiconductor region along a third direction perpendicular to the first direction and the second direction is wider than a width of the third semiconductor region along the third direction.

### (Tenth Aspect)

There is provided a device according to the second aspect, wherein the first electric field relaxation region is provided so as to surround an end portion on a side of the first portion of the third portion.

### (Eleventh Aspect)

There is provided a device according to the third aspect, wherein
an outer shape along the first direction of the second portion is provided in a wave shape, and
a part of an outer shape along the first direction of the third semiconductor region is similar to the outer shape of the second portion.

### (Twelfth Aspect)

There is provided a device according to the first aspect, further comprising:
a plurality of third semiconductor regions of a second conductivity type being in conduction with the first electrode,
the third portion is provided in a plurality,
the plurality of third portions are provided so as to be separated in a direction perpendicular to the first direction, and
one of the plurality of third semiconductor regions being provided between adjacent portions of the plurality of third portions.

### (Thirteenth Aspect)

There is provided a device according to the third aspect, wherein
the second semiconductor region further includes a fifth concentration region provided between the first concentration region and the third portion and having an impurity concentration lower than the impurity concentration in the first concentration region.

### (Fourteenth Aspect)

There is provided a device according to the third aspect, wherein
the second semiconductor region further includes a sixth concentration region provided between the first concentration region and the third portion and having an impurity concentration higher than the impurity concentration in the first concentration region.

### (Fifteenth Aspect)

There is provided a device according to the twelfth aspect, wherein
the second semiconductor region further includes a seventh concentration region provided in a vicinity of an interface between the second semiconductor region and the third portion and in a vicinity of an interface between the second semiconductor region with the third semiconductor region, and having an impurity concentration lower than the impurity concentration in the first concentration region.

### (Sixteenth Aspect)

There is provided a device according to the twelfth aspect, wherein
the second semiconductor region further includes an eighth concentration region provided in a vicinity of an interface between the second semiconductor region and the third portion and in a vicinity of an interface between the second semiconductor region with the third semiconductor region, and having an impurity concentration higher than the impurity concentration in the first concentration region.

### (Seventeenth Aspect)

There is provided a device according to the first aspect, wherein
the second semiconductor region further includes a ninth concentration region provided between the first concentration region and the first portion and surrounding a part under the second portion, and
the ninth concentration region has a specific resistance higher than a specific resistance of the first concentration region or has an impurity concentration lower than the impurity concentration in the first concentration region.

### (Eighteenth Aspect)

There is provided a device according to the seventeenth aspect, further comprising:
an insulating film provided between the ninth concentration region and the second portion.

### (Nineteenth Aspect)

According to a nineteenth aspect of the embodiment, there is provided a method for manufacturing a semiconductor device comprising:
forming a second semiconductor region of a first conductivity type including a region having an impurity concentration lower than an impurity concentration in an first semiconductor region, on a first major surface of a first portion of the first semiconductor region of the first conductivity type;
forming a first groove in a first direction perpendicular to the first major surface from the second semiconductor region to a half way of the first portion to form a second portion of the first semiconductor region in the first groove; and
forming a second groove facing the second portion in the second semiconductor region, and forming a third portion that is a metal region of a first electrode in the second groove to cause the third portion and the second semiconductor region to form a Schottky junction.

### (Twentieth Aspect)

There is provided a method according to the nineteenth aspect, wherein an electric field relaxation region is formed by implanting boron by ion implantation into the second groove and thermally diffusing.

### (Twenty-First Aspect)

According to a twenty-first aspect of the embodiment, there is provided a method for manufacturing a semiconductor device comprising:
forming a first portion and a second portion of a first semiconductor region of a first conductivity type, the first portion including a first major surface, the second portion extending in a first direction perpendicular to the first major surface on the first major surface;
forming a second semiconductor region including a region having an impurity concentration lower than an impurity concentration in the first semiconductor rejoin, the second semiconductor region being adjacent to the second portion on the first major surface; and
forming a groove facing the second portion in the second semiconductor region, and forming a third portion that is a metal region of a first electrode in the groove to cause the third portion and the second semiconductor region to form a Schottky junction.

### (Twenty-Second Aspect)

There is provided a method according to the twenty-first aspect, wherein an electric field relaxation region is formed by implanting boron into the groove by ion implantation and thermally diffusing.

### (Twenty-Third Aspect)

According to a twenty-third aspect of the embodiment, there is provided a method for manufacturing a semiconductor device comprising:
forming a first portion and a second portion of a first semiconductor region of a first conductivity type, and a second semiconductor region, the first portion including a first major surface, the second portion extending in a first direction perpendicular to the first major surface on the first major, the second semiconductor region disposed adjacent to the second portion on the first major surface and including a region having an impurity concentration lower than an impurity concentration in the first semiconductor region;
forming a first groove in the second semiconductor region in a direction perpendicular to the second portion and forming a third semiconductor region of a second conductivity type in the first groove; and
forming a second groove facing the second portion in the second semiconductor region and the third semiconductor region, and forming a third portion that is a metal region of a first electrode in the second groove to cause the third portion and the second semiconductor region to form a Schottky junction.

### (Twenty-Fourth Aspect)

According to a twenty-fourth aspect of the embodiment, there is provided a method for manufacturing a semiconductor device comprising:
forming a first portion and a second portion of a first semiconductor region of a first conductivity type, and a second semiconductor region, the first portion including a first major surface, the second portion extending in a first direction perpendicular to the first major surface on the first major surface, the second semiconductor region disposed adjacent to the second portion on the first major surface and including a region having an impurity concentration lower than an impurity concentration in the first semiconductor region;
forming a first groove in a direction perpendicular to the second portion in the second semiconductor region and forming an insulating film on an inner wall of the first groove to bury an electrically conductive material in the first groove; and
forming a second groove facing the second portion in the second semiconductor region, the insulating film and the electrically conductive material, and forming a third portion that is a metal region of a first electrode in the second groove to cause the third portion and the second semiconductor region to form a Schottky junction.

### (Twenty-Fifth Aspect)

According to a twenty-fifth aspect of the embodiment, there is provided a method for manufacturing a semiconductor device comprising:
forming a first portion and two second portions of a first semiconductor region of a first conductivity type, the first portion including a first major surface, the two second portions extending in a first direction perpendicular to the first major surface on the first major surface, the forming including forming an outer shape of the two second portions when seen in the first direction into a wave shape, and alternately forming a first interval and a second interval smaller than the first interval as to the intervals of the two second portions;
epitaxially growing the second semiconductor region having an impurity concentration lower than an impurity concentration in the first semiconductor region between the two second portions, and burying a portion with the second interval with a second semiconductor material forming the second semiconductor region to leave a hole not buried with the second semiconductor material at a portion with the first interval;
burying a third semiconductor material forming a third semiconductor region of the second conductivity type in the hole; and
forming a groove penetrating the second semiconductor region and the third semiconductor region, and forming a third portion that is a metal region of a first electrode in the groove to cause the third portion and the second semiconductor region to form a Schottky junction.

### (Twenty-Sixth Aspect)

According to a twenty-sixth aspect of the embodiment, there is provided a method for manufacturing a semiconductor device comprising:
forming a first portion and two second portions of a first semiconductor region of a first conductivity type, the first portion including a first major surface, the two second portions extending in a first direction perpendicular to the first major surface on the first major surface, the forming including forming an outer shape of the two second portions when seen in the first direction into a wave shape, and alternately forming a first interval and a second interval smaller than the first interval as to the intervals of the two second portions;
epitaxially growing the second semiconductor region having an impurity concentration lower than an impurity concentration in the first semiconductor region between the two second portions, and burying a portion with the second interval with a second semiconductor material forming the second semiconductor region to leave a hole not buried with the second semiconductor material at a portion with the first interval;
forming a third portion that is a metal region of a first electrode in the hole to cause the third portion and the second semiconductor region to form a Schottky junction.

What is claimed is:

1. A semiconductor device, comprising:
a first semiconductor region of a first conductivity type, including a first portion including a first major surface and a second portion extending in a first direction perpendicular to the first major surface on the first major surface;
a first electrode including a third portion that is a metal region provided so as to face the second portion, and provided so as to be separated from the first semiconductor region;
a second semiconductor region of the first conductivity type provided between the second portion and the third portion, including a first concentration region having an impurity concentration lower than an impurity concentration in the first semiconductor region, and forming a Schottky junction with the third portion; and
a second electrode provided on an opposite side of the first major surface of the first portion and being in conduction with the first portion.

2. The device according to claim 1, wherein
the second portion is provided in two, and
the third portion is disposed between the two second portions.

3. The device according to claim 1, further comprising a first electric field relaxation region provided between the third portion and the first portion.

4. The device according to claim 3, wherein the first electric field relaxation region is a semiconductor region of a second conductivity type.

5. The device according to claim 3, wherein the first electric field relaxation region has a specific resistance higher than a specific resistance of the second semiconductor region or is a semiconductor region of the first conductivity type having an impurity concentration lower than an impurity concentration in the second semiconductor region.

6. The device according to claim 1, further comprising a second electric field relaxation region provided in an interface between the third portion and the second semiconductor region.

7. The device according to claim 6, wherein the second electric field relaxation region is a semiconductor region of a second conductivity type.

8. The device according to claim 6, wherein the first electric field relaxation region is a semiconductor region of the first conductivity type having an impurity concentration lower than an impurity concentration in the second semiconductor region.

9. The device according to claim 1, further comprising a third semiconductor region of the second conductivity type, the third semiconductor region extending in a second direction connecting the third portion and the second portion, extending in the first direction, and being in conduction with the first electrode.

10. The device according to claim 9, wherein the third semiconductor region is provided separated from the third portion.

11. The device according to claim 1, wherein
the first electrode further includes a fourth portion extending in a second direction connecting the third portion and the second portion and extending in the first direction, and
an insulating region is provided between the fourth portion and the second semiconductor region.

12. The device according to claim 11, wherein the fourth portion and the insulating region are provided separated from the third portion.

13. The device according to claim 12, wherein
the fourth portion and the insulating region are provided so as to extend from the third portion to the second portion, and
a film thickness in a region in a vicinity of a portion overlapping with the second portion of the insulating region is larger than a film thickness in other regions.

14. The device according to claim 12, wherein a fourth semiconductor region of the second conductivity type is provided on a side of the insulating region of the second semiconductor region.

15. The device according to claim 1, wherein
the second semiconductor region further includes a second concentration region provided between the third portion and the first concentration region, and
the second concentration region has an impurity concentration lower than the impurity concentration in the first concentration region.

16. The device according to claim 1, wherein
the second semiconductor region further includes a third concentration region provided between the third portion and the first concentration region, and
the third concentration region has an impurity concentration higher than the impurity concentration in the first concentration region.

17. The device according to claim 1, wherein
an outer shape along the first direction of the second portion is provided in a wave shape, and
a part of an outer shape along the first direction of the third portion is similar to the outer shape of the second portion.

18. The device according to claim 1, further comprising:
a plurality of third semiconductor regions of a second conductivity type being in conduction with the first electrode,
the third portion is provided in a plurality,
the plurality of third portions are provided so as to be separated in a direction perpendicular to the first direction, and
one of the plurality of third semiconductor regions being provided between adjacent portions of the plurality of third portions.

19. The device according to claim 1, wherein
the second semiconductor region further includes a fourth concentration region provided between the first concentration region and the third portion, and
the fourth concentration region has a specific resistance higher than a specific resistance of the first concentration region or has an impurity concentration lower than the impurity concentration in the first concentration region.

20. The device according to claim 1, wherein
the second semiconductor region further includes a ninth concentration region provided between the first concentration region and the first portion and surrounding a part under the second portion, and
the ninth concentration region has a specific resistance higher than a specific resistance of the first concentration region or has an impurity concentration lower than the impurity concentration in the first concentration region.
